(19) United States
(12) Patent Application Publication
(10) Pub. No.: US 2025/0072203 A1
(43) Pub. Date: Feb. 27, 2025

(54) LIGHT EMITTING ELEMENT AND DISPLAY PANEL INCLUDING THE SAME

(71) Applicant: Samsung Display Co., Ltd., Yongin-si (KR)

(72) Inventors: JONGWON LEE, Yongin-si (KR); PILGU KANG, Yongin-si (KR); SEUNG CHEOL KIM, Yongin-si (KR); CHANG-MIN LEE, Yongin-si (KR); HAKCHOONG LEE, Yongin-si (KR); WONSUK HAN, Yongin-si (KR); JAEHOON HWANG, Yongin-si (KR)

(73) Assignee: Samsung Display Co., Ltd., Yongin-si (KR)

(21) Appl. No.: 18/616,884

(22) Filed: Mar. 26, 2024

(30) Foreign Application Priority Data
Jul. 20, 2023 (KR) 10-2023-0094221

(51) Int. Cl. H10K 50/13; H10K 59/38

(52) U.S. Cl. CPC H10K 50/131; H10K 59/38

(57) ABSTRACT

A light emitting element includes a first electrode, a first light emitting stack disposed on the first electrode, a second light emitting stack disposed on the first light emitting stack, a third light emitting stack disposed on the second light emitting stack, a fourth light emitting stack disposed on the third light emitting stack, a fifth light emitting stack disposed on the fourth light emitting stack, a second electrode disposed on the fifth light emitting stack, and charge generation layers disposed between adjacent ones of the first light emitting stack to the fifth light emitting stack. Each of the first light emitting stack to the fifth light emitting stack includes at least one emission layer, and the first light emitting stack to the fifth light emitting stack include at least two blue emission layers, at least one green emission layer, and at least one red emission layer.

### CROSS-REFERENCE TO RELATED APPLICATION(S)

This application claims priority to and benefits of Korean Patent Application No. 10-2023-0094221 under 35 U.S.C. § 119, filed on Jul. 20, 2023, in the Korean Intellectual Property Office (KIPO), the entire contents of which are incorporated herein by reference.

### BACKGROUND

### 1. Technical Field

The disclosure herein relates to a light emitting element in which luminous efficiency and an element service life are improved, and a display panel including the same.

### 2. Description of the Related Art

Organic light emitting elements are self-emitting elements having fast response times and driven by low voltages. Accordingly, organic light emitting display devices including the organic light emitting elements may exclude a separate light source, and thus may be thin and lightweight. The organic light emitting display devices have numerous advantages, such as excellent brightness and viewing angle independence.

Organic light emitting elements are display elements that include an emission layer made of organic materials between an anode electrode and a cathode electrode. After a hole provided from the anode electrode and an electron provided from the cathode electrode combine in the emission layer to form an exciton, light corresponding to the energy between the hole and the electron is generated from the exciton.

Tandem organic light emitting elements may each have a structure that includes two or more stacks of hole injection layer/emission layer/electron transport layer between the anode electrode and the cathode electrode. A charge generation layer assisting in the generation and movement of charges may be present between each of the stacks.

### SUMMARY

The disclosure provides a light emitting element in which luminous efficiency and an element service life are improved.

The disclosure also provides a display panel with improved display efficiency.

In an embodiment of the disclosure, a light emitting element may include a first electrode, a first light emitting stack disposed on the first electrode, a second light emitting stack disposed on the first light emitting stack, a third light emitting stack disposed on the second light emitting stack, a fourth light emitting stack disposed on the third light emitting stack, a fifth light emitting stack disposed on the fourth light emitting stack, a second electrode disposed on the fifth light emitting stack, and charge generation layers disposed between adjacent ones of the first light emitting stack to the fifth light emitting stack. Each of the first light emitting stack to the fifth light emitting stack may include at least one emission layer, and the first light emitting stack to the fifth light emitting stack may include at least two blue emission layers, at least one green emission layer, and at least one red emission layer.

In an embodiment, the first light emitting stack to the fifth light emitting stack may include three blue emission layers, one or two green emission layers, and one or two red emission layers.

In an embodiment, the first light emitting stack may include a first blue emission layer, the second light emitting stack may include a second blue emission layer, the third light emitting stack may include a red emission layer, the fourth light emitting stack may include a third blue emission layer, and the fifth light emitting stack may include a green emission layer.

In an embodiment, the first light emitting stack may include a first blue emission layer, the second light emitting stack may include a second blue emission layer, the third light emitting stack may include a first complex emission layer, the fourth light emitting stack may include a third blue emission layer, the fifth light emitting stack may include a green emission layer, the first complex emission layer may include a red sub-emission layer and a green sub-emission layer disposed on first red sub-emission layer.

In an embodiment, the first light emitting stack may include a red emission layer, the second light emitting stack may include a first blue emission layer, the third light emitting stack may include a green emission layer, the fourth light emitting stack may include a second blue emission layer, and the fifth light emitting stack may include a third blue emission layer.

In an embodiment, the first light emitting stack may include a first complex emission layer, the second light emitting stack may include a first blue emission layer, the third light emitting stack may include a green emission layer, the fourth light emitting stack may include a second blue emission layer, the fifth light emitting stack may include a third blue emission layer, the first complex emission layer may include a red sub-emission layer and a green sub-emission layer disposed on the red sub-emission layer.

In an embodiment, the first light emitting stack to the fifth light emitting stack may include a first blue emission layer, a second blue emission layer, and a third blue emission layer, the third blue emission layer may be disposed adjacent to the second electrode compared to the first blue emission layer and the second blue emission layer, a distance from a top surface of the first electrode to a center of the third blue emission layer may be an nth-order resonance distance of the third blue emission layer. In an embodiment, n may be an integer greater than or equal to 3.

In an embodiment, the first light emitting stack to the fifth light emitting stack may include a red emission layer, a distance from a top surface of the first electrode to a center of the first red emission layer may be an mth-order resonance distance of the red emission layer. In an embodiment, m may be 1 or 2.

In an embodiment, the at least one emission layer included in each of the first light emitting stack to the fifth light emitting stack may have a thickness in a range of about 50 Å to about 400 Å.

In an embodiment, the charge generation layers may include a first charge generation layer disposed between the first light emitting stack and the second light emitting stack, a second charge generation layer disposed between the second light emitting stack and the third light emitting stack, a third charge generation layer disposed between the third light emitting stack and the fourth light emitting stack, and a fourth charge generation layer disposed between the fourth light emitting stack and the fifth light emitting stack.

In an embodiment, each of the charge generation layers may include a p-type charge generation layer doped with a p-dopant, and an n-type charge generation layer doped with an n-dopant.

In an embodiment, each of the first to fifth light emitting stacks may further include a hole transport region adjacent to the first electrode, and an electron transport region which is spaced apart from the hole transport region with the emission layer interposed between the electron transport region and the hole transport region, and may be adjacent to the second electrode.

In an embodiment, at least one of the electron transport regions of the first to fifth light emitting stacks may include an electron injection layer, and the electron injection layer may include at least two of Mg, Ag, Yb, and Al.

In an embodiment, at least one of the first light emitting stack to the fifth light emitting stack may include a phosphorescent emission layer, and at least another one of the first light emitting stack to the fifth light emitting stack may include a fluorescent emission layer.

In an embodiment, at least one of the first light emitting stack to the fifth light emitting stack may include a first host, a second host, and a dopant, and the first host and the second host may form an exciplex.

In an embodiment, the light emitting element may further include a capping layer disposed on the second electrode. The capping layer may have a refractive index greater than or equal to about 1.6.

In an embodiment of the disclosure, a light emitting element may include a first electrode, a first light emitting stack disposed on the first electrode, a second light emitting stack disposed on the first light emitting stack, a third light emitting stack disposed on the second light emitting stack, a fourth light emitting stack disposed on the third light emitting stack, a fifth light emitting stack disposed on the fourth light emitting stack, and a second electrode disposed on the fifth light emitting stack. Three of the first light emitting stack to the fifth light emitting stack may include blue emission layers, one of the first light emitting stack to the fifth light emitting stack may include at least one green emission layer, and a rest of the first light emitting stack to the fifth light emitting stack may include at least one red emission layer. The rest of the first light emitting stack to the fifth light emitting stack including the at least one red emission layer may be disposed adjacent to the first electrode compared to the one of the first light emitting stack to the fifth light emitting stack including the at least one green emission layer.

In an embodiment of the disclosure, a display panel may include a light emitting element that emits source light, and an optical structure layer which is disposed on the light emitting element and transmits the source light or converts the source light into light having a different wavelength. The light emitting element may include a first electrode, a first light emitting stack disposed on the first electrode, a second light emitting stack disposed on the first light emitting stack, a third light emitting stack disposed on the second light emitting stack, a fourth light emitting stack disposed on the third light emitting stack, a fifth light emitting stack disposed on the fourth light emitting stack, a second electrode disposed on the fifth light emitting stack, and charge generation layers disposed between adjacent ones of the first light emitting stack to the fifth light emitting stack. Each of the first light emitting stack to the fifth light emitting stack may include at least one emission layer, and the first light emitting stack to the fifth light emitting stack may include at least two blue emission layers, at least one green emission layer, and at least one red emission layer.

In an embodiment, the optical structure layer may include a light control layer disposed on the light emitting element, and the light control layer may include a first light control pattern that emits light having a red wavelength, a second light control pattern that emits light having a blue wavelength, and a third light control pattern that emits light having a green wavelength.

In an embodiment, the first light emitting stack to the fifth light emitting stack may include three blue emission layers, one or two green emission layers, and one or two red emission layers.

### BRIEF DESCRIPTION OF THE FIGURES

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1A is a perspective view of a display panel according to an embodiment of the disclosure;

FIG. 1B is a schematic cross-sectional view of the display panel according to an embodiment of the disclosure;

FIG. 1C is a plan view of the display panel according to an embodiment of the disclosure;

FIG. 2 is an enlarged plan view of a portion of the display panel according to an embodiment of the disclosure;

FIG. 3 is a schematic cross-sectional view of the display panel according to an embodiment of the disclosure;

FIGS. 4A to 4C are schematic cross-sectional views of the display panel according to embodiment of the disclosure;

FIGS. 5A to 5E are schematic cross-sectional views schematically illustrating light emitting elements according to embodiments of the disclosure; and

FIG. 6 is a graph showing emission intensity depending on an optical distance of each of red light, blue light, and green light.

### DETAILED DESCRIPTION

Hereinafter, embodiments of the disclosure will be described with reference to the accompanying drawings.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Like reference numerals refer to like components throughout. Also, in the drawings, the thicknesses, ratios, and dimensions of the components are exaggerated for effective description of technical contents.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that, although the terms “first”, “second”, etc. may be used herein to describe various elements, these elements should not be limited by these terms. These terms are only used to distinguish one element from another. For example, a first component could be termed a second component, and, similarly, a second component could be termed a first component, without departing from the scope of the disclosure. The terms of a singular form may include plural forms unless the context clearly indicates otherwise.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Being “disposed directly on” herein means that there are no intervening layers, films, regions, plates, or the like between a part such as a layer, a film, a region, and a plate and another part. For example, being “disposed directly on” may mean being disposed between two layers or two members without using an additional member, such as an adhesive member.

Unless otherwise defined, all terms (including technical and scientific terms) used herein have the same meaning as commonly understood by one of ordinary skill in the art to which the disclosure belongs. In addition, it will be understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display panel according to an embodiment of the disclosure will be described with reference to the accompanying drawings.

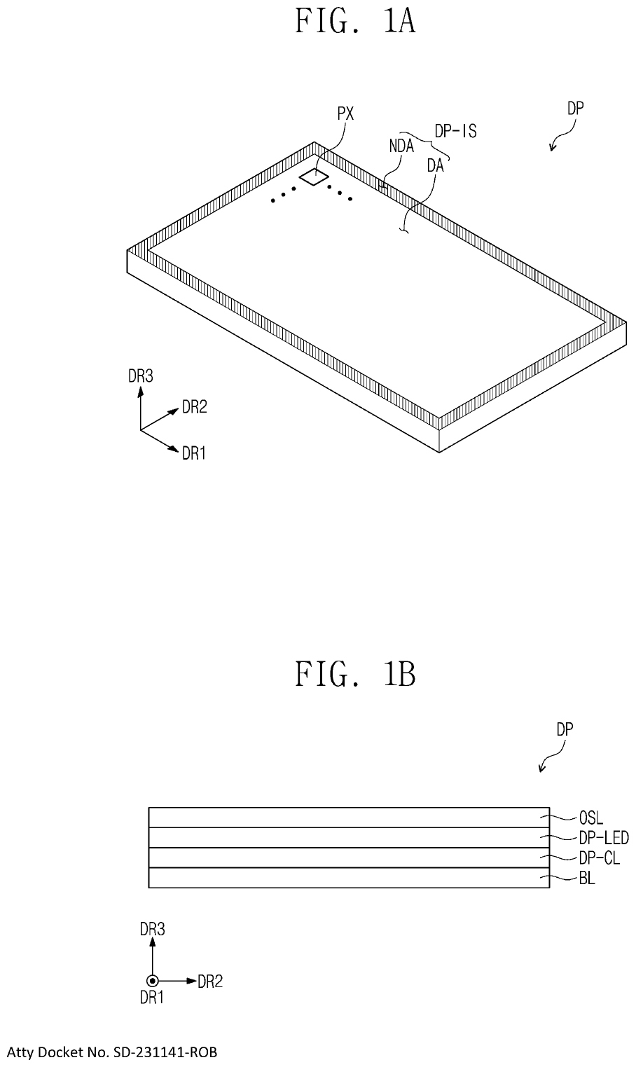

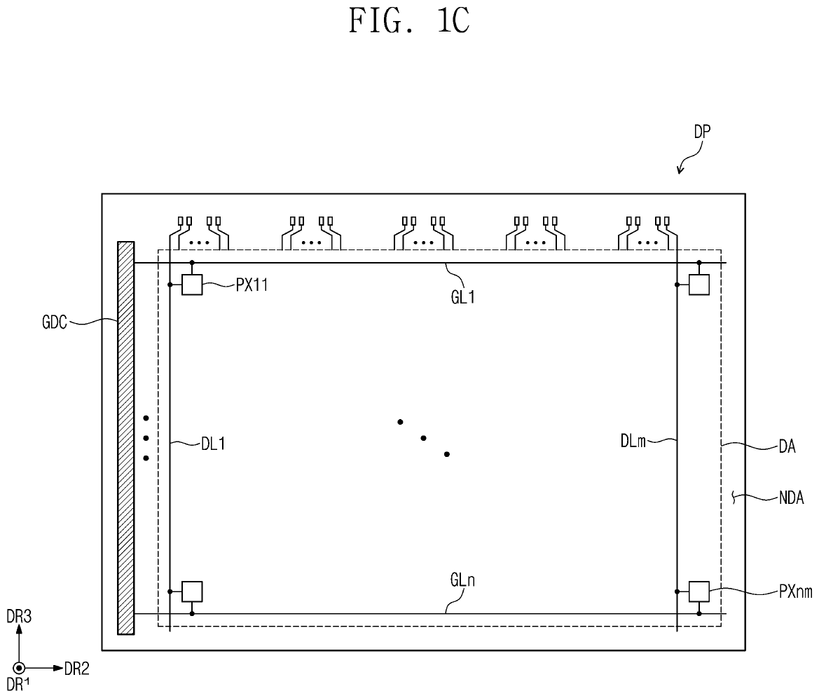

FIG. 1A is a perspective view of a display panel according to an embodiment of the disclosure. FIG. 1B is a schematic cross-sectional view of the display panel according to an embodiment of the disclosure. FIG. 1C is a plan view of the display panel according to an embodiment of the disclosure.

As shown in FIG. 1, a display panel DP may display an image through a display surface DP-IS. The display surface DP-IS may be parallel to a plane defined by a first direction DR1 and a second direction DR2. The display surface DP-IS may include a display region DA and a non-display region NDA. Pixels PX may be disposed in the display region DA and pixels PX may be not disposed in the non-display region NDA. The non-display region NDA may be defined along edges of the display surface DP-IS. The non-display region NDA may surround the display region DA. However, the disclosure is not limited thereto, and in an embodiment of the disclosure, the non-display region NDA may be omitted or disposed only a side of the display region DA.

The normal direction of the display surface DP-IS, for example, the thickness direction of the display panel DP may be a third direction DR3. A front surface (or an upper surface) and a rear surface (or a lower surface) of each of layers or units described below are separated by the third direction DR3. However, the first to third directions DR1, DR2, and DR3 shown in the drawings are not limited thereto.

In the drawings, a display panel DP having a flat display surface DP-IS is illustrated, but the disclosure is not limited thereto. The display panel DP may include a curved display surface or a three-dimensional display surface. The three-dimensional display surface may include multiple display regions facing different directions.

As illustrated in FIG. 1B, the display panel DP may include a base substrate BS, a circuit element layer DP-CL, a display element layer DP-LED, and an optical structure layer OSL. The base substrate BS may include a synthetic resin substrate or a glass substrate. The circuit element layer DP-CL may include at least one insulation layer and circuit element. The circuit element may include a signal line, a pixel driving circuit, etc. The circuit element layer DP-CL may be formed through a forming process of an insulation layer, a semiconductor layer, and a conductive layer by coating, deposition, etc. and a patterning process of the insulation layer, the semiconductor layer, and the conductive layer by a photolithography process. The display element layer DP-LED may include at least one display element. The optical structure layer OSL may convert the color of light provided from the display element. The optical structure layer OSL may include a structure for increasing light control patterns and conversion efficiency of light.

FIG. 1C schematically illustrates a planar arrangement of signal lines GL1 to GLn and DL1 to DLm and pixels PX11 to PXnm. The signal lines GL1 to GLn and DL1 to DLm may include multiple gate lines GL1 to GLn and multiple data lines DL1 to DLm.

Each of the pixels PX11 to PXnm may be connected to a corresponding gate line among the gate lines GL1 to GLn and a corresponding data line among the data lines DL1 to DLm. Each of the pixels PX11 to PXnm may include a pixel driving circuit and a display element. According to the configuration of the pixel driving circuit of the pixels PX11 to PXnm, more types of signal lines may be provided in the display panel DP.

The pixels PX11 to PXnm in the form of a matrix are schematically illustrated, but the disclosure is not limited thereto. The pixels PX11 to PXnm may be arranged in the form of PenTile®. For example, the points, at which the pixels PX11 to PXnm are arranged, may correspond to apexes of a diamond. The gate driving circuit GDC may be integrated in the display panel DP through an oxide silicon gate driver circuit (OSG) or an amorphous silicon gate driver circuit (ASG) process.

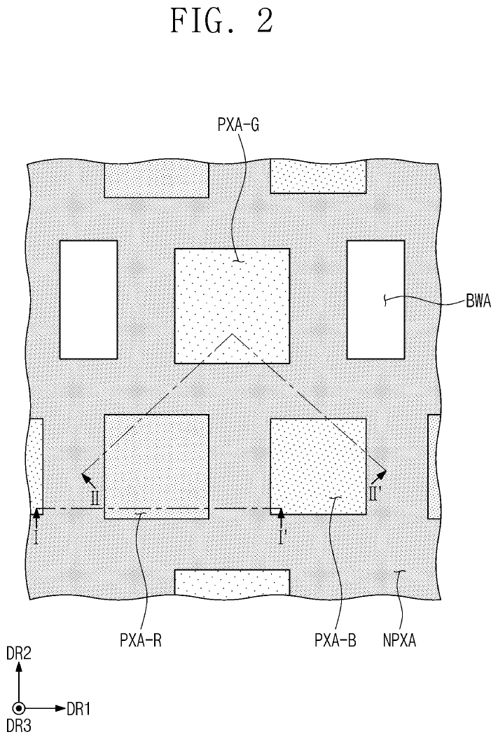

FIG. 2 is an enlarged plan view of a portion of the display panel according to an embodiment of the disclosure. FIG. 2 schematically illustrate a plane including three pixel regions PXA-R, PXA-B, and PXA-G and a bank well region BWA adjacent thereto in the display panel DP (see FIG. 1A) according to an embodiment. In an embodiment of the disclosure, three kinds of pixel regions PXA-R, PXA-B, and PXA-G illustrated in FIG. 2 may be repeatedly disposed in the entire display region DA (see FIG. 1A).

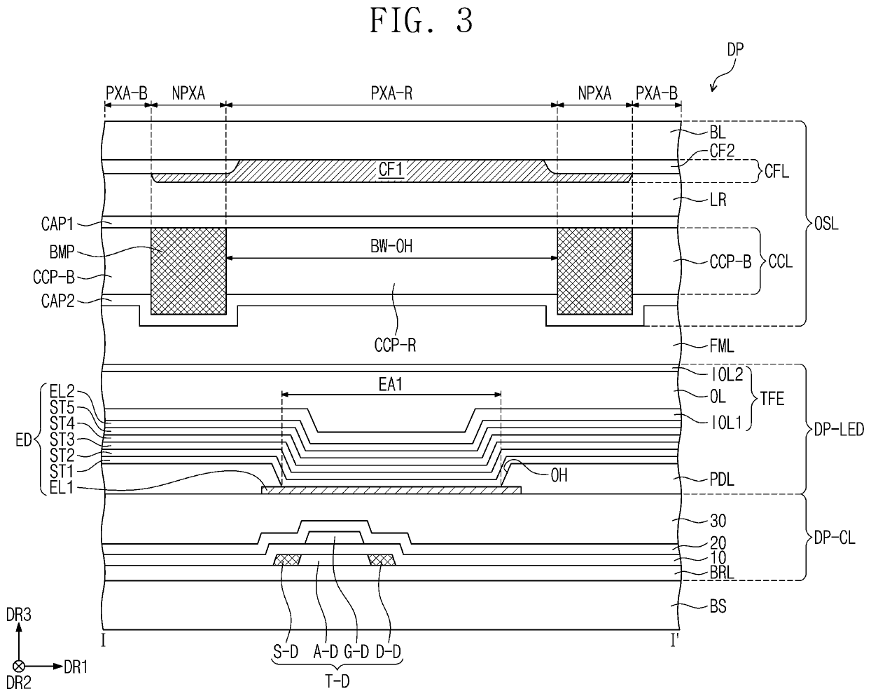

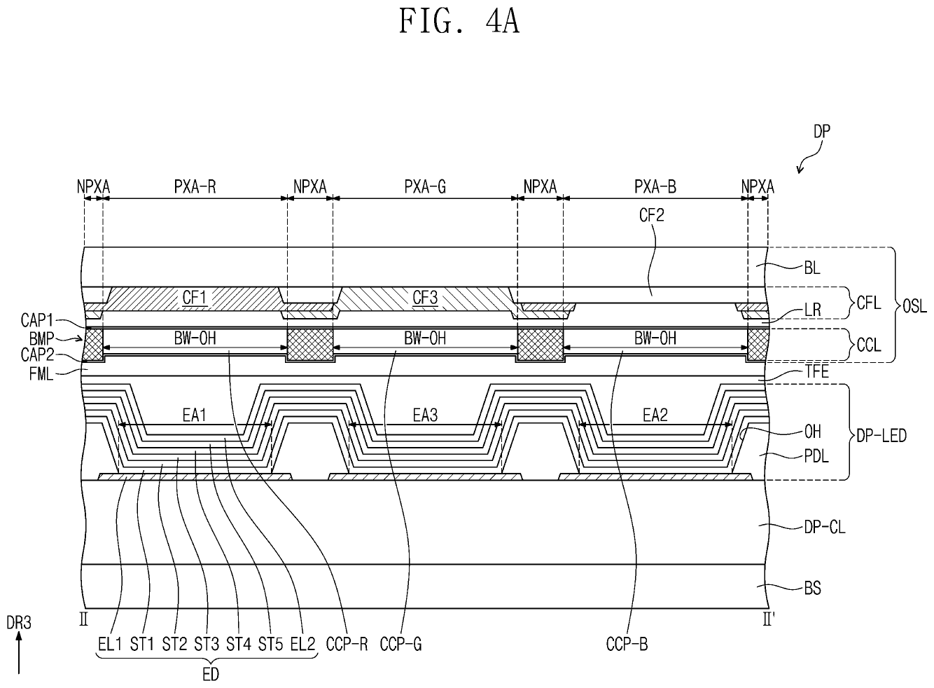

The peripheral region NPXA may be disposed adjacent to first to third pixel regions PXA-R, PXA-B, and PXA-G. The peripheral region NPXA may define boundaries of the first to third pixel regions PXA-R, PXA-B, and PXA-G. The peripheral region NPXA may surround the first to third pixel regions PXA-R, PXA-B, and PXA-G. In the peripheral region NPXA, a structure for preventing color mixing among the first to third pixel regions PXA-R, PXA-B, and PXA-G, for example, a pixel defining film PDL (see FIG. 3), a bank BMP (see FIG. 3), or the like, may be disposed.

Although FIG. 2 illustrates the first to third pixel regions PXA-R, PXA-B, and PXA-G having the same planar shape and different planar areas, the disclosure is not limited thereto. The areas of at least two of the first to third pixel regions PXA-R, PXA-B, and PXA-G may be the same. The areas of the first to third pixel regions PXA-R, PXA-B, and PXA-G may be set according to light emission colors. Among the primary colors, the area of a pixel region that emits red light may be the largest, and the area of a pixel region that emits blue light may be the smallest.

Although FIG. 2 illustrates the first to third pixel regions PXA-R, PXA-B, and PXA-G in a rectangular shape in a plan view, the disclosure is not limited thereto. In a plan view, the first to third pixel regions PXA-R, PXA-B, and PXA-G may have another polygonal shape (substantially polygonal shape) such as a diamond or a pentagon. In an embodiment, the first to third pixel regions PXA-R, PXA-B, and PXA-G may have a rectangular shape (a substantially rectangular shape) of which corners are rounded in a plan view.

Although FIG. 2 illustrates that the third pixel region PXA-G is disposed on a first row and the first pixel region PXA-R and the second pixel region PXA-B are disposed on a second row, the arrangement of the first to third pixel regions PXA-R, PXA-B, and PXA-G is not limited thereto and may be variously changed. For example, the first to third pixel regions PXA-R, PXA-B, and PXA-G may be disposed on a same row.

One of the first to third pixel regions PXA-R, PXA-B, and PXA-G may provide red light, another may provide blue light, and the other may provide green light. In an embodiment, the first pixel region PXA-R may provide red light, the second pixel region PXA-B may provide blue light, and the third pixel region PXA-G may provide green light. The first pixel region PXA-R may emit light having an emission wavelength in a range of about 620 nm to about 700 nm, the second pixel region PXA-B may emit light having an emission wavelength in a range of about 410 nm to about 480 nm, and the third pixel region PXA-G may emit light having an emission wavelength in a range of about 520 nm to about 600 nm.

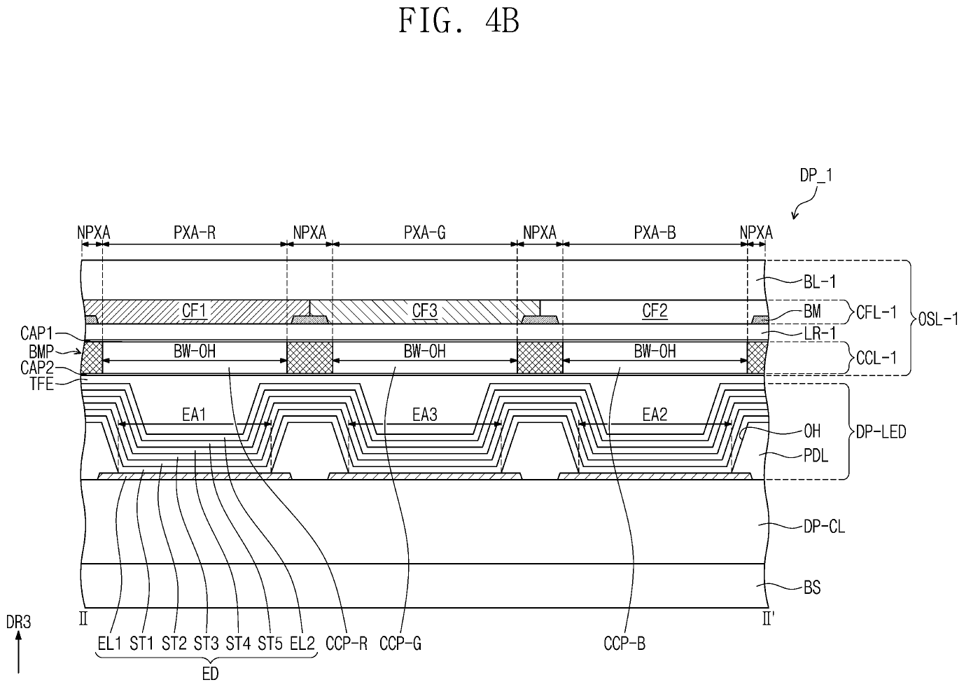

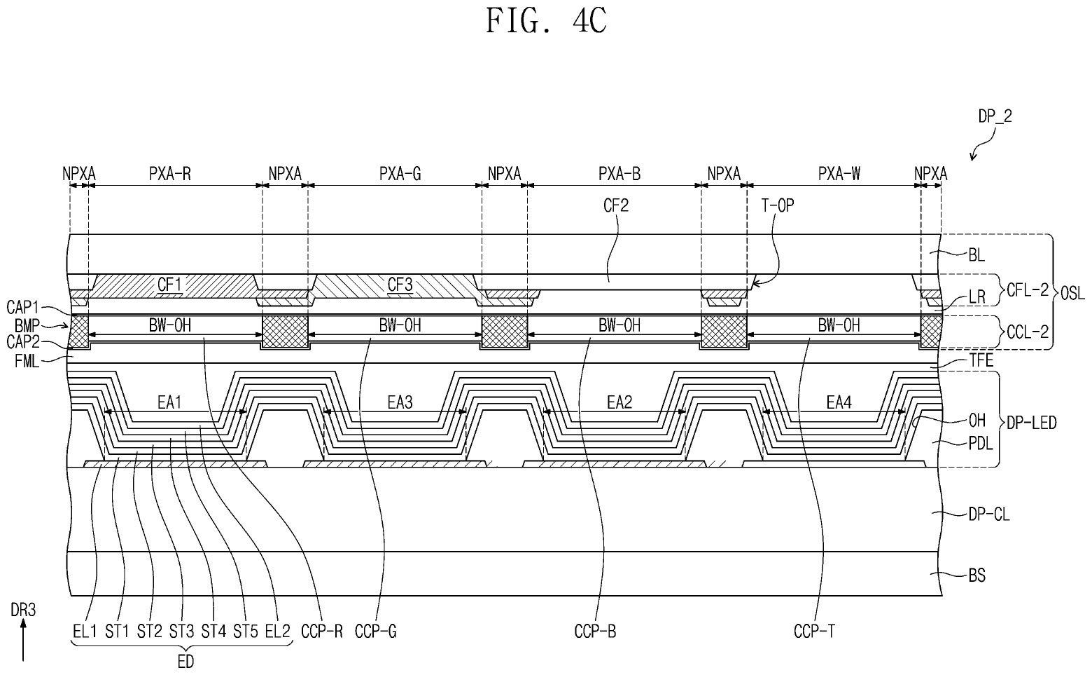

A bank well region BWA may be defined in the display region DA (see FIG. 1A). The bank well region BWA may be a region in which a bank well is formed in order to prevent defects due to misalignment in a process of patterning multiple light control patterns CCP-R, CCP-B, and CCP-G (see FIG. 4A) included in the light control layer CCL (see FIG. 4A). For example, the bank well region BWA may be a region in which a bank well formed by removing a portion of the bank BMP (see FIG. 4A) is defined.

Although FIG. 2 illustrates that two bank well regions BWA are defined to be adjacent to the third pixel region PXA-G, the disclosure is not limited thereto, and the shape and arrangement of the bank well regions BWA may be variously changed.

FIG. 3 is a schematic cross-sectional view of the display panel according to an embodiment of the disclosure. FIG. 4A is a schematic cross-sectional view of the display panel according to an embodiment of the disclosure. FIG. 3 is a schematic cross-sectional view of the light emitting element included in the display panel according to an embodiment of the disclosure. FIG. 3 schematically illustrates a cross-section taken along cut-line I-I′ shown in FIG. 2. FIG. 4A schematically illustrates a cross-section taken along cut-line II-II′ shown in FIG. 2.

Referring to FIG. 3, the display panel DP of an embodiment may include a base substrate BS, a circuit element layer DP-CL disposed on the base substrate BS, and a display element layer DP-LED disposed on the circuit element layer DP-CL. In this specification, the base substrate BS, the circuit element layer DP-CL, and the display element layer DP-LED may be collectively referred to as a lower panel.

The base substrate BS may be a member providing a base surface on which the configuration included in the circuit element layer DP-CL is disposed. In an embodiment, the base substrate BS may be a glass substrate, a metal substrate, a polymer substrate, etc. However, the disclosure is not limited thereto, and the base substrate BS may be an inorganic layer, a functional layer, or a composite material layer.

The base substrate BS may have a multi-layered structure. For example, the base substrate BS may have a three-layered structure including a polymer resin layer, an adhesive layer, and a polymer resin layer. For example, the polymer resin layer may include a polyimide-based resin. For example, the polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, apolyamide-based resin, and a perylene-based resin. In this specification, the term “a-based” resin means a resin including a functional group of “a.”

The circuit element layer DP-CL may be disposed on the base substrate BS. The circuit element layer DP-CL may include a transistor T-D as a circuit element. The configuration of the circuit element layer DP-CL may vary with the design of the driving circuit of the pixels PX (see FIG. 1A), and FIG. 3 illustrates one transistor T-D according to an embodiment. The arrangement of an active A-D, a source S-D, a drain D-D, and a gate G-D constituting the transistor T-D is illustrated according to an embodiment. The active A-D, the source S-D, and the drain D-D may be regions that are divided according to a doping concentration or conductivity of a semiconductor pattern.

The circuit element layer DP-CL may include a lower buffer layer BRL disposed on the base substrate BS, a first insulation layer 10, a second insulation layer 20, and a third insulation layer 30. For example, the lower buffer layer BRL, the first insulation layer 10, and the second insulation layer 20 may be inorganic layers, and the third insulation layer 30 may be an organic layer.

The display element layer DP-LED may include a light emitting element ED as a display element. The light emitting element ED may generate the source light. In an embodiment, the source light may be white light or blue light. In an embodiment, the display element layer DP-LED may include an organic light emitting diode as a light emitting element. For example, the emission layer included in the light emitting element ED may include an organic light emitting material as a light emitting material.

The light emitting element ED may include the first electrode EL1, the second electrode EL2, and at least one light emitting stack ST1, ST2, ST3, ST4, and ST5 disposed between the first electrode EL1 and the second electrode EL2. In an embodiment, the light emitting element ED may include the first electrode EL1, the second electrode EL2, and five light emitting stacks ST1, ST2, ST3, ST4, and ST5 disposed between the first electrode EL1 and the second electrode EL2. The light emitting stacks included in the light emitting element ED will be described below.

The first electrode EL1 may be disposed on the third insulation layer 30. The first electrode EL1 may be directly or indirectly connected to the transistor T-D, and FIG. 3 does not illustrate the connection structure of the first electrode EL1 and the transistor T-D.

The display element layer DP-LED may include a pixel defining film PDL. For example, the pixel defining film PDL may be an organic layer. A light emitting opening OH may be defined in the pixel defining film PDL. The light emitting opening OH of the pixel defining film PDL may expose at least a portion of the first electrode EL1. In an embodiment, a first light emitting region EA1 may be defined by the light emitting opening OH.

Each of the five light emitting stacks ST1, ST2, ST3, ST4, and ST5 may at least overlap the pixel region PXA-R in a plan view, and may include an emission layer. Each of the five light emitting stacks ST1, ST2, ST3, ST4, and ST5 may be commonly disposed in the first to third pixel regions PXA-R, PXA-B, and PXA-G (see FIG. 4A). Each of the five light emitting stacks ST1, ST2, ST3, ST4, and ST5 overlapping the first to third pixel regions PXA-R, PXA-B, and PXA-G (see FIG. 4A) may have an integral shape. However, the disclosure is not limited thereto, and at least one of the five light emitting stacks ST1, ST2, ST3, ST4, and ST5 may be formed separately in each of the first to third pixel regions PXA-R, PXA-B, and PXA-G (see FIG. 4A). In an embodiment, at least one of the five light emitting stacks ST1, ST2, ST3, ST4, and ST5 may be patterned in the light emitting opening OH and may be formed separately in each of the first to third pixel regions PXA-R, PXA-B, and PXA-G (see FIG. 4A).

The second electrode EL2 may be disposed to face the first electrode EL1 with the five light emitting stacks ST1, ST2, ST3, ST4, and ST5 interposed between the first electrode EL1 and the second electrode EL2.

The display element layer DP-LED may include a thin-film encapsulation layer TFE that protects the second electrode EL2. The thin-film encapsulation layer TFE may include an organic material or inorganic material. The thin-film encapsulation layer TFE may have a multi-layered structure in which an inorganic layer/organic layer is alternately stacked each other. In an embodiment, the thin-film encapsulation layer TFE may include a first inorganic encapsulation layer IOL1/organic encapsulation layer OL/second inorganic encapsulation layer IOL2. The first and second inorganic encapsulation layer IOL1 and IOL2 may protect the light emitting element ED from external moisture, and the organic encapsulation layer OL may prevent pit defect of the light emitting element ED caused by introduced foreign substances during a manufacture process. Although not illustrated, the display panel DP may further include a refractive index control layer for improving light output efficiency.

As illustrated in FIG. 3, the optical structure layer OSL may be disposed on the thin-film encapsulation layer TFE. The optical structure layer OSL may include a light control layer CCL, a low refractive layer LR, a color filter layer CFL, and a base layer BL. In the specification, the optical structure layer OSL may be referred to as an upper panel.

The light control layer CCL may be disposed on the display element layer DP-LED including the light emitting element ED. The light control layer CCL may include a bank BMP, light control patterns CCP-R, CCP-G, and CCP-B, and a first barrier layer CAP1.

The bank BMP may include a base resin and an additive. The base resin may be formed of various resin compositions, which may be generally referred to as a binder. The additive may include a coupling agent and/or photoinitiator. The additive may further include a dispersant.

The bank BMP may include a black coloring agent for shielding light. The bank BMP may include a black pigment and black dye mixed in the base resin. In an embodiment, the black component may include carbon black or a metal such as chromium, or an oxide thereof.

The bank BMP may include a bank opening BW-OH corresponding to the light emitting opening OH. In a plan view, the bank opening BW-OH may overlap the light emitting opening OH, and may have an area greater than an area of the light emitting opening OH. For example, the bank opening BW-OH may have an area greater than an area of the light emitting region EA1 defined by the light emitting opening OH. In the specification, “corresponding” means that the two configurations overlap each other in the thickness direction DR3 of the display panel DP, and is not limited to the same area.

The light control patterns CCP-R, CCP-G, and CCP-B may be disposed inside the bank opening BW-OH. At least a portion of the light control patterns CCP-R, CCP-G, and CCP-B may change the optical properties of the source light. In an embodiment, a first light control pattern CCP-R may change the optical properties of the source light.

The first light control pattern CCP-R may include a quantum dot for changing the optical properties of the source light. The first light control pattern CCP-R may include a quantum dot which converts the source light into light having a different wavelength. In the first light control pattern CCP-R overlapping the first pixel region PXA-R in a plan view, the quantum dot may convert the source light into red light.

In the specification, the quantum dot means a crystal of a semiconductor compound. The quantum dot may emit light having various emission wavelengths depending on the size of crystal. The quantum dot may emit light having various emission wavelengths as the elemental ratio in the quantum dot compound is adjusted.

The quantum dot may have a diameter in a range of, for example, about 1 nm to about 10 nm.

The quantum dot may be synthesized by a wet chemical process, a metal organic chemical vapor deposition process, a molecular beam epitaxy process, a similar process thereto, or the like.

The wet chemical process is a method in which a precursor material is mixed with an organic solvent to grow quantum dot particle crystals. When the crystals grow, the organic solvent naturally may act as a dispersant coordinated on the surface of the quantum dot crystals and control the growth of the crystals. Thus, the wet chemical process may control the growth of quantum dot particles through a process which is more readily performed than vapor deposition methods, such as metal organic chemical vapor deposition (MOCVD) or molecular beam epitaxy (MBE), and which is performed at low costs.

The core of the quantum dot may include a Group II-VI compound, a Group III-V compound, a Group III-VI compound, a Group I-III-IV compound, a Group IV-VI compound, a Group IV element, a Group IV compound, or a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. The Group II-VI semiconductor compound may further include a Group I metal and/or a Group IV element. The Group I-II-VI compound may include CuSnS, CuZnS, or the like and the Group II-IV-VI compound may include ZnSnS, or the like. The Group I-II-IV-VI compound may include a quaternary compound selected from the group consisting of Cu₂ZnSnS₂, Cu₂ZnSnS₄, Cu₂ZnSnSe₄, Ag₂ZnSnS₂, and a mixture thereof.

The Group III-VI compound may include a binary compound such as In₂S₃ or In₂Se₃, a ternary compound such as InGaS₃ or InGaSe₃, or a combination thereof.

The Group I-III-VI compound may include a ternary compound selected from the group consisting of AgInS, AgInS₂, CuInS, CuInS₂, AgGaS₂, CuGaS₂ CuGaO₂, AgGaO₂, AgAlO₂, and a mixture thereof, or a quaternary compound such as AgInGaS₂ or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The Group III-V compound may further include a Group II metal. For example, InZnP, etc., may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof.

Examples of the Group II-IV-V compound may include a ternary compound selected from the group consisting of ZnSnP, ZnSnP₂, ZnSnAs₂, ZnGeP₂, ZnGeAs₂, CdSnP₂, CdGeP₂, and a mixture thereof.

The Group IV element may be selected from the group consisting of Si, Ge, and a mixture thereof. The Group IV compound may be a binary compound selected from the group consisting of SiC, SiGe, and a mixture thereof.

Each element included in a polynary compound such as the binary compound, the ternary compound, or the quaternary compound may be present in a particle with a uniform or non-uniform concentration distribution. For example, the formulae indicate the types of elements included in the compounds, and the elemental ratio in the compound may vary. For example, AgInGaS₂ may mean AgInₓGa₁₋ₓS₂ (where x is a real number between 0 to 1).

The binary compound, the ternary compound, or the quaternary compound may be present in a particle with a uniform concentration distribution, or may be present in a particle with a partially different concentration distribution. The quantum dot may have a core/shell structure in which one quantum dot surrounds another quantum dot. The core/shell structure may have a concentration gradient in which the concentration of elements present in the shell decreases toward the core.

In embodiments, the quantum dot may have a core-shell structure including a core containing nanocrystals and a shell surrounding the core. The shell of the quantum dot may serve as a protection layer to prevent the chemical deformation of the core so as to maintain semiconductor properties, and/or a charging layer to impart electrophoresis properties to the quantum dot. The shell may be a single layer or a multilayer. The shell of the quantum dots may include a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but of the disclosure is not limited thereto.

The semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the disclosure is not limited thereto.

The quantum dot may have a full width of half maximum (FWHM) of an emission wavelength spectrum less than or equal to about 45 nm. For example, the quantum dot may have a full width of half maximum (FWHM) of an emission wavelength spectrum less than or equal to about 40 nm. For example, the quantum dot may have a full width of half maximum (FWHM) of an emission wavelength spectrum less than or equal to about 30 nm. Color purity or color reproducibility may be improved in the above range. Light emitted through such a quantum dot may be emitted in all directions, and thus a wide viewing angle may be improved.

Although the form of the quantum dot is not particularly limited as long as it is a form commonly used in the art, for example, the quantum dot in the form of spherical, pyramidal, multi-arm, cubic nanoparticles, nanotubes, nanowires, nanofibers, nanoplate particles, etc. may be used.

As the size of the quantum dot is adjusted or the elemental ratio in the quantum dot compound is adjusted, the energy band gap of the quantum dot may be controlled, and thus light in various wavelength ranges may be obtained in the quantum dot. Therefore, the quantum dot as above (using different sizes of quantum dots or different elemental ratios in the quantum dot compound) may be used, and thus the light emitting element, which emits light in various wavelengths, may be implemented. For example, the adjustment of the size of the quantum dot or the elemental ratio in the quantum dot compound may be selected to emit red, green, and/or blue light. The quantum dots may be configured to emit white light by combining various colors of light.

In an embodiment, the quantum dot included in the first light control pattern CCP-R overlapping the first pixel region PXA-R may have a red light emission color. The smaller the particle size of the quantum dot becomes, the shorter wavelength of light may be emitted. For example, in the quantum dot having a same core, the particle size of a quantum dot emitting green light may be smaller than the particle size of a quantum dot emitting red light. In the quantum dot having a same core, the particle size of a quantum dot emitting blue light may be smaller than the particle size of a quantum dot emitting green light. However, the disclosure is not limited thereto, and even in the quantum dot having a same core, the particle size may be adjusted according to forming-materials and thickness of a shell.

In case that the quantum dot has various light emission colors such as blue, red, and green, the quantum dot having a different light emission color may have a different core material.

The first light control pattern CCP-R may further include a scatterer. The first light control pattern CCP-R may include a quantum dot that converts the blue light into the red light, and the scatterer that scatters light.

The scatterer may be inorganic particles. For example, the scatterer may include at least one of TiO₂, ZnO, Al₂O₃, SiO₂, and hollow sphere silica. The scatterer may include at least one of TiO₂, ZnO, Al₂O₃, SiO₂, and hollow sphere silica, or may be a mixture of at least two of TiO₂, ZnO, Al₂O₃, SiO₂, and hollow sphere silica.

The first light control pattern CCP-R may include a base resin in which the quantum dots and the scatterer are dispersed. The base resin may be a medium in which the quantum dots and the scatterer are dispersed, and may be composed of various resin compositions that may be generally referred to as a binder. For example, the base resin may be an acrylic-based resin, a urethane-based resin, a silicone-based resin, an epoxy-based resin, etc. The base resin may be a transparent resin.

In an embodiment, the first light control pattern CCP-R may be formed by an inkjet process. A liquid composition may be provided in the bank opening BW-OH. A composition polymerized by a thermo-curing process or a photo-curing process may have a decrease in volume after being cured.

A height difference between the bottom surface of the bank BMP and the bottom surface of the light control pattern CCP-R may occur. For example, the bottom surface of the bank BMP may be higher than the bottom surface of the first light control pattern CCP-G. The height difference between the bottom surface of the bank BMP and the bottom surface of the light control pattern CCP-R may be, for example, in a range of about 2 m to about 3 km.

The light control layer CCL may include a first barrier layer CAP1 disposed on a surface of the first light control pattern CCP-R. The first barrier layer CAP1 may serve to prevent the penetration of moisture and/or oxygen (hereinafter, referred to as “moisture/oxygen”) and adjust a refractive index, thereby improving the optical properties of the optical structure layer OSL. The first barrier layer CAP1 may be disposed on a surface of the upper portion or a surface of the lower portion of the first light control pattern CCP-R to prevent the first light control pattern CCP-R from being exposed to moisture/oxygen, for example, may prevent quantum dots included in the first light control pattern CCP-R from being exposed to moisture/oxygen. The first barrier layer CAP1 may also protect the first light control pattern CCP-R from an external impact.

In an embodiment, the first barrier layer CAP1 may be spaced apart from the display element layer DP-LED with the first light control pattern CCP-R interposed between the first barrier layer CAP1 and the display element layer DP-LED. For example, the first barrier layer CAP1 may be disposed on the top surface of the first light control pattern CCP-R. In an embodiment, the light control layer CCL may include a second barrier layer CAP2 disposed between the first light control pattern CCP-R and the display element layer DP-LED. The first barrier layer CAP1 may cover the top surface of the light control pattern CCP-G, which is adjacent to the low refractive layer LR, and the second barrier layer CAP2 may cover the bottom surface of the first light control pattern CCP-R which is adjacent to the display element layer DP-LED. In the specification, the “top surface” may be a surface positioned at an upper portion based on the third direction DR3, and the “bottom surface” may be a surface positioned at a lower portion based on the third direction DR3.

The first barrier layer CAP1 and the second barrier layer CAP2 may cover a surface of the bank BMP as well as the first light control pattern CCP-R.

The first barrier layer CAP1 may cover a surface of the bank BMP and the first light control pattern CCP-R adjacent to the low refractive layer LR. The first barrier layer CAP1 may be disposed (e.g., directly disposed) on the lower portion of the low refractive layer LR. The second barrier layer CAP2 may be disposed to follow the height difference between the bank BMP and the first light control pattern CCP-R. The second barrier layer CAP2 may be disposed (e.g., directly disposed) on the upper portion of a filling layer FML.

The first barrier layer CAP1 and the second barrier layer CAP2 may include an inorganic material. In the display panel DP of an embodiment, the first barrier layer CAP1 may include silicon oxynitride (SiON). Both the first barrier layer CAP1 and the second barrier layer CAP2 may include silicon oxynitride. However, the disclosure is not limited thereto, and the first barrier layer CAP1 disposed on the upper portion of the first light control pattern CCP-R may include silicon oxynitride, and the second barrier layer CAP2 disposed on the lower portion of the first light control pattern CCP-R may include silicon oxide (SiOx).

The color filter layer CFL may be disposed on the light control layer CCL. The color filter layer CFL may include at least one color filter. The color filter may transmit light having a specific wavelength range and block light other than light having the specific wavelength range. A first color filter CF1 of the first pixel region PXA-R may transmit red light, and may block green light and blue light.

The first color filter CF1 may include a base resin, and dye and/or pigment dispersed in the base resin. The base resin may be a medium in which dye and/or pigment is dispersed, and may be composed of various resin compositions that may be generally referred to as a binder.

The first color filter CF1 may have a uniform thickness in the first pixel region PXA-R. The light converted from the source light, which is blue light, into red light through the first light control pattern CCP-R may be provided to the outside with uniform brightness in the first pixel region PXA-R.

The optical structure layer OSL may include the low refractive layer LR. The low refractive layer LR may be disposed between the light control layer CCL and the color filter layer CFL. The low refractive layer LR may be disposed on the upper portion of the light control layer CCL and block the light control pattern CCP-R from being exposed to moisture/oxygen. The low refractive layer LR may be disposed between the light control pattern CCP-R and the first color filter CF1 or may serve as an optical functional layer, for example, increasing light extraction efficiency or preventing reflected light from being incident to the light control layer CCL. The low refractive layer LR may have a refractive index lower than an adjacent layer.

The low refractive layer LR may include at least one inorganic layer. For example, the low refractive layer LR may include silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride, or a thin metal film which secures light transmittance. However, the disclosure is not limited thereto, and the low refractive layer LR may include an organic film. The low refractive layer LR may have, for example, a structure in which multiple hollow particles are dispersed in an organic polymer resin. The low refractive layer LR may be formed of a single layer or multiple layers.

In an embodiment, the display panel DP may further include a base layer BL disposed on the color filter layer CFL. The base layer BL may be a member that provides a reference surface on which the color filter layer CFL, the low refractive layer LR, the light control layer CCL, etc. are disposed. The base layer BL may be a glass substrate, a metal substrate, a plastic substrate, etc. However, the disclosure is not limited thereto, and the base layer BL may be an inorganic layer, an organic layer, or a composite material layer. Unlike the configuration illustrated, in an embodiment, the base layer BL may be omitted.

Although not illustrated, an anti-reflection layer may be disposed on the base layer BL. The anti-reflection layer may be a layer that reduces reflectance of external light incident from the outside. The anti-reflection layer may be a layer that selectively transmits light emitted from the display panel DP. In an embodiment, the anti-reflection layer may be a single layer including a dye and/or pigment dispersed in a base resin. The anti-reflection layer may be provided as a continuous layer that entirely overlaps the first to third pixel regions PXA-R, PXA-B, and PXA-G (see FIG. 4A) in a plan view.

The anti-reflection layer may not include a polarizing layer. Accordingly, the light passing through the anti-reflection layer and incident on the display element layer DP-LED may be unpolarized light. The display element layer DP-LED may receive the unpolarized light from the upper portion of the anti-reflection layer.

The display panel DP of an embodiment may include a lower panel including the display element layer DP-LED and an upper panel (an optical structure layer OSL) including the color filter layer CFL, and in an embodiment, a filling layer FML may be disposed between the lower panel and the upper panel OSL. In an embodiment, the filling layer FML may fill a space between the display element layer DP-LED and the light control layer CCL. The filling layer FML may be disposed (e.g., directly disposed) on the encapsulation layer TFE, and the second barrier layer CAP2 may be disposed (e.g., directly disposed) on the filling layer FML. The bottom surface of the filling layer FML may be in contact with the top surface of the encapsulation layer TFE, and the top surface of the filling layer FML may be in contact with the bottom surface of the second barrier layer CAP2.

The filling layer FML may serve as a buffer between the display element layer DP-LED and the light control layer CCL. In an embodiment, the filling layer FML may function to absorb an impact, and may increase the strength of the display panel DP. The filling layer FML may be formed of a filling resin including a polymer. For example, the filling layer FML may be formed of a filling resin such as an acrylic-based resin, an epoxy-based resin, or the like.

Referring to FIG. 4A, the display panel DP may include a base substrate BS, a circuit element layer DP-CL disposed on the base substrate BS. The circuit element layer DP-CL may be disposed on the base substrate BS. The circuit element layer DP-CL may include an insulation layer, a semiconductor pattern, a conductive pattern, a signal line, etc. The insulation layer, the semiconductor layer, and the conductive layer may be formed on the base substrate BS by coating or vapor deposition, and the insulation layer, the semiconductor layer, and the conductive layer may be optionally patterned through multiple photolithography processes. Thereafter, the semiconductor pattern, the conductive pattern, and the signal line, which are included in the circuit element layer DP-CL, may be formed. In an embodiment, the circuit element layer DP-CL may include a transistor, a buffer layer, and multiple insulation layers.

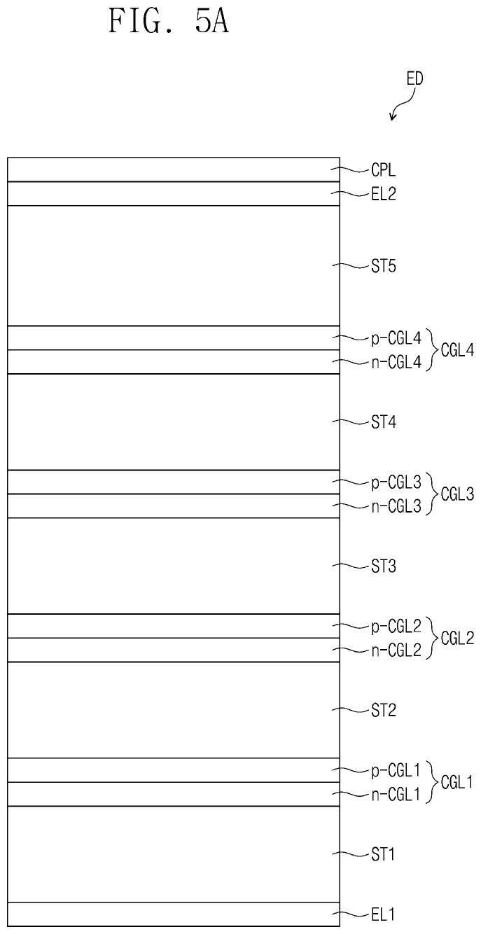

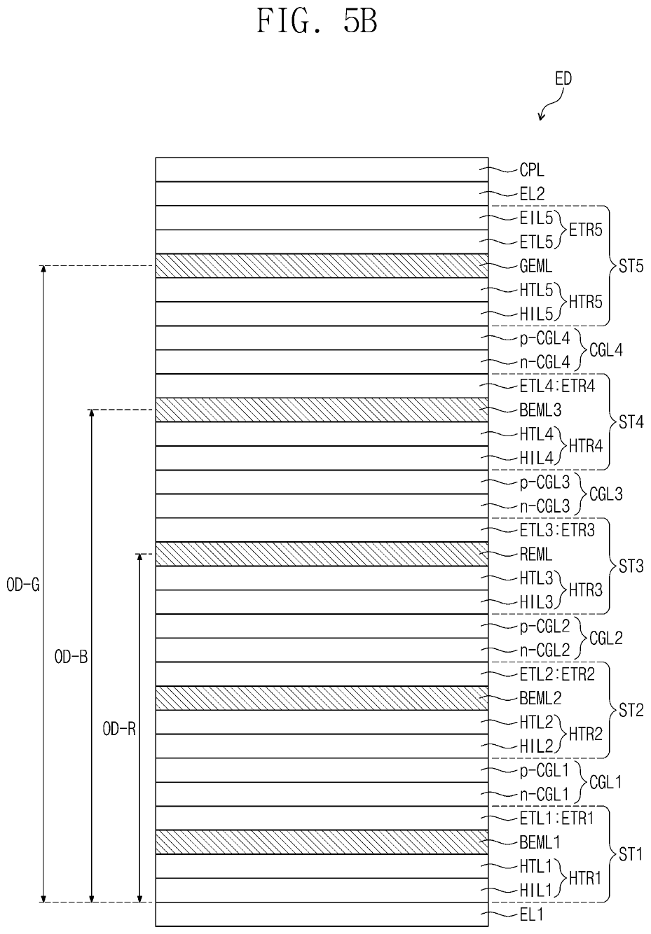

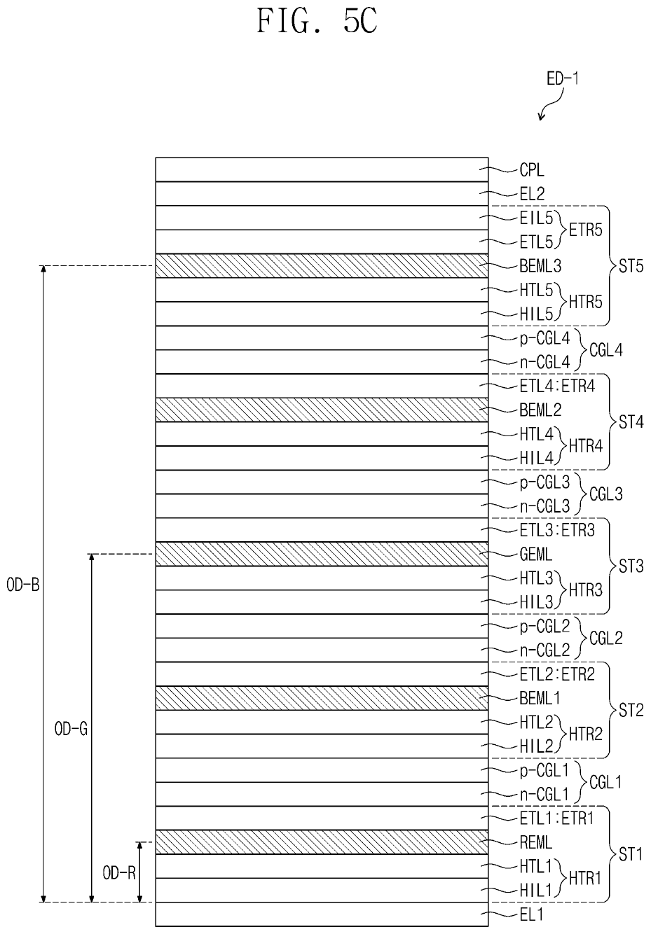

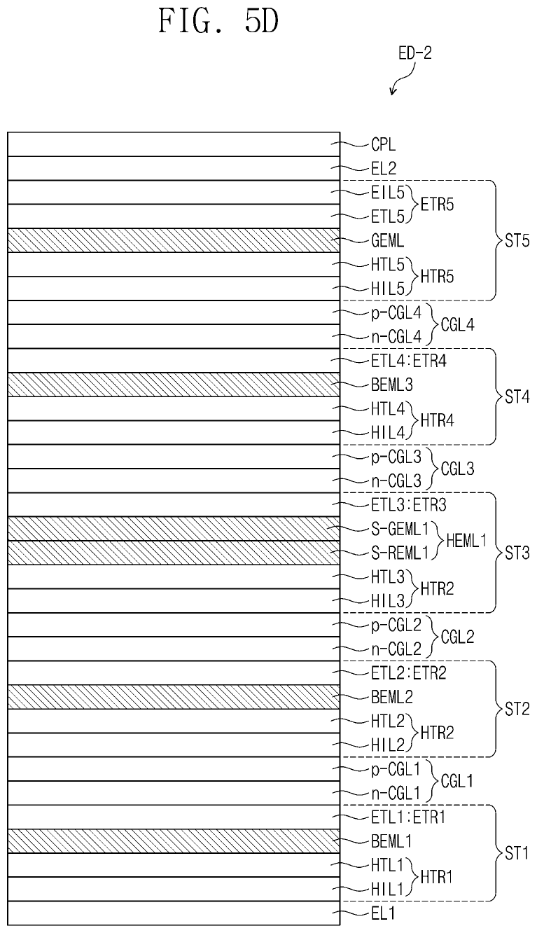

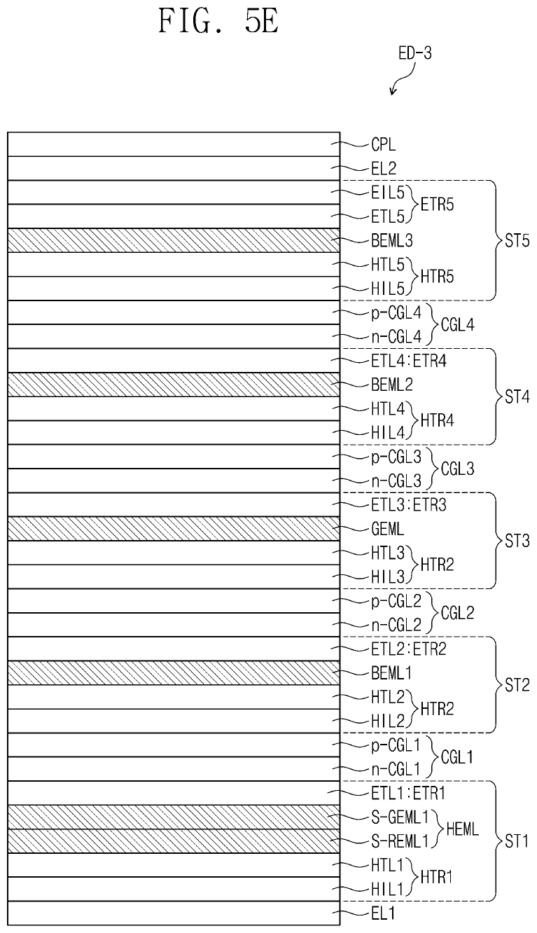

The light emitting elements ED according to embodiments each may include a first electrode EL1, a second electrode EL2 facing the first electrode EL1, and five light emitting stacks ST1, ST2, ST3, ST4, and ST5 disposed between the first electrode EL1 and the second electrode EL2. Each of the five light emitting stacks ST1, ST2, ST3, ST4, and ST5 included in the light emitting element ED may include an organic light emitting material as a light emitting material. Each of the five light emitting stacks ST1, ST2, ST3, ST4, and ST5 included in the light emitting element ED may include a hole transport region, an emission layer, and an electron transport region. The light emitting element ED may further include a capping layer CPL (see FIG. 5A) disposed on the upper portion of the second electrode EL2.

The pixel defining film PDL may be disposed on the circuit element layer DP-CL, and may cover a portion of the first electrode EL1. A light emitting opening OH may be defined in the pixel defining film PDL. The light emitting opening OH of the pixel defining film PDL may expose at least a portion of the first electrode EL1. In an embodiment, the light emitting regions EA1, EA2, and EA3 may correspond to the portion of the first electrode EL1 that is exposed by the light emitting opening OH.

The display element layer DP-LED may include a first light emitting region EA1, a second light emitting region EA2, and a third light emitting region EA3. The first light emitting region EA1, the second light emitting region EA2, and the third light emitting region EA3 may be regions divided by the pixel defining film PDL. The first light emitting region EA1, the second light emitting region EA2, and the third light emitting region EA3 may correspond to the first pixel region PXA-R, the second pixel region PXA-B, and the third pixel region PXA-G, respectively.

The light emitting regions EA1, EA2, and EA3 may overlap the pixel regions PXA-R, PXA-B, and PXA-G and may not overlap the bank well region BWA in a plan view. In a plan view, the areas of the pixel regions PXA-R, PXA-B, and PXA-G divided by the bank BMP may be greater than the areas of the light emitting regions EA1, EA2, and EA3 divided by the pixel defining film PDL.

In the light emitting element ED, the first electrode EL1 may be disposed on the circuit element layer DP-CL. The first electrode EL1 may be an anode or a cathode. The first electrode EL1 may be a pixel electrode. The first electrode EL1 may be a transmissive electrode, a transflective electrode, or a reflective electrode.

In the display panel DP of an embodiment, the five light emitting stacks ST1, ST2, ST3, ST4, and ST5 may be disposed between the first electrode EL1 and the second electrode EL2 of the light emitting element ED.

Each of the five light emitting stacks ST1, ST2, ST3, ST4, and ST5 may be commonly disposed in the first to third pixel regions PXA-R, PXA-B, and PXA-G. Each of the five light emitting stacks ST1, ST2, ST3, ST4, and ST5 overlapping the first to third pixel regions PXA-R, PXA-B, and PXA-G may have an integral shape. However, the disclosure is not limited thereto, and at least one of the five light emitting stacks ST1, ST2, ST3, ST4, and ST5 may be formed separately in each of the first to third pixel regions PXA-R, PXA-B, and PXA-G. In an embodiment, at least one of the five light emitting stacks ST1, ST2, ST3, ST4, and ST5 may be patterned in the light emitting opening OH, and may be formed separately in each of the first to third pixel regions PXA-R, PXA-B, and PXA-G. The light emitting stacks included in the light emitting element ED will be described in detail below.

The second electrode EL2 may be provided on the five light emitting stacks ST1, ST2, ST3, ST4, and ST5. The second electrode EL2 may be a common electrode. The second electrode EL2 may be a cathode or an anode, but the disclosure is not limited thereto. For example, in case that the first electrode EL1 is an anode, the second electrode EL2 may be a cathode, and in case that the first electrode EL1 is a cathode, the second electrode EL2 may be an anode. The second electrode EL2 may be a transmissive electrode, a transflective electrode, or a reflective electrode.

The encapsulation layer TFE may be disposed on the light emitting element ED. For example, the encapsulation layer TFE of an embodiment may be disposed on the second electrode EL2. In case that the light emitting element ED includes the capping layer CPL (see FIG. 5A), the encapsulation layer TFE may be disposed on the capping layer CPL. As described above, the encapsulation layer TFE may include at least one organic film and at least one inorganic film, and the inorganic film and the organic film may be alternately stacked each other.

The display panel DP of an embodiment may include an optical structure layer OSL disposed on the display element layer DP-LED. The optical structure layer OSL may include a light control layer CCL, a color filter layer CFL, and a base layer BL.

The light control layer CCL may include a light conversion body. The light conversion body may be a quantum dot, a phosphor, or the like. The light conversion body may emit provided light by converting the wavelength of the light. For example, the light control layer CCL may be a layer containing the quantum dot or a layer containing the phosphor in at least a portion of the light control layer CCL.

The light control layer CCL may include multiple light control patterns CCP-R, CCP-B, and CCP-G. The light control patterns CCP-R, CCP-B, and CCP-G may be spaced apart from each other. The light control patterns CCP-R, CCP-B, and CCP-G may be spaced apart from each other by the bank BMP. The light control patterns CCP-R, CCP-B, and CCP-G may be disposed in the bank opening BW-OH defined in the bank BMP. However, the disclosure is not limited thereto. Although FIG. 4A illustrates that the bank BMP has a rectangular shape in a cross-sectional view and does not overlap the light control patterns CCP-R, CCP-B, and CCP-G in a plan view, the disclosure is not limited thereto, and the edges of the light control patterns CCP-R, CCP-B, and CCP-G may at least partially overlap the bank BMP in a plan view. The bank BMP may have a trapezoidal shape in a cross-sectional view. The bank BMP may have a shape in which a width in a cross-sectional view increases as the bank BMP is closer to the display element layer DP-LED.

The light control patterns CCP-R, CCP-B, and CCP-G may be portions that convert a wavelength of light provided from the display element layer DP-LED or transmit the provided light. The light control patterns CCP-R, CCP-B, and CCP-G may be formed by an inkjet process. A liquid ink composition may be provided in the bank opening BW-OH, and the provided ink composition may be polymerized by a thermal curing process or a photo curing process to form light control patterns CCP-R, CCP-B, and CCP-G.

The light control layer CCL may include a first light control pattern CCP-R that transmits red light, which is first light, a second light control pattern CCP-B that transmits blue light, which is second light, and a third light control pattern CCP-G that transmits green light, which is third light. The light control layer CCL may include a first light control pattern CCP-R that converts source light provided from the light emitting element ED into the first light, a second light control pattern CCP-B that converts the source light into the second light, and a third light control pattern CCP-G that converts the source light into the third light. Each of the light control patterns CCP-R, CCP-B, and CCP-G may include quantum dots that convert the source light into light having a specific wavelength.

The light control layer CCL may further include scatterers. The first light control pattern CCP-R may include first quantum dots and scatterers, the third light control pattern CCP-G may include second quantum dots and scatterers, and the second light control pattern CCP-B may not include a quantum dot and may include scatterers.

Each of the first light control pattern CCP-R, the second light control pattern CCP-B, and the third light control pattern CCP-G may include a base resin that disperses quantum dots and scatterers.

The light control layer CCL may include the first barrier layer CAP1 disposed on a surface of the light control pattern. The light control layer CCL may include the first barrier layer CAP1 spaced apart from the display element layer DP-LED with the light control pattern CCP-R interposed between the first barrier layer CAP1 and the display element layer DP-LED, and the second barrier layer CAP2 adjacent to the display element layer DP-LED.

In the display panel DP, the optical structure layer OSL may include the color filter layer CFL disposed on the light control layer CCL. The color filter layer CFL may include color filters CF1, CF2, and CF3. The color filter layer CFL may include the first color filter CF1 that transmits the first light, the second color filter CF2 that transmits the source light, and the third color filter CF3 that transmits the second light. In an embodiment, the first color filter CF1 may be a red filter, the second color filter CF2 may be a blue filter, and the third color filter CF3 may be a green filter.

Each of the filters CF1, CF2, and CF3 may include a polymeric photosensitive resin and a colorant. The first color filter CF1 may include a red colorant, the second color filter CF2 may include a blue colorant, and the third color filter CF3 may include a green colorant. The first color filter CF1 may include a red pigment or dye, the second color filter CF2 may include a blue pigment or dye, and the third color filter CF3 may include a green pigment or dye.

The first to third color filters CF1, CF2, and CF3 may be disposed to correspond to the first pixel region PXA-R, the second pixel region PXA-B, and the third pixel region PXA-G, respectively. The first to third color filters CF1, CF2, and CF3 may be disposed to correspond to the first to third light control patterns CCP-R, CCP-B, and CCP-G, respectively.

Multiple color filters CF1, CF2, and CF3, which transmit different light, may be disposed to overlap the peripheral region NPXA disposed between the pixel regions PXA-R, PXA-B, and PXA-G. The color filters CF1, CF2, and CF3 may overlap each other in the third direction DR3, which is the thickness direction, so that boundaries between adjacent light emitting regions PXA-R, PXA-B, and PXA-G may be distinguished. Unlike the configuration illustrated, the color filter layer CFL may include a light shielding part (not shown) that defines a boundary between adjacent color filters CF1, CF2, and CF3. The light shielding part (not shown) may be formed of a blue filter or may include an organic light shielding material or an inorganic light shielding material including a black pigment or dye.

The optical structure layer OSL may include a low refractive layer LR disposed between the light control layer CCL and the color filter layer CFL. The low refractive layer LR may be disposed between the light control patterns CCP-R, CCP-B, and CCP-G and the color filters CF1, CF2, and CF3. The low refractive layer LR may be disposed on the upper portion of the light control layer CCL and prevent the light control patterns CCP-R, CCP-B, and CCP-G from being exposed to moisture/oxygen. The low refractive layer LR may be disposed between the light control patterns CCP-R, CCP-B, and CCP-G and the color filters CF1, CF2, and CF3 or may serve as an optical functional layer, for example, increasing light extraction efficiency or preventing reflected light from being incident to the light control layer CCL. The low refractive layer LR may be a layer having a small refractive index compared to adjacent layers.

The low refractive layer LR may include at least one inorganic layer. For example, the low refractive layer LR may include silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride, or a thin metal film which secures light transmittance. However, the disclosure is not limited thereto, and the low refractive layer LR may include an organic film. The low refractive layer LR may have, for example, a structure in which multiple hollow particles are dispersed in an organic polymer resin. The low refractive layer LR may be formed of a single layer or multiple layers.

In an embodiment, the optical structure layer OSL may further include a base layer BL disposed on the color filter layer CFL. The base layer BL may be a member configured to provide a base surface on which the color filter layer CFL, the light control layer CCL, and the like are disposed. The base layer BL may be a glass substrate, a metal substrate, a plastic substrate, etc. However, the disclosure is not limited thereto, and the base layer BL may be an inorganic layer, an organic layer, or a composite material layer. Unlike the configuration illustrated, in an embodiment, the base layer BL may be omitted.

FIGS. 4B and 4C are each schematic cross-sectional view of the display panel according to an embodiment of the disclosure. FIGS. 4B and 4C each schematically illustrates display panels DP_1 and DP_2 different from the display panel DP of the embodiment illustrated in FIG. 4A.

Referring to FIG. 4B, the display panel DP_1 according to an embodiment may include a lower panel including a base substrate BS, a circuit element layer DP-CL disposed on the base substrate BS, a display element layer DP-LED disposed on the circuit element layer DP-CL, and an optical structure layer OSL-1 disposed on the lower panel. The optical structure layer OSL-1 in the display panel DP_1 according to an embodiment may include a light control layer CCL-1, a low refractive layer LR-1, a color filter layer CFL-1, and a base layer BL-1 which are sequentially disposed on the thin-film encapsulation layer TFE. The optical structure layer OSL-1 may include a first barrier layer CAP1 and a second barrier layer CAP2 disposed on the upper and lower surfaces of the light control layer CCL-1, respectively.

The light control layer CCL-1 may be disposed on the display element layer DP-LED and the thin film encapsulation layer TFE with the second barrier layer CAP2 interposed between the light control layer CCL-1 and the thin film encapsulation layer TFE. The light control layer CCL-1 may include multiple banks BMP and light control patterns CCP-B, CCP-G, and CCP-R disposed between the banks BMP. The low refractive layer LR may be disposed on the light control layer CCL-1.

The color filter layer CFL-1 may include multiple color filters CF1, CF2, and CF3 and a light shielding part BM.

Compared with the display panel DP illustrated in FIG. 4A, the display panel DP_1 according to an embodiment illustrated in FIG. 4B is an embodiment in which the light control layer CCL-1, the low refractive layer LR, and the color filter layer CFL-1 are disposed on the top surface of the thin film encapsulation layer TFE as a base surface. For example, the light control patterns CCP-B, CCP-G, and CCP-R of the light control layer CCL-1 may be formed on the thin film encapsulation layer TFE through a continuous process, and the color filters CF1, CF2, and CF3 of the color filter layer CFL-1 may be sequentially formed on the light control layer CCL-1 through a continuous process. The light control layer CCL-1 may be formed by using the top surface of the second barrier layer CAP2 disposed on the thin film encapsulation layer TFE as a base surface, and may have a shape turned upside down from the shape of the light control layer CCL illustrated in FIG. 4A. For example, each of the banks BMP and the light control patterns CCP-B, CCP-G, and CCP-R may have a shape turned upside down from the shape illustrated in FIG. 4A. The color filter layer CFL-1 may be formed by using the top surface of the light control layer CCL-1 as a base surface, and may have a shape different from that illustrated in FIG. 4A.

In the color filter layer CFL-1 of an embodiment, the light shielding part BM may be a black matrix. The light shielding part BM may include an organic light shielding material or an inorganic light shielding material containing a black pigment or dye. The light shielding unit BM may prevent light leakage, and may define boundaries between the adjacent color filters CF-B, CF-G, and CF-R.

Referring to FIG. 4C, compared with the display panel DP illustrated in FIG. 4A, the pixel regions PXA-R, PXA-B, PXA-G, and PXA-W may further include a white pixel region PXA-W in the display panel DP_2 according to an embodiment illustrated in FIG. 4C. In the display panel DP_2 of an embodiment, the light emitting element ED may generate white light, and the white pixel region PXA-W may be a region through which light generated by the light emitting element ED is transmitted without being converted. FIG. 4C illustrates the areas of the pixel regions PXA-R, PXA-B, PXA-G, and PXA-W in a plan view are the same, but the disclosure is not limited thereto, and the white pixel region PXA-W may have an area different from the area of each of other pixel regions PXA-R, PXA-B, and PXA-G. White light emitted from the white pixel region PXA-W may be a mixture of light in various wavelengths. The display element layer DP-LED may include a fourth light emitting region EA4 corresponding to the white pixel region PXA-W.

The light control layer CCL-2 of the display panel DP_2 according to an embodiment may further include a fourth light control pattern CCP-T in addition to the first light control pattern CCP-R, the second light control pattern CCP-B, and the third light control pattern CCP-G. The fourth light control pattern CCP-T may overlap the white pixel region PXA-W in a plan view. A bank BMP may be provided between the fourth light control pattern CCP-T and adjacent light control pattern. A light emitter such as a quantum dot may not be included in the fourth light control pattern CCP-T. The fourth light control pattern CCP-T may be a transmission part that transmits the incident light without converting the wavelength of the incident light. The fourth light control pattern CCP-T may include only scatterers dispersed in the base resin. The same description as described above may be applied to the description of the base resin and the scatterers.

In the color filter layer CFL-2 of the display panel DP_2 according to an embodiment, an opening overlapping the white pixel region PXA-W in a plan view may be defined. The filters CF1, CF2, and CF3 included in the color filter layer CFL-2 may not overlap the white pixel region PXA-W in a plan view. For example, an opening T-OP corresponding to the white pixel region PXA-W may be defined in the second color filter CF2, and accordingly, the filters CF1, CF2, and CF3 may not overlap the white pixel region PXA-W. However, the disclosure is not limited thereto, and the second color filter CF2 may overlap the white pixel region PXA-W in a plan view, and the second color filter CF2 may be formed of a transparent photosensitive resin.

FIGS. 5A to 5E are schematic cross-sectional views schematically illustrating light emitting elements according to embodiments of the disclosure. Hereinafter, light emitting elements ED, ED-1, ED-2, and ED-3 according to an embodiment of the disclosure will be described with reference to FIGS. 5A to 5E.

Referring to FIG. 5A, the light emitting element ED of an embodiment may include a first electrode EL1, a second electrode EL2 facing the first electrode EL1, and multiple light emitting stacks ST1, ST2, ST3, ST4, and ST5 disposed between the first electrode EL1 and the second electrode EL2. The light emitting stacks ST1, ST2, ST3, ST4, and ST5 may include a first light emitting stack ST1, a second light emitting stack ST2, a third light emitting stack ST3, a fourth light emitting stack ST4, and a fifth light emitting stack ST5. Each of the first light emitting stack ST1, the second light emitting stack ST2, the third light emitting stack ST3, the fourth light emitting stack ST4, and the fifth light emitting stack ST5 may include an emission layer. Although FIG. 5A schematically illustrates that the light emitting element ED includes five light emitting stacks ST1, ST2, ST3, ST4, and ST5, the disclosure is not limited thereto, and the light emitting element ED may include more than five light emitting stacks.

The light emitting element ED according to an embodiment may include charge generation layers CGL1, CGL2, CGL3, and CGL4 disposed between sequential pairs of the light emitting stacks ST1, ST2, ST3, ST4, and ST5, respectively. The light emitting element ED according to an embodiment may include a first charge generation layer CGL1 disposed between a first light emitting stack ST1 and a second light emitting stack ST2, a second charge generation layer CGL2 disposed between a second light emitting stack ST2 and a third light emitting stack ST3, a third charge generation layer CGL3 disposed between a third light emitting stack ST3 and a fourth light emitting stack ST4, and a fourth charge generation layer CGL4 disposed between a fourth light emitting stack ST4 and a fifth light emitting stack ST5.

The charge generation layers CGL1, CGL2, CGL3, and CGL4 may generate charges (electrons and holes) by forming a complex through an oxidation-reduction reaction in case that a voltage is applied to the light emitting element ED. The charge generation layers CGL1, CGL2, CGL3, and CGL4 may provide the generated charges to each of adjacent light emitting stacks ST1, ST2, ST3, ST4, and ST5. The charge generation layers CGL1, CGL2, CGL3, and CGL4 may double the efficiency of currents generated in each of the adjacent light emitting stacks ST1, ST2, ST3, ST4, and ST5, and may serve to adjust the balance of charges between the adjacent light emitting stacks ST1, ST2, ST3, ST4, and ST5.

The charge generation layers CGL1, CGL2, CGL3, and CGL4 may each have a layer structure in which n-type charge generation layers n-CGL1, n-CGL2, n-CGL3, and n-CGL4 abut p-type charge generation layers p-CGL1, p-CGL2, p-CGL3, and p-CGL4. The first charge generation layer CGL1 may have a layer structure in which a first n-type charge generation layer n-CGL1 abuts a first p-type charge generation layer p-CGL1. The second charge generation layer CGL2 may have a layer structure in which a second n-type charge generation layer n-CGL2 abuts a second p-type charge generation layer p-CGL2. The third charge generation layer CGL3 may have a layer structure in which a third n-type charge generation layer n-CGL3 abuts a third p-type charge generation layer p-CGL3. The fourth charge generation layer CGL4 may have a layer structure in which a fourth n-type charge generation layer n-CGL4 abuts a fourth p-type charge generation layer p-CGL4.

The n-type charge generation layers n-CGL1, n-CGL2, n-CGL3, and n-CGL4 may be charge generation layers that provide electrons to adjacent light emitting stacks. The n-type charge generation layers n-CGL1, n-CGL2, n-CGL3, and n-CGL4 may be layers in which the n-dopant is doped in a base material. The p-type charge generation layers p-CGL1, p-CGL2, p-CGL3, and p-CGL4 may be charge generation layers that provide holes to adjacent light emitting stacks. Although not illustrated, buffer layers may further be disposed between sequential pairs of the n-type charge generation layers n-CGL1, n-CGL2, n-CGL3, and n-CGL4 and the p-type charge generation layers p-CGL1, p-CGL2, p-CGL3, and p-CGL4, respectively.

The charge generation layers CGL1, CGL2, CGL3, and CGL4 may each include an n-type aryl amine-based material or a p-type metal oxide. For example, charge generation layers CGL1, CGL2, CGL3, and CGL4 may each include a charge generation compound that is formed of an aryl amine-based organic compound, a metal, an oxide, a carbide, or a fluoride of the metal, or a mixture thereof.

For example, the aryl amine-based organic compound may be α-NPD, 2-TNATA, TDATA, MTDATA, sprio-TAD, or sprio-NPB. For example, the metal may be cesium (Cs), molybdenum (Mo), vanadium (V), titanium (Ti), tungsten (W), barium (Ba), or lithium (Li). Also, for example, the oxide, carbide, or fluoride of the metal may be Re₂O₇, MoO₃, V₂O₅, WO₃, TiO₂, Cs₂CO₃, BaF, LiF, or CsF.

Each of the first light emitting stack ST1, the second light emitting stack ST2, the third light emitting stack ST3, the fourth light emitting stack ST4, and the fifth light emitting stack ST5 may include an emission layer. The first light emitting stack ST1, the second light emitting stack ST2, the third light emitting stack ST3, the fourth light emitting stack ST4, and the fifth light emitting stack ST5 may include at least two blue emission layers, at least one green emission layer, and at least one red emission layer. At least two of the first light emitting stack ST1, the second light emitting stack ST2, the third light emitting stack ST3, the fourth light emitting stack ST4, and the fifth light emitting stack ST5 may include blue emission layers, at least one of the first light emitting stack ST1, the second light emitting stack ST2, the third light emitting stack ST3, the fourth light emitting stack ST4, and the fifth light emitting stack ST5 may include a green emission layer, and at least one of the first light emitting stack ST1, the second light emitting stack ST2, the third light emitting stack ST3, the fourth light emitting stack ST4, and the fifth light emitting stack ST5 may include a red emission layer.

The first light emitting stack ST1, the second light emitting stack ST2, the third light emitting stack ST3, the fourth light emitting stack ST4, and the fifth light emitting stack ST5 may include three blue emission layers, one or two green emission layers, and one or two red emission layers. Three of the first light emitting stack ST1, the second light emitting stack ST2, the third light emitting stack ST3, the fourth light emitting stack ST4, and the fifth light emitting stack ST5 may include blue emission layers. The remaining two of the first light emitting stack ST1, the second light emitting stack ST2, the third light emitting stack ST3, the fourth light emitting stack ST4, and the fifth light emitting stack ST5 may include at least one green emission layer, or at least one red emission layer. One of the remaining two light emitting stacks may include at least one green emission layer, and another one of the remaining two light emitting stacks may include at least one red emission layer.

Among the first light emitting stack ST1, the second light emitting stack ST2, the third light emitting stack ST3, the fourth light emitting stack ST4, and the fifth light emitting stack ST5, a light emitting stack including a red emission layer may be disposed adjacent to the first electrode EL1, compared to a light emitting stack including a green emission layer. For example, the light emitting stack including a red emission layer may be a light emitting stack disposed below the light emitting stack including a green emission layer in the light emitting element ED illustrated in FIG. 5A.

A light emitting stack including at least one red emission layer among the first light emitting stack ST1, the second light emitting stack ST2, the third light emitting stack ST3, the fourth light emitting stack ST4, and the fifth light emitting stack ST5 may include a green emission layer together. One light emitting stack including at least one green emission layer among the first light emitting stack ST1, the second light emitting stack ST2, the third light emitting stack ST3, the fourth light emitting stack ST4, and the fifth light emitting stack ST5 may include a red emission layer together.

FIGS. 5B to 5E each schematically illustrate layers included in the light emitting stacks ST1, ST2, ST3, ST4, and ST5 included in the light emitting element according to an embodiment of the disclosure.

Referring to FIG. 5B, the first light emitting stack ST1 may include a first blue emission layer BEML1, the second light emitting stack ST2 may include a second blue emission layer BEML2, the third light emitting stack ST3 may include a first red emission layer REML, the fourth light emitting stack ST4 may include a third blue emission layer BEML3, and the fifth light emitting stack ST5 may include a first green emission layer GEML.

In the light emitting element ED according to an embodiment, each of the blue emission layers BEML1, BEML2, and BEML3 may emit light having a first wavelength. The light having the first wavelength may be light in a blue wavelength region. In an embodiment, the first wavelength may be in a range of about 410 nm to about 480 nm. The blue emission layers BEML1, BEML2, and BEML3 may include an organic material that emits light having a wavelength in a range of about 410 nm to about 480 nm. The blue emission layers BEML1, BEML2, and BEML3 may include, for example, a host and a dopant.

The blue emission layers BEML1, BEML2, and BEML3 may have a single-layered structure. Each of the first blue emission layer BEML1, the second blue emission layer BEML2, and the third blue emission layer BEML3 may have a single-layered structure. The blue emission layers BEML1, BEML2, and BEML3 having a single-layered structure may have a thickness in a range of about 50 Å to about 400 Å. At least some of the blue emission layers BEML1, BEML2, and BEML3 may have a double-layered structure, unlike the configuration illustrated in FIG. 5B. The double-layered structure of at least some of the blue emission layers BEML1, BEML2, and BEML3 may include different host materials, but the disclosure is not limited thereto.

The blue emission layers BEML1, BEML2, and BEML3 may include a host and a dopant. In an embodiment, the blue emission layers BEML1, BEML2, and BEML3 may include a host and a blue dopant that emits light having the first wavelength. The host included in each of the blue emission layers BEML1, BEML2, and BEML3 may be a blue fluorescent host, and the first dopant may be a blue fluorescent dopant.

In the light emitting element ED according to an embodiment, the host included in the blue emission layers BEML1, BEML2, and BEML3 may include one of the materials H1-1 to H1-20 listed below. The host material included in each of the blue emission layers BEML1, BEML2, and BEML3 may include one of the materials H1-1 to H1-20 listed below. However, the host materials included in the blue emission layers BEML1, BEML2, and BEML3 are not limited to the following materials H1-1 to H1-20.

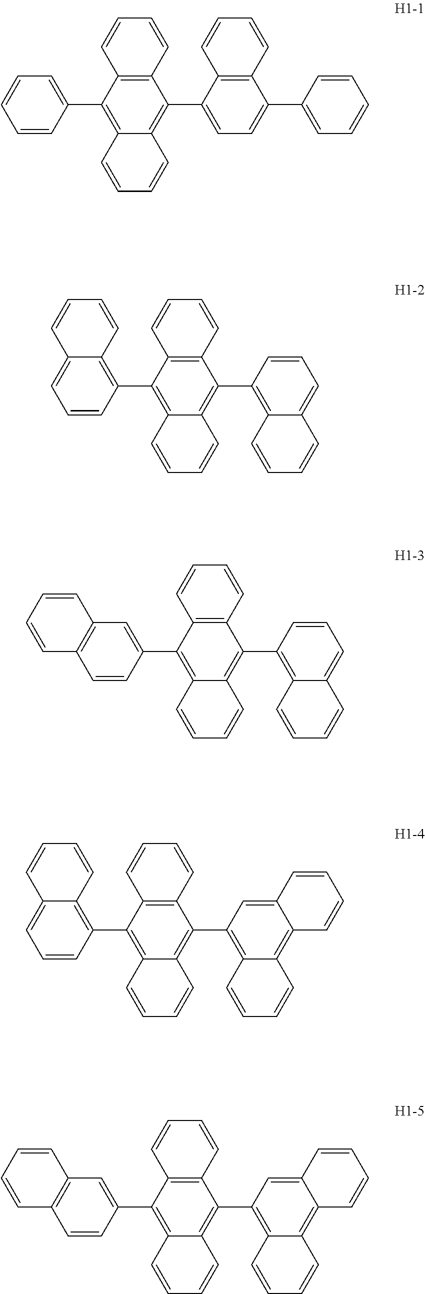

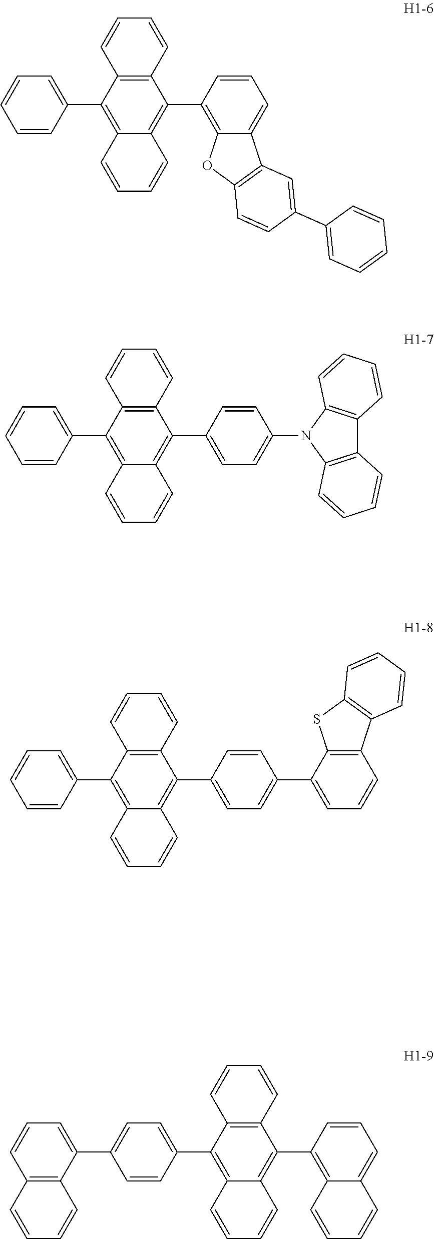

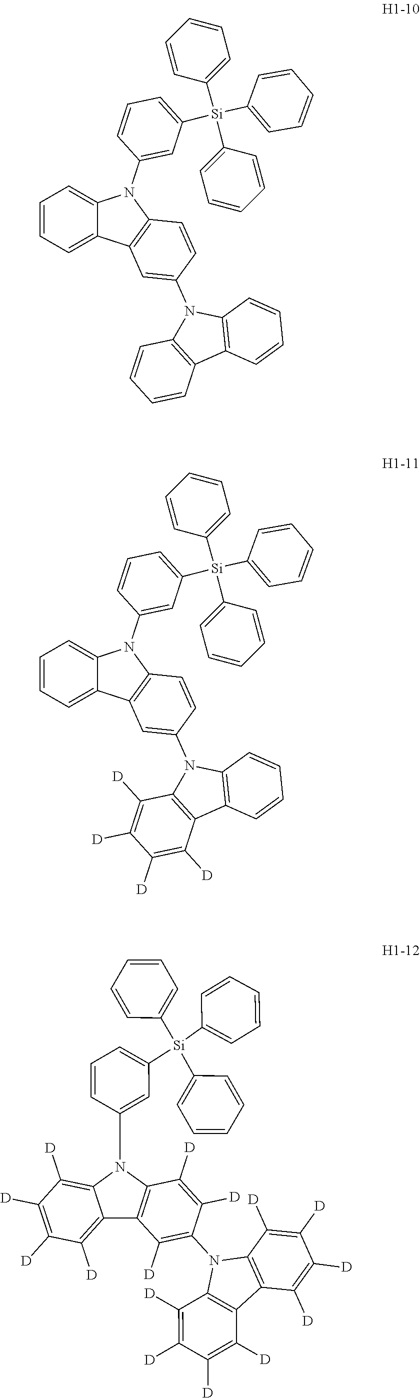 [SMILES: c1ccc([Si](c2ccccc2)(c2ccccc2)c2cccc(-n3c4ccccc4c4cc(-n5c6ccccc6c6ccccc65)ccc43)c2)cc1 ; [2H]c1c([2H])c([2H])c2c(c1[2H])c1ccccc1n2-c1ccc2c(c1)c1ccccc1n2-c1cccc([Si](c2ccccc2)(c2ccccc2)c2ccccc2)c1 ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cccc([Si](c2ccccc2)(c2ccccc2)c2ccccc2)c1]

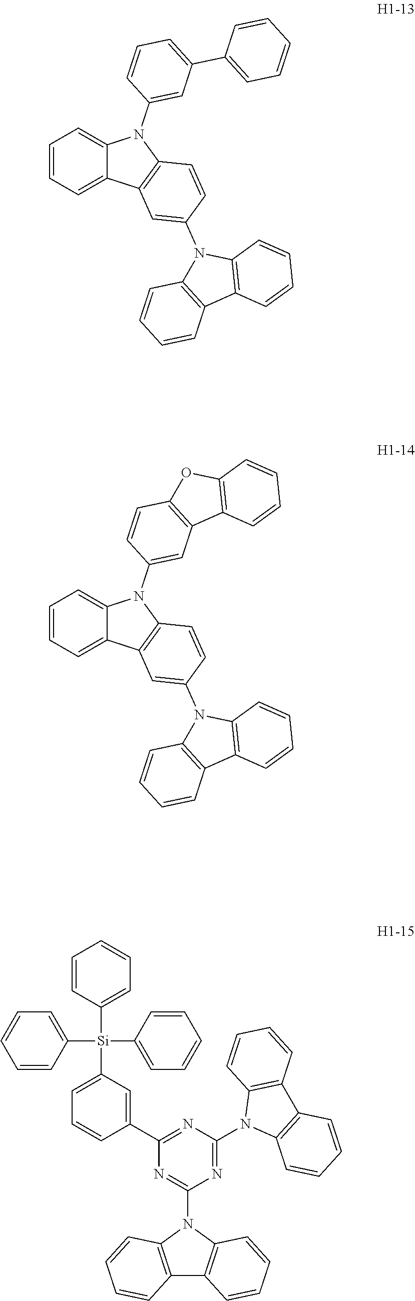 [SMILES: c1ccc(-c2cccc(-n3c4ccccc4c4cc(-n5c6ccccc6c6ccccc65)ccc43)c2)cc1 ; c1ccc2c(c1)oc1ccc(-n3c4ccccc4c4cc(-n5c6ccccc6c6ccccc65)ccc43)cc12 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

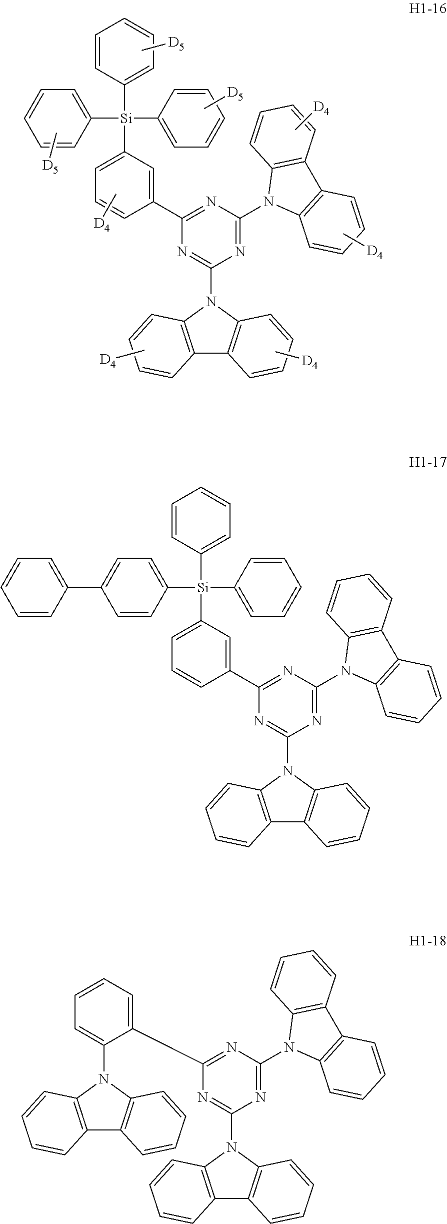

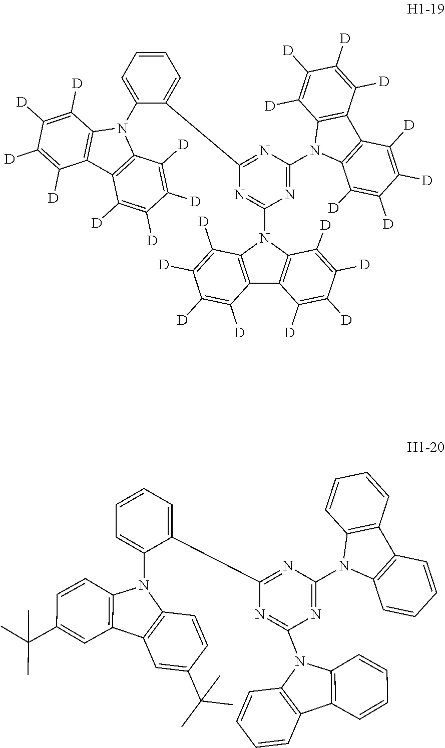 [SMILES: [2H]c1c([2H])c([2H])c2c(c1[2H])c1c([2H])c([2H])c([2H])c([2H])c1n2-c1nc(-c2ccccc2-n2c3c([2H])c([2H])c([2H])c([2H])c3c3c([2H])c([2H])c([2H])c([2H])c32)nc(-n2c3c([2H])c([2H])c([2H])c([2H])c3c3c([2H])c([2H])c([2H])c([2H])c32)n1 ; CC(C)(C)c1ccc2c(c1)c1cc(C(C)(C)C)ccc1n2-c1ccccc1-c1nc(-n2c3ccccc3c3ccccc32)nc(-n2c3ccccc3c3ccccc32)n1]

In an embodiment, the H1-1 to H1-20 compounds may each independently have one of hydrogen atoms substituted with a deuterium atom. For example, H1-1 above may be represented by H1-1D below.

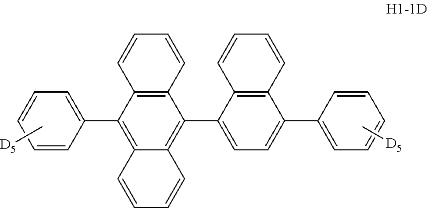

In the light emitting element ED according to an embodiment, the first dopants included in the blue emission layers BEML1, BEML2, and BEML3 may include one of the materials FD1 to FD44 listed below. In an embodiment, the first dopant included in each of the blue emission layers BEML1, BEML2, and BEML3 may include one of the materials FD1 to FD44 listed below. However, the first dopant materials included in the blue emission layers BEML1, BEML2, and BEML3 are not limited to the following materials FD1 to FD44.

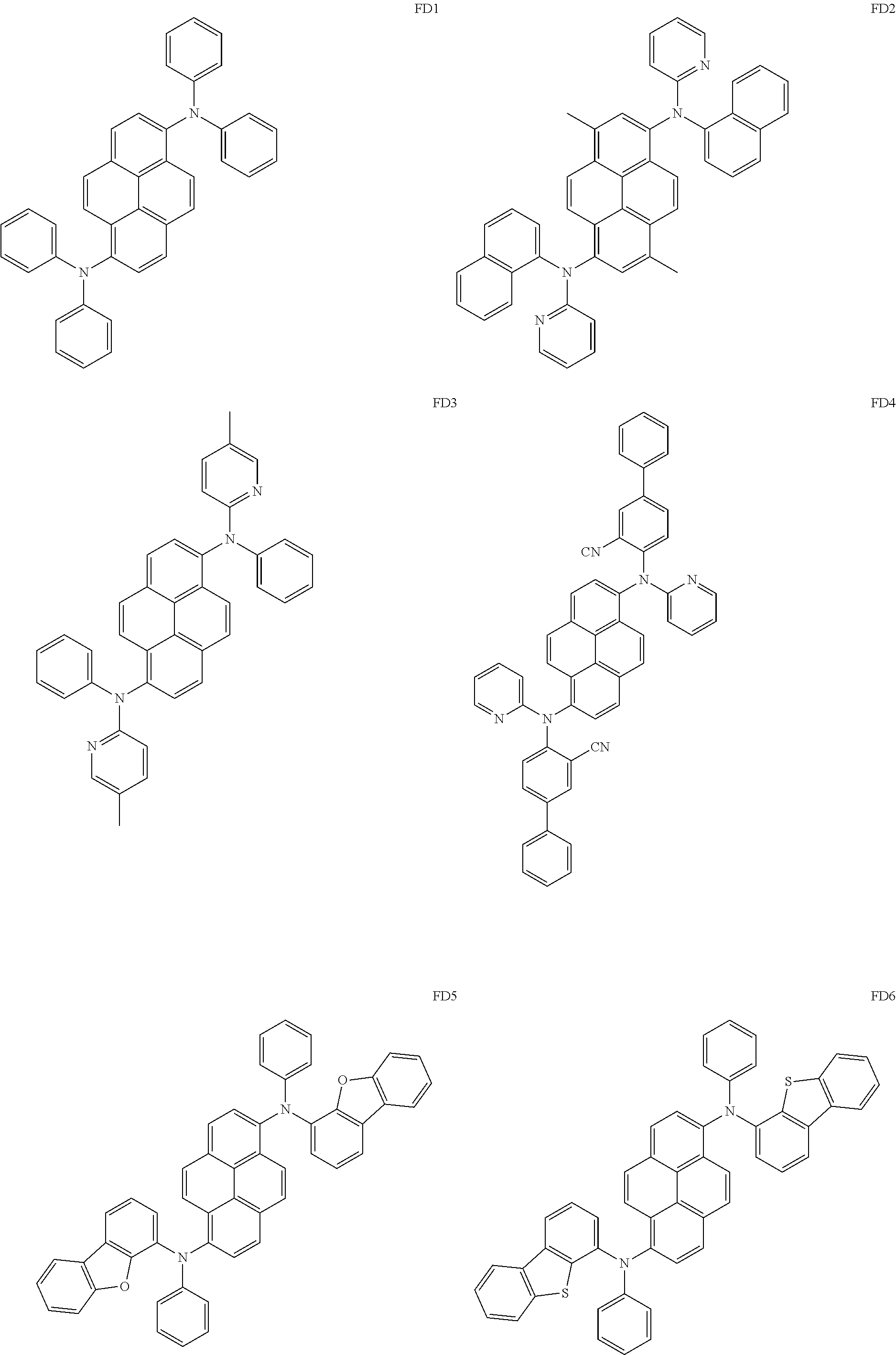

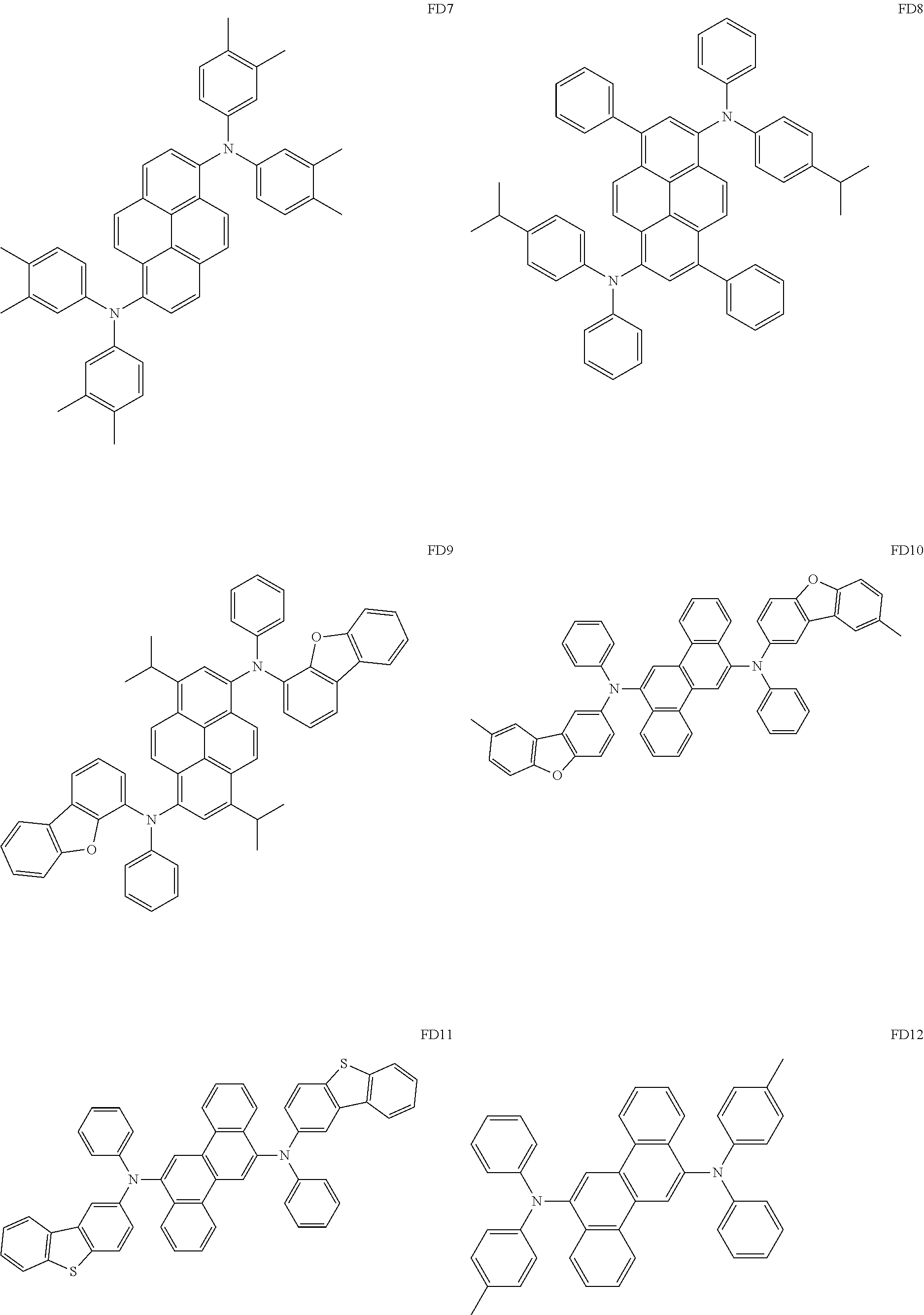

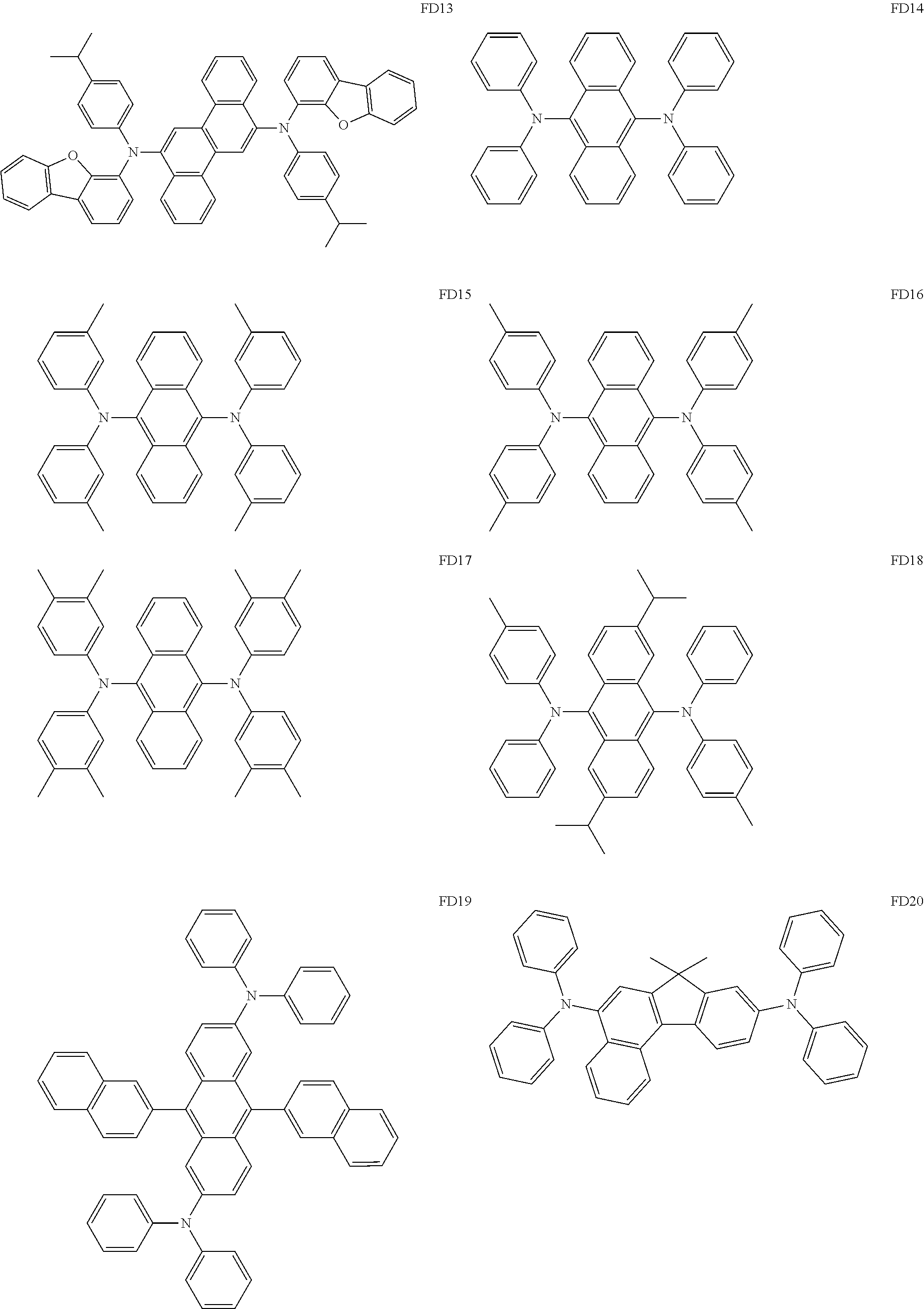

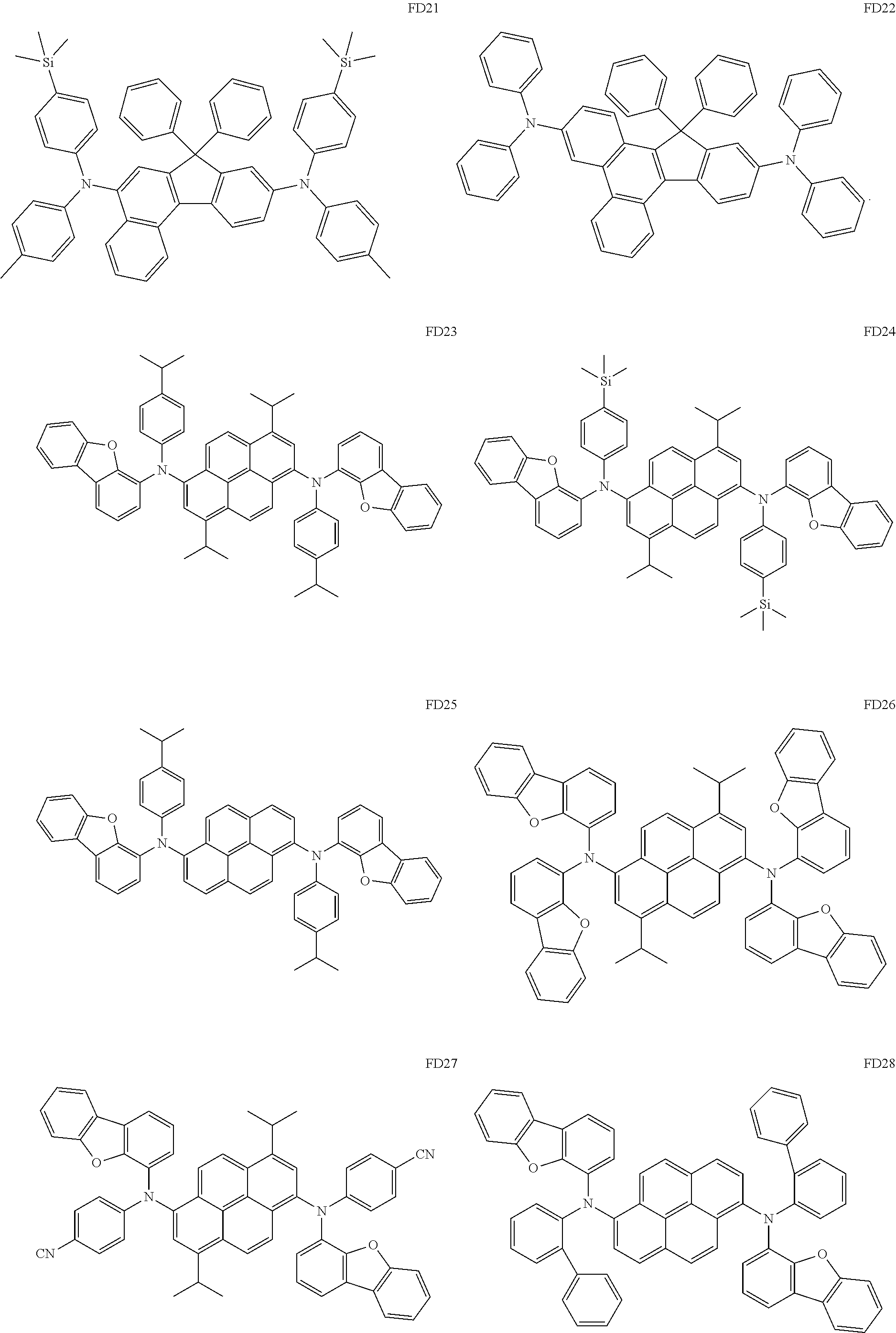

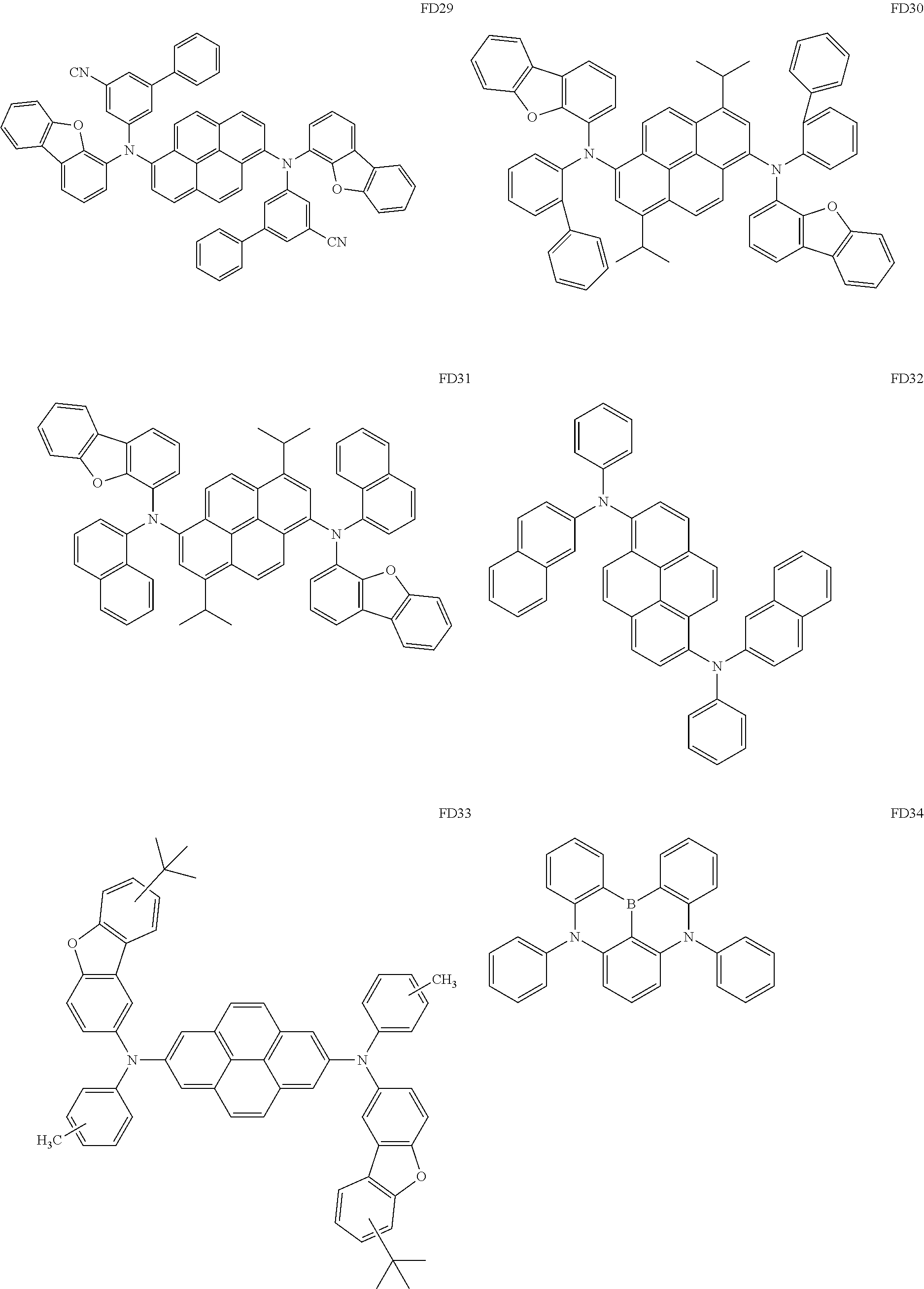

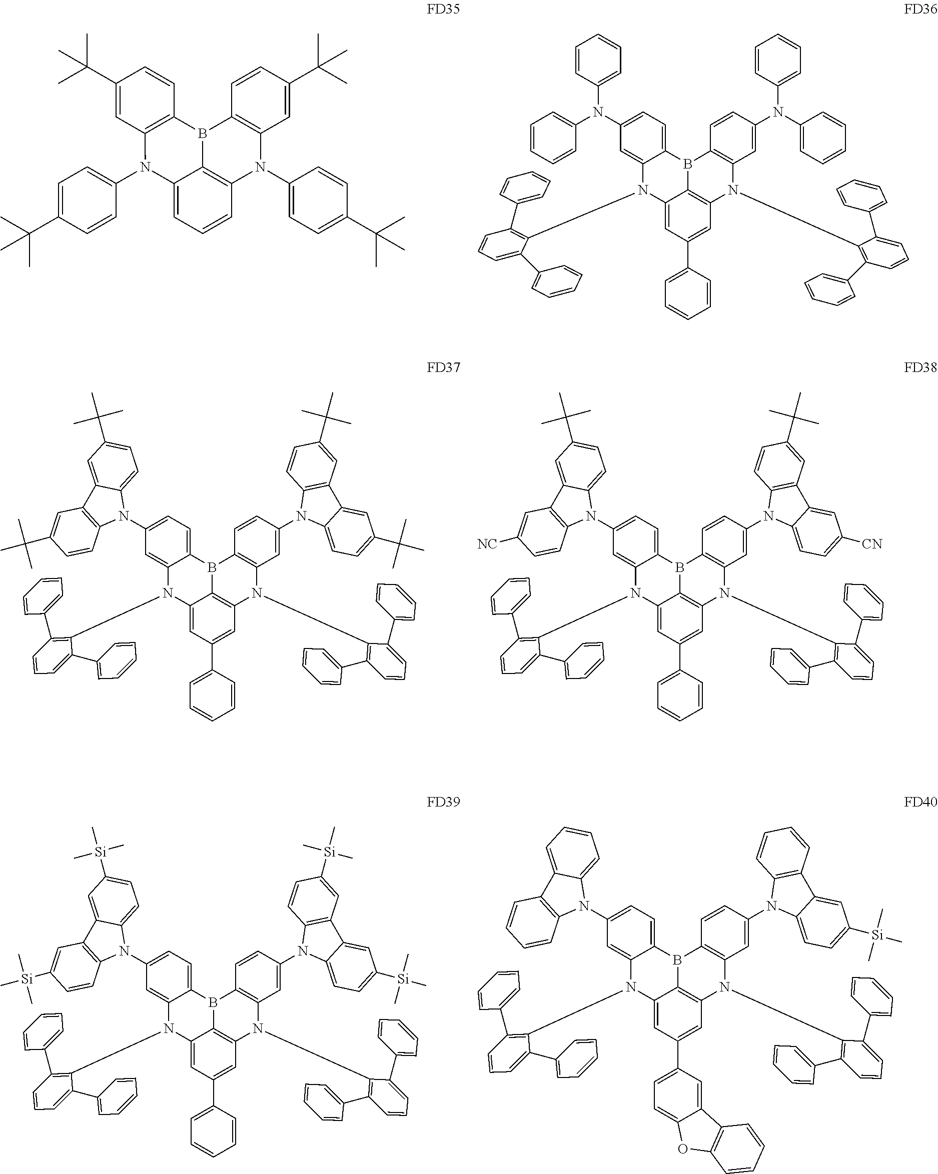

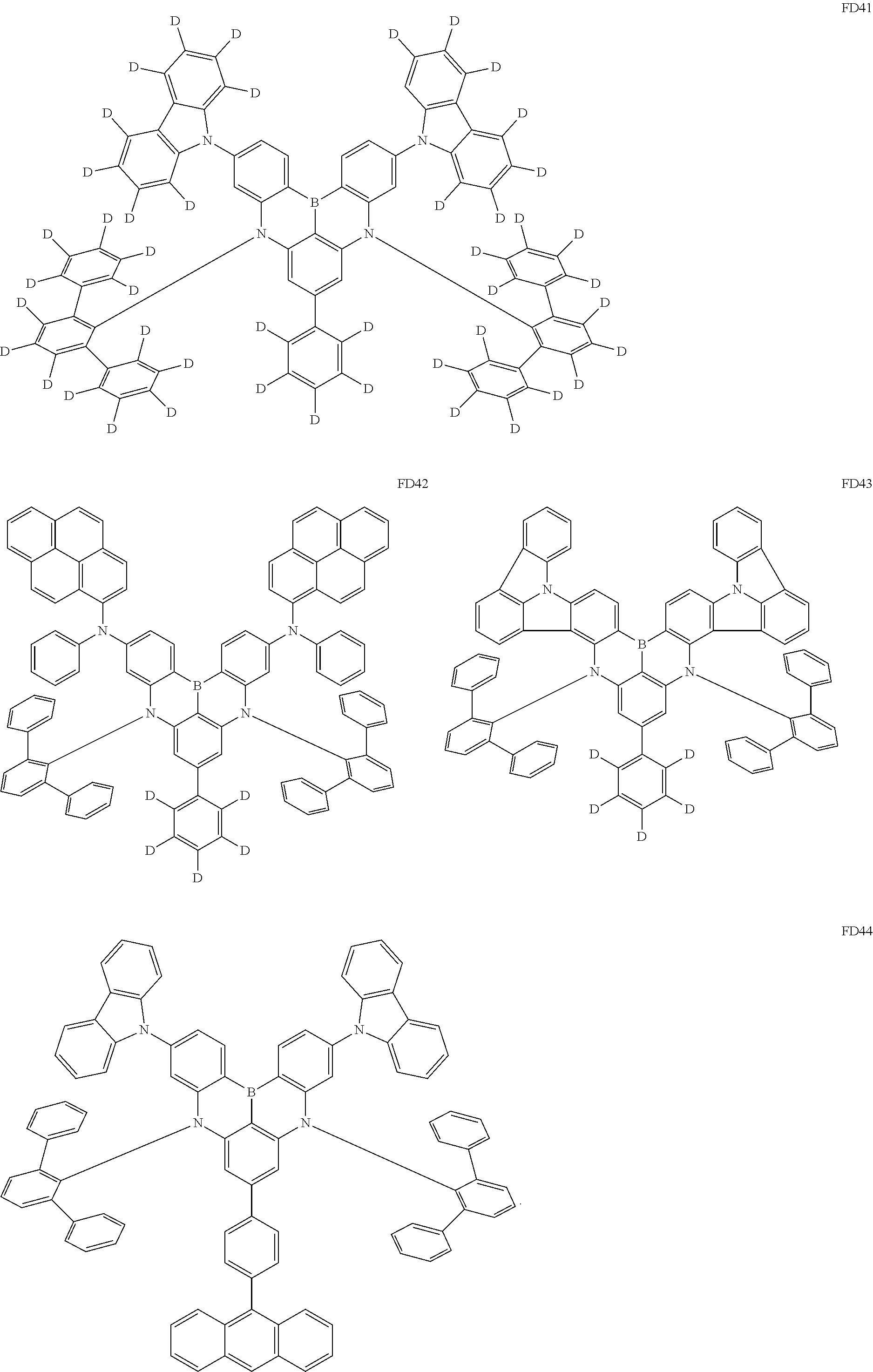

In the light emitting element ED according to an embodiment, the first green emission layer GEML may emit light having a second wavelength. The light having the second wavelength may be light in a green wavelength region. In an embodiment, the second wavelength may be in a range of about 520 nm to about 600 nm. The first green emission layer GEML may include an organic material that emits light having a wavelength in a range of about 520 nm to about 600 nm.

The first green emission layer GEML may have a single-layered structure. The first green emission layer GEML having a single-layered structure may have a layer in which two different host materials are mixed in one layer. In an embodiment, the first green emission layer GEML may have a structure in which a hole transporting host material and an electron transporting host material are mixed in one layer. In the specification, the hole transporting host may be described as a “first host,” and the electron transporting host may be described as a “second host.” The hole transporting host material and the electron transporting host material may form an exciplex. The first green emission layer GEML having a single-layered structure may have a thickness in a range of about 50 Å to about 400 Å. In another embodiment, the first green emission layer GEML may have a double-layered structure, unlike the configuration illustrated in FIG. 5B. In case that the first green emission layer GEML has a double-layered structure, the double-layered structure may include different host materials, but the disclosure is not limited thereto.

In an embodiment, the first green emission layer GEML may have a first hole transporting host, a first electron transporting host, and a second dopant. The first green emission layer GEML may be a layer in which the first hole transporting host and the first electron transporting host are mixed, the layer being doped with a second dopant that emits light having a second wavelength. In an embodiment, the first hole transporting host and the first electron transporting host included in the first green emission layer GEML may be materials different from the host materials included in the blue emission layers BEML1, BEML2, and BEML3. The second dopant may be a phosphorescent dopant. The second dopant may be a green phosphorescent dopant.

In the light emitting element ED according to an embodiment, the first hole transporting host included in the first green emission layer GEML may include one of the materials H4-1 to H4-11 listed below. However, the first hole transporting host included in the first green emission layer GEML is not limited to the following materials H4-1 to H4-11.

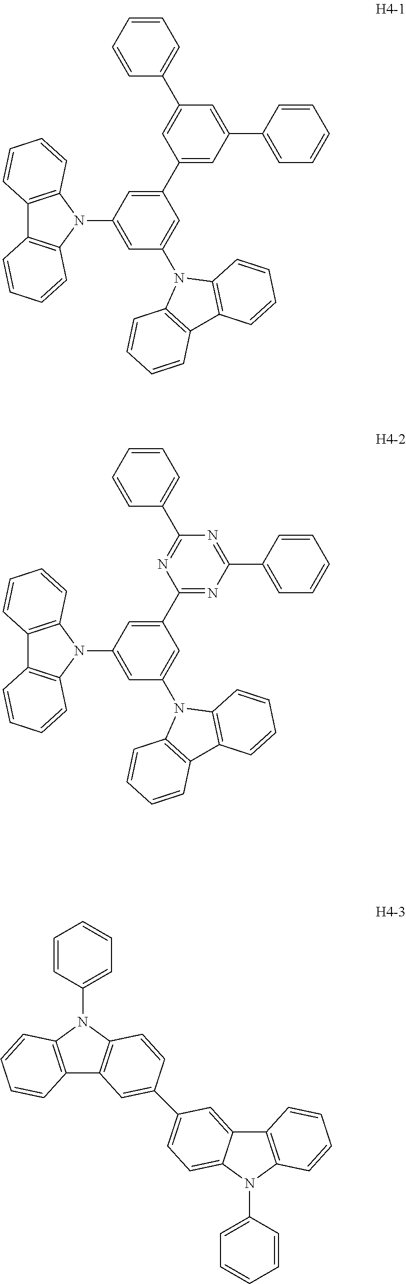 [SMILES: c1ccc(-c2cc(-c3ccccc3)cc(-c3cc(-n4c5ccccc5c5ccccc54)cc(-n4c5ccccc5c5ccccc54)c3)c2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1ccc(-n2c3ccccc3c3cc(-c4ccc5c(c4)c4ccccc4n5-c4ccccc4)ccc32)cc1]

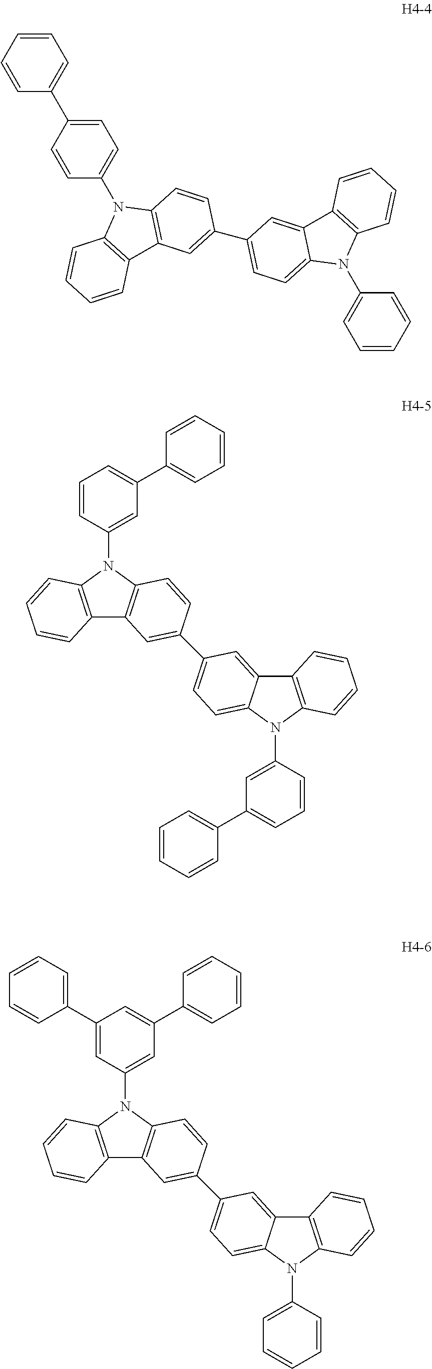 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cc(-c3ccccc3)cc(-n3c4ccccc4c4cc(-c5ccc6c(c5)c5ccccc5n6-c5ccccc5)ccc43)c2)cc1]

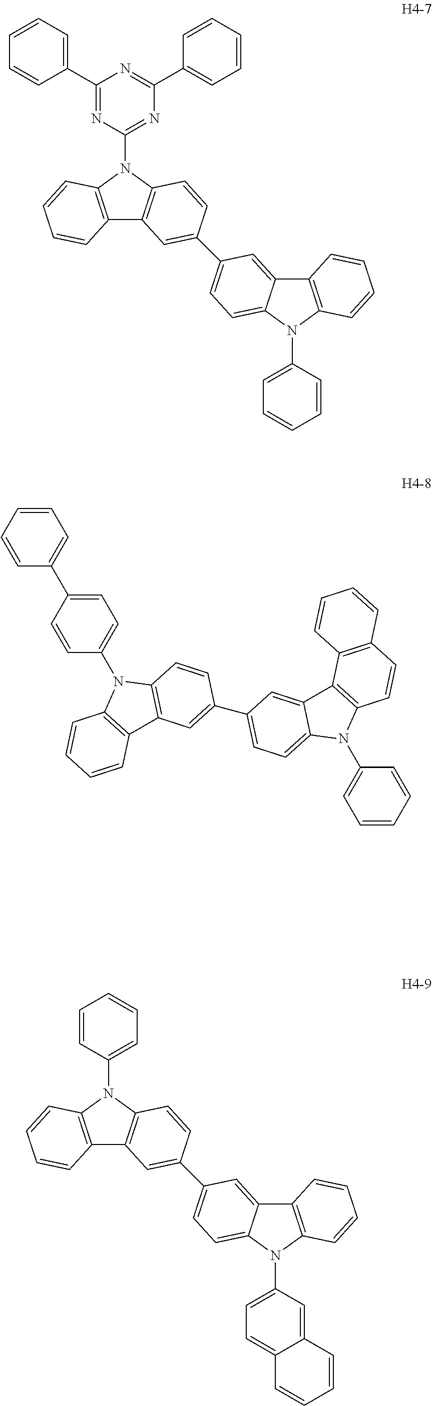 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2ccc(-n3c4ccccc4c4cc(-c5ccc6c(c5)c5c7ccccc7ccc5n6-c5ccccc5)ccc43)cc2)cc1 ; c1ccc(-n2c3ccccc3c3cc(-c4ccc5c(c4)c4ccccc4n5-c4ccc5ccccc5c4)ccc32)cc1]

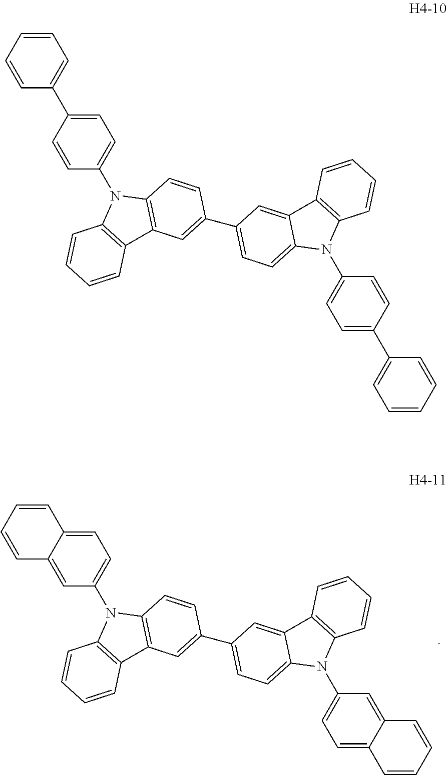 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc2cc(-n3c4ccccc4c4cc(-c5ccc6c(c5)c5ccccc5n6-c5ccc6ccccc6c5)ccc43)ccc2c1]

In the light emitting element ED according to an embodiment, the first electron transporting host included in the first green emission layer GEML may include one of the materials H3-1 to H3-23 listed below. However, the first electron transporting host included in the first green emission layer GEML is not limited to the following materials H3-1 to H3-23.

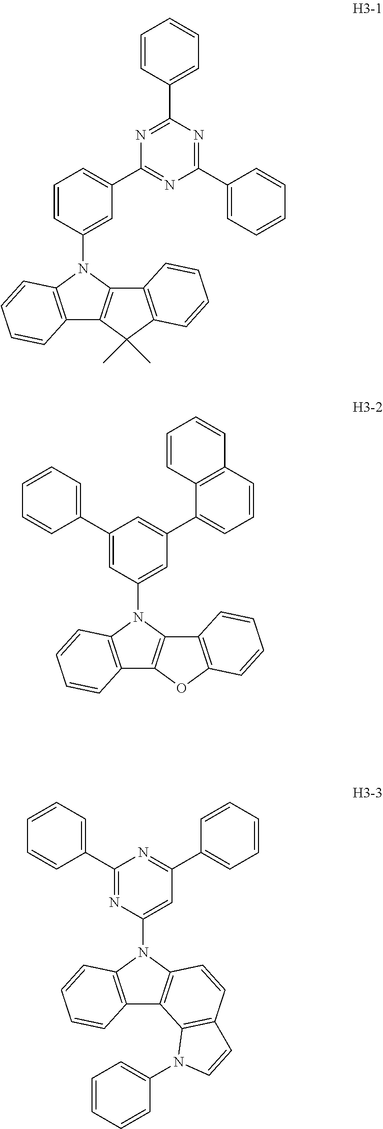 [SMILES: CC1(C)c2ccccc2-c2c1c1ccccc1n2-c1cccc(-c2nc(-c3ccccc3)nc(-c3ccccc3)n2)c1 ; c1ccc(-c2cc(-c3cccc4ccccc34)cc(-n3c4ccccc4c4oc5ccccc5c43)c2)cc1 ; c1ccc(-c2cc(-n3c4ccccc4c4c5c(ccc43)ccn5-c3ccccc3)nc(-c3ccccc3)n2)cc1]

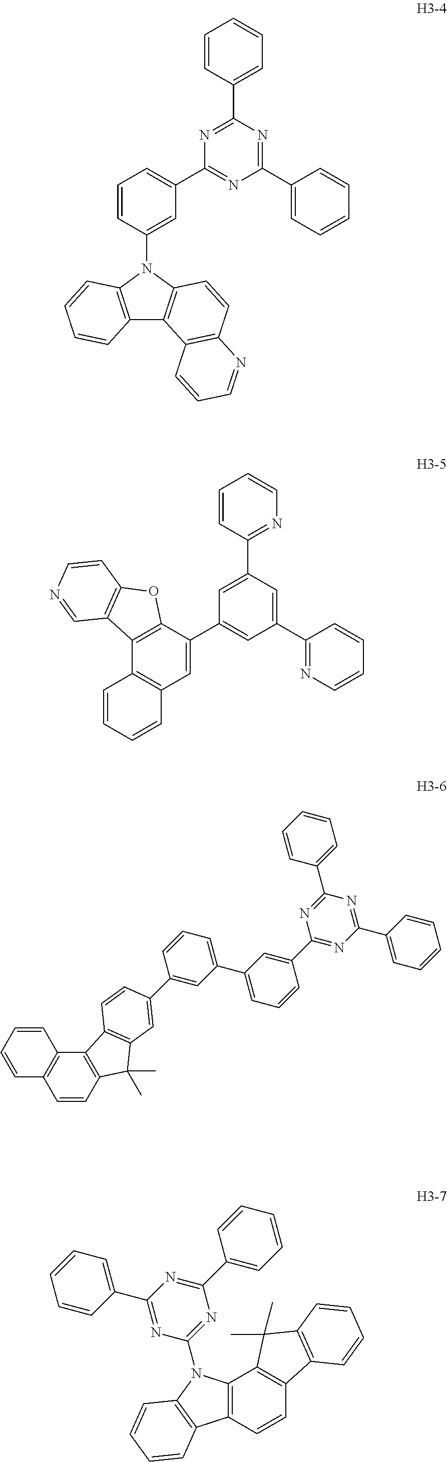 [SMILES: c1ccc(-c2nc(-c3ccccc3)nc(-c3cccc(-n4c5ccccc5c5c6cccnc6ccc54)c3)n2)cc1 ; c1ccc(-c2cc(-c3ccccn3)cc(-c3cc4ccccc4c4c3oc3ccncc34)c2)nc1 ; CC1(C)c2cc(-c3cccc(-c4cccc(-c5nc(-c6ccccc6)nc(-c6ccccc6)n5)c4)c3)ccc2-c2c1ccc1ccccc21 ; CC1(C)c2ccccc2-c2ccc3c4ccccc4n(-c4nc(-c5ccccc5)nc(-c5ccccc5)n4)c3c21]

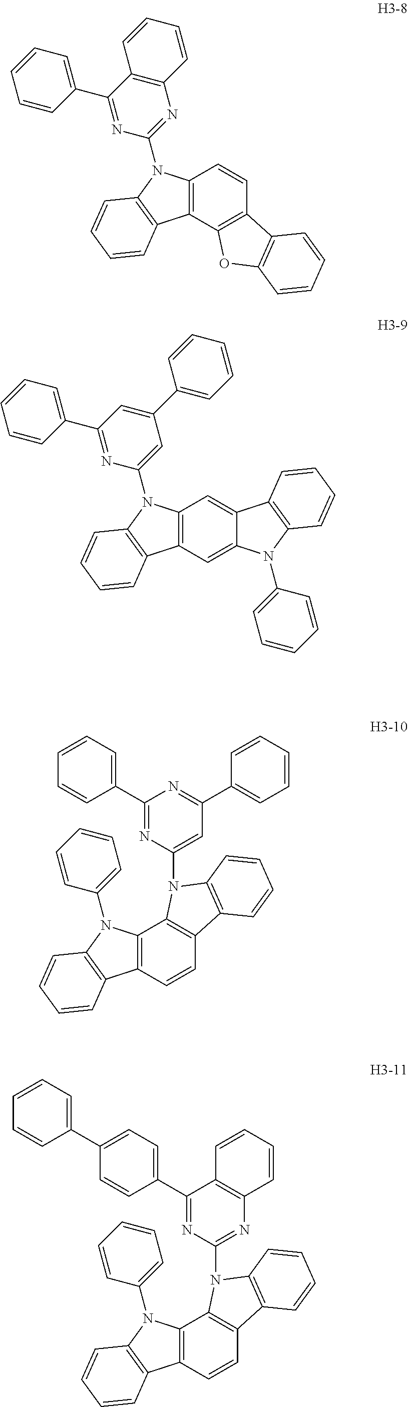 [SMILES: c1ccc(-c2nc(-n3c4ccccc4c4c5oc6ccccc6c5ccc43)nc3ccccc23)cc1 ; c1ccc(-c2cc(-c3ccccc3)nc(-n3c4ccccc4c4cc5c(cc43)c3ccccc3n5-c3ccccc3)c2)cc1 ; c1ccc(-c2cc(-n3c4ccccc4c4ccc5c6ccccc6n(-c6ccccc6)c5c43)nc(-c3ccccc3)n2)cc1 ; c1ccc(-c2ccc(-c3nc(-n4c5ccccc5c5ccc6c7ccccc7n(-c7ccccc7)c6c54)nc4ccccc34)cc2)cc1]

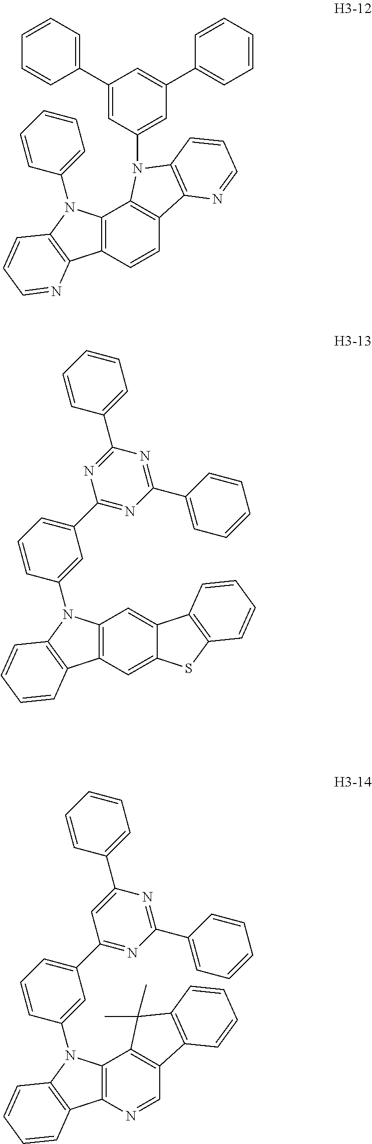 [SMILES: c1ccc(-c2cc(-c3ccccc3)cc(-n3c4cccnc4c4ccc5c6ncccc6n(-c6ccccc6)c5c43)c2)cc1 ; c1ccc(-c2nc(-c3ccccc3)nc(-c3cccc(-n4c5ccccc5c5cc6sc7ccccc7c6cc54)c3)n2)cc1 ; CC1(C)c2ccccc2-c2cnc3c4ccccc4n(-c4cccc(-c5cc(-c6ccccc6)nc(-c6ccccc6)n5)c4)c3c21]

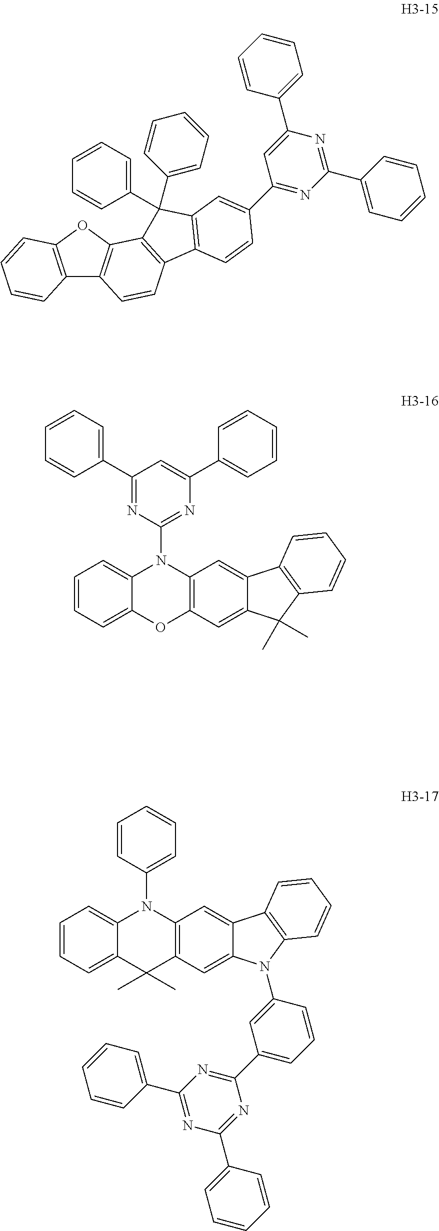 [SMILES: c1ccc(-c2cc(-c3ccc4c(c3)C(c3ccccc3)(c3ccccc3)c3c-4ccc4c3oc3ccccc34)nc(-c3ccccc3)n2)cc1 ; CC1(C)c2ccccc2-c2cc3c(cc21)Oc1ccccc1N3c1nc(-c2ccccc2)cc(-c2ccccc2)n1 ; CC1(C)c2ccccc2N(c2ccccc2)c2cc3c4ccccc4n(-c4cccc(-c5nc(-c6ccccc6)nc(-c6ccccc6)n5)c4)c3cc21]

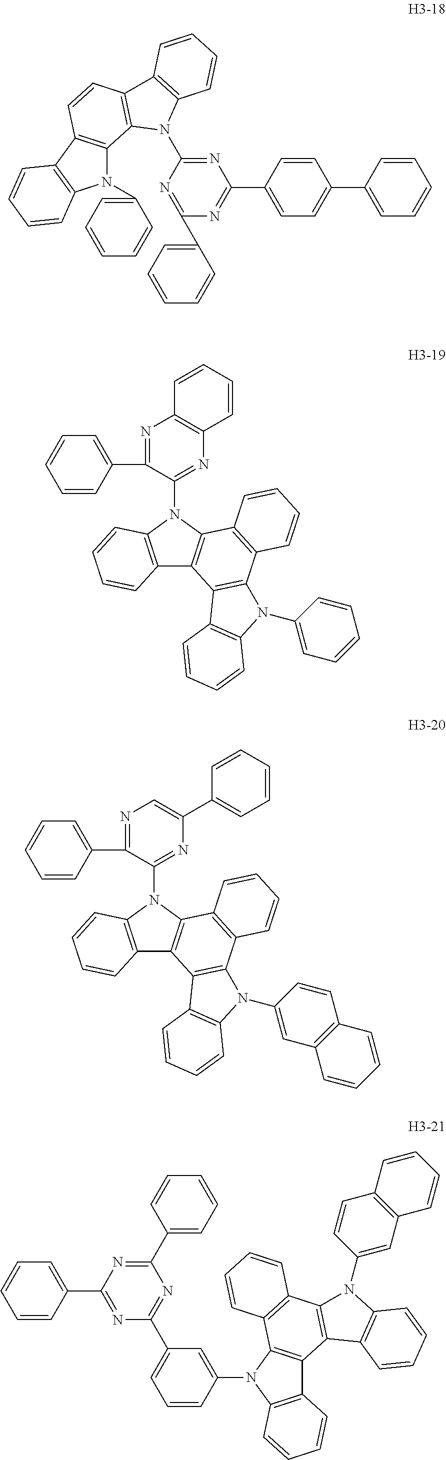 [SMILES: c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-c2nc3ccccc3nc2-n2c3ccccc3c3c4c5ccccc5n(-c5ccccc5)c4c4ccccc4c32)cc1 ; c1ccc(-c2cnc(-c3ccccc3)c(-n3c4ccccc4c4c5c6ccccc6n(-c6ccc7ccccc7c6)c5c5ccccc5c43)n2)cc1 ; c1ccc(-c2nc(-c3ccccc3)nc(-c3cccc(-n4c5ccccc5c5c6c7ccccc7n(-c7ccc8ccccc8c7)c6c6ccccc6c54)c3)n2)cc1]

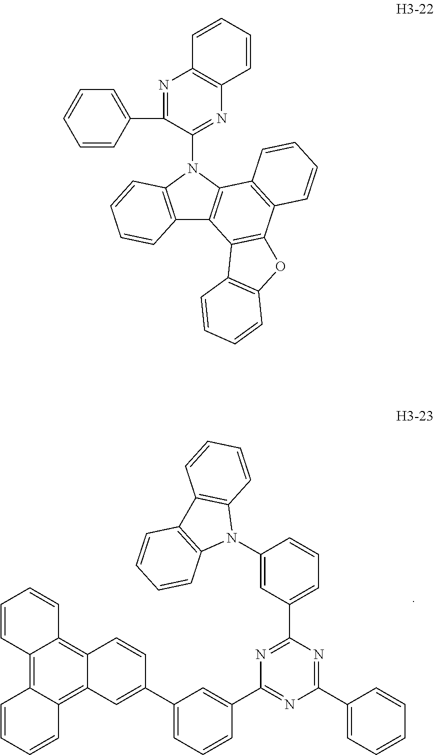 [SMILES: c1ccc(-c2nc3ccccc3nc2-n2c3ccccc3c3c4c5ccccc5oc4c4ccccc4c32)cc1 ; c1ccc(-c2nc(-c3cccc(-c4ccc5c6ccccc6c6ccccc6c5c4)c3)nc(-c3cccc(-n4c5ccccc5c5ccccc54)c3)n2)cc1]

In the light emitting element ED according to an embodiment, the second dopant included in the first green emission layer GEML may include one of the materials PD1 to PD33 listed below. However, the second dopant material included in the first green emission layer GEML is not limited to the following materials PD1 to PD33.

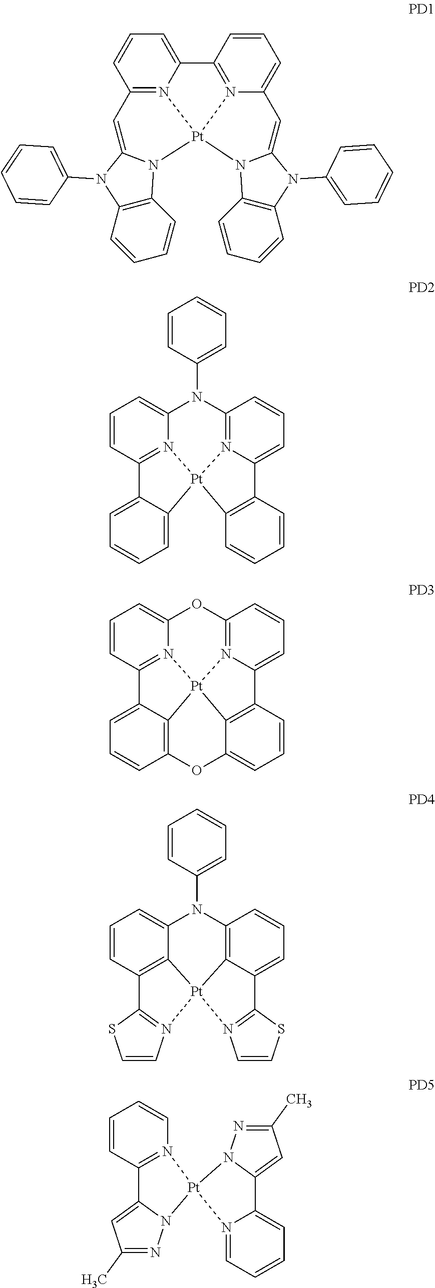

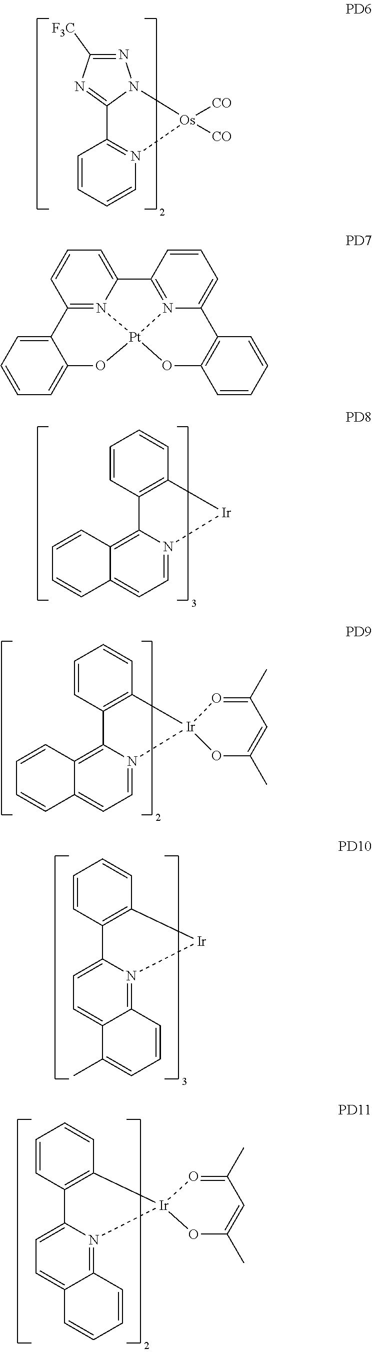

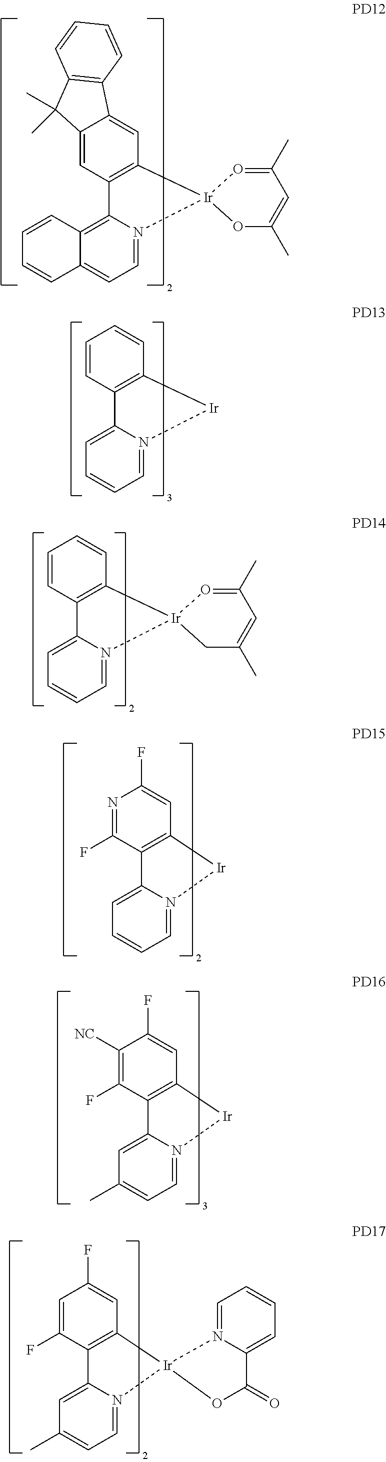

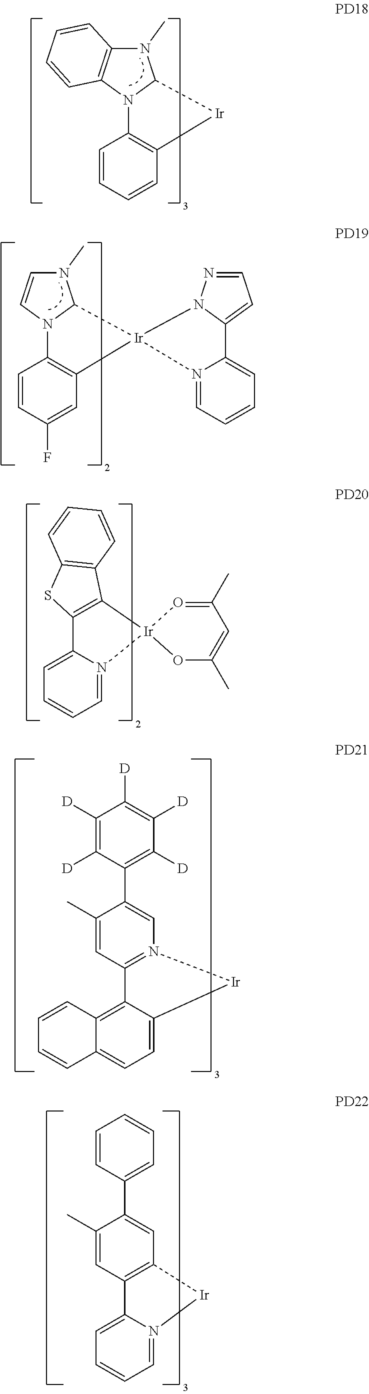

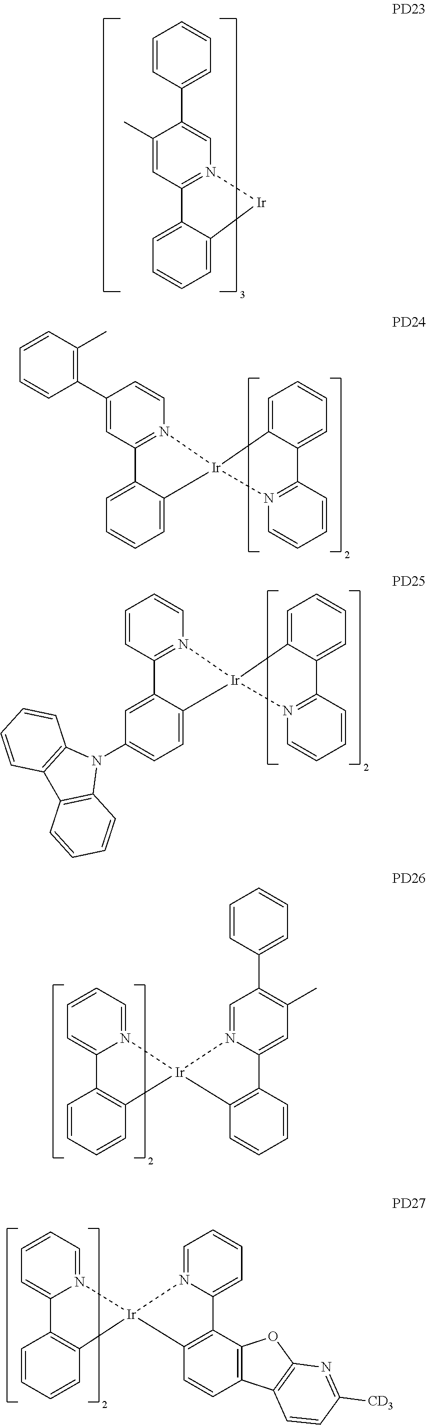

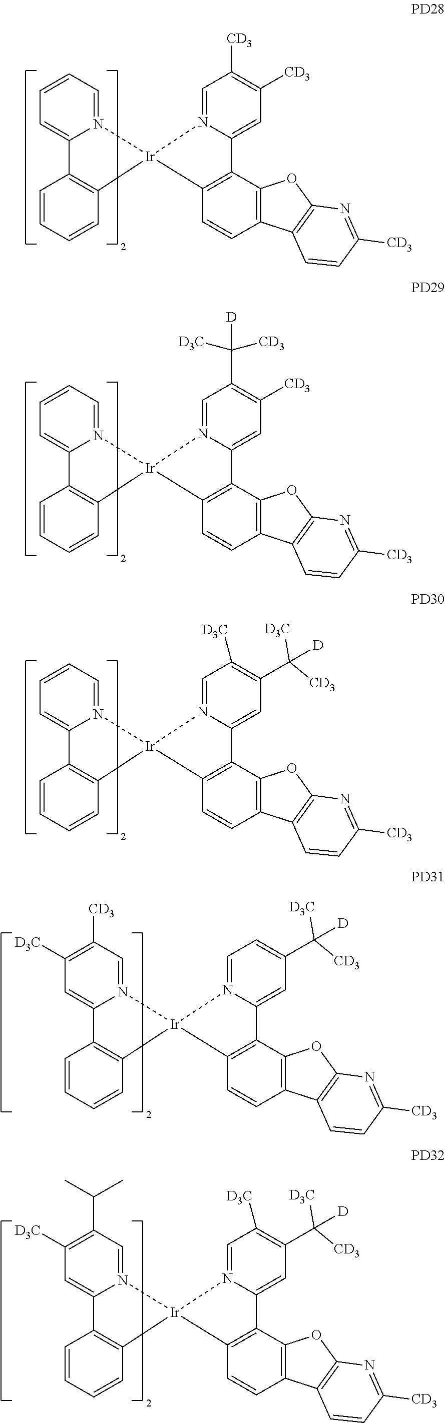

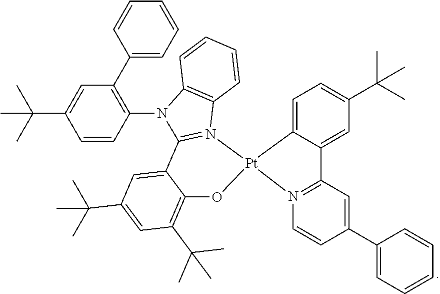

In the light emitting element ED according to an embodiment, the first red emission layer REML may emit light having a third wavelength. The light having the third wavelength may be light in a red wavelength region. In an embodiment, the third wavelength may be in a range of about 620 nm to about 700 nm. The first red emission layer REML may include an organic material that emits light having a wavelength in a range of about 620 nm to about 700 nm.

The first red emission layer REML may have a single-layered structure. The first red emission layer REML having a single-layered structure may have a layer in which two different host materials are mixed in one layer. In an embodiment, the first red emission layer REML may have a structure in which a hole transporting host material and an electron transporting host material are mixed in one layer. The first red emission layer REML having a single-layered structure may have a thickness in a range of about 50 Å to about 400 Å. In another embodiment, the first red emission layer REML may have a double-layered structure, unlike the configuration illustrated in FIG. 5B. In case that the first red emission layer REML has a double-layered structure, the double-layered structure may include different host materials, but the disclosure is not limited thereto.

In an embodiment, the first red emission layer REML may have a second hole transporting host, a second electron transporting host, and a third dopant. The first red emission layer REML may be a layer in which the second hole transporting host and the second electron transporting host are mixed, the layer being doped with a third dopant that emits light having a third wavelength. In an embodiment, the second hole transporting host and the second electron transporting host included in the first red emission layer REML may be materials different from the host materials included in the blue emission layers BEML1, BEML2, and BEML3 and the red emission layer REML. The third dopant may be a phosphorescent dopant. The third dopant may be a red phosphorescent dopant.

In the light emitting element ED according to an embodiment, the second hole transporting host included in the first red emission layer REML may be, for example, H5 below. The second electron transporting host included in the first red emission layer REML may be, for example, H6 below. However, the second hole transporting host and the second electron transporting host included in the first red emission layer REML are not limited to the following materials H5 and H6.

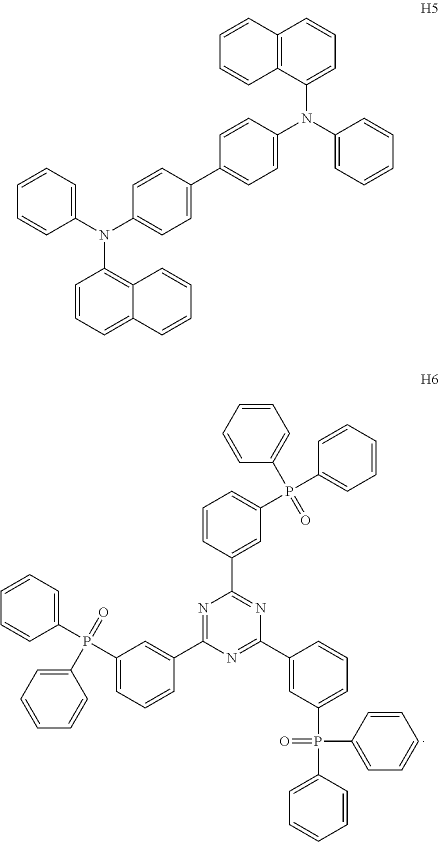 [SMILES: c1ccc(N(c2ccc(-c3ccc(N(c4ccccc4)c4cccc5ccccc45)cc3)cc2)c2cccc3ccccc23)cc1 ; O=P(c1ccccc1)(c1ccccc1)c1cccc(-c2nc(-c3cccc(P(=O)(c4ccccc4)c4ccccc4)c3)nc(-c3cccc(P(=O)(c4ccccc4)c4ccccc4)c3)n2)c1]

In the light emitting element ED according to an embodiment, the third dopant included in the first red emission layer REML may include one of the materials PR1 to PR35 listed below. However, the third dopant material included in the first red emission layer REML is not limited to the following materials PR1 to PR35.

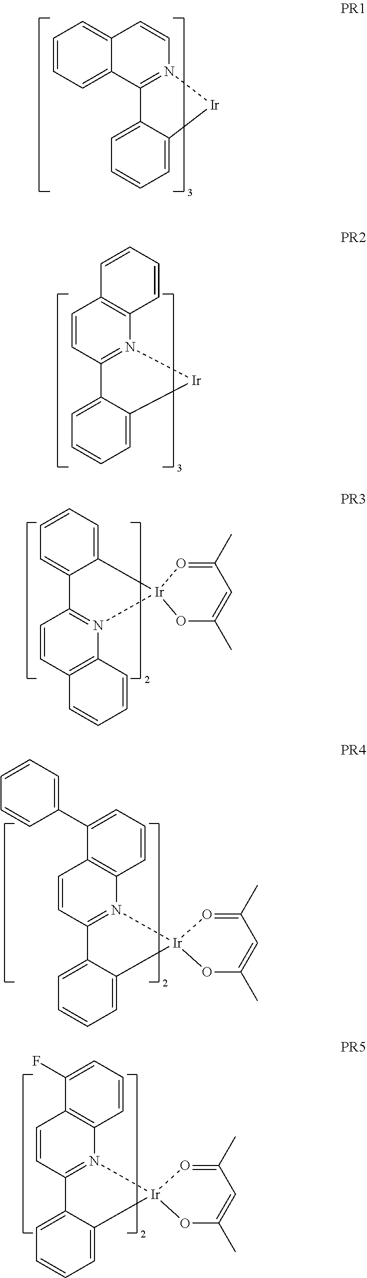

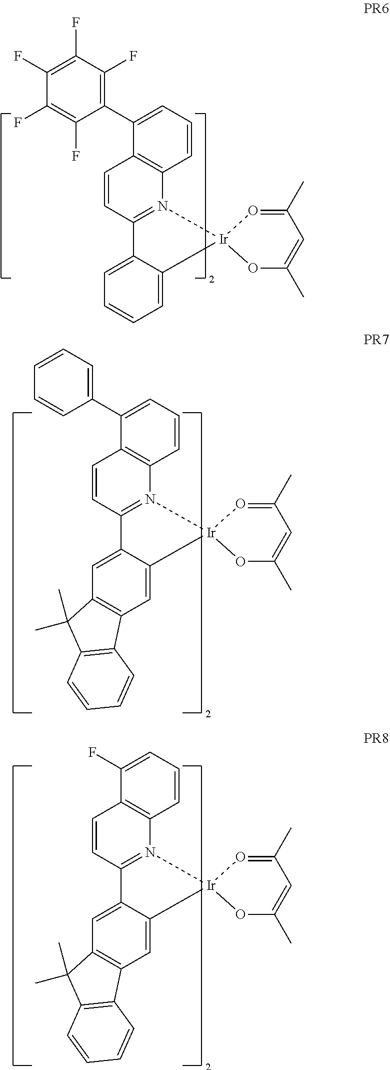

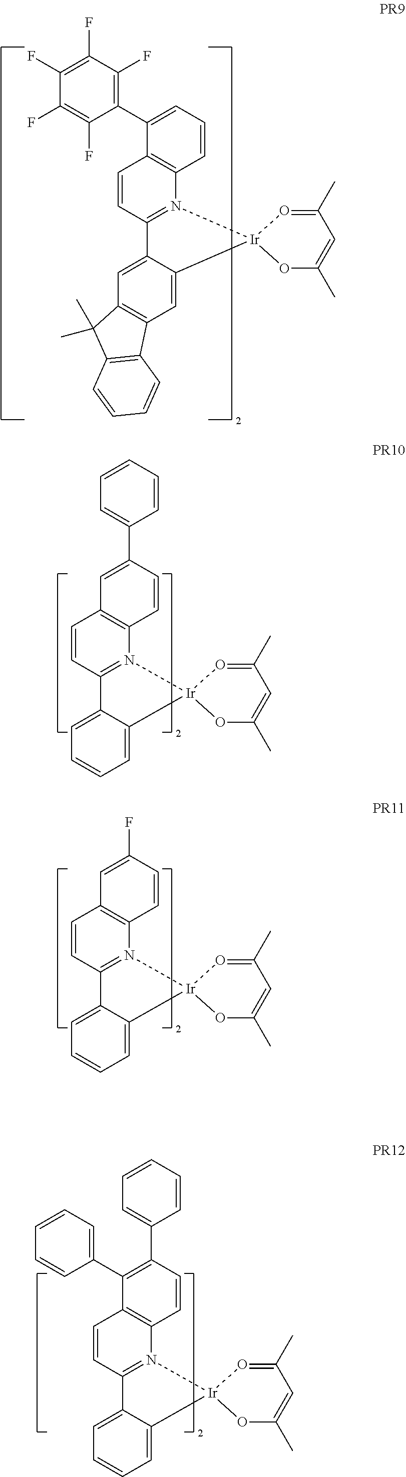

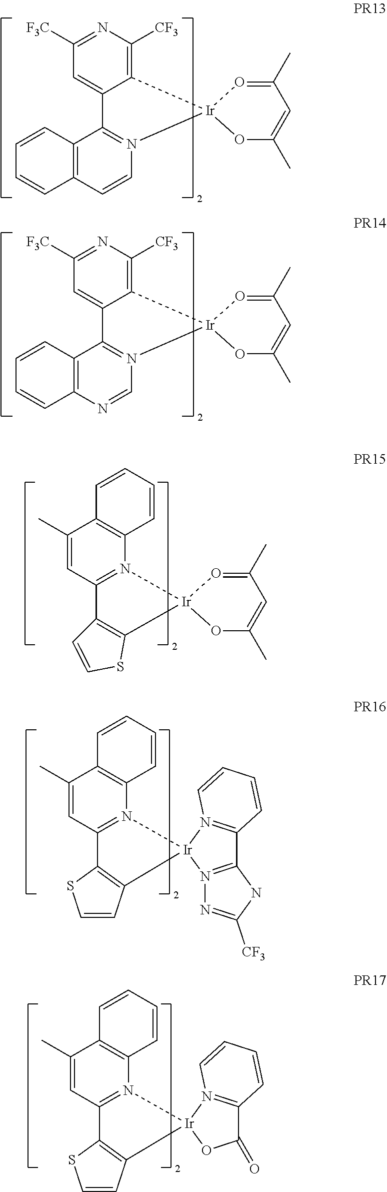

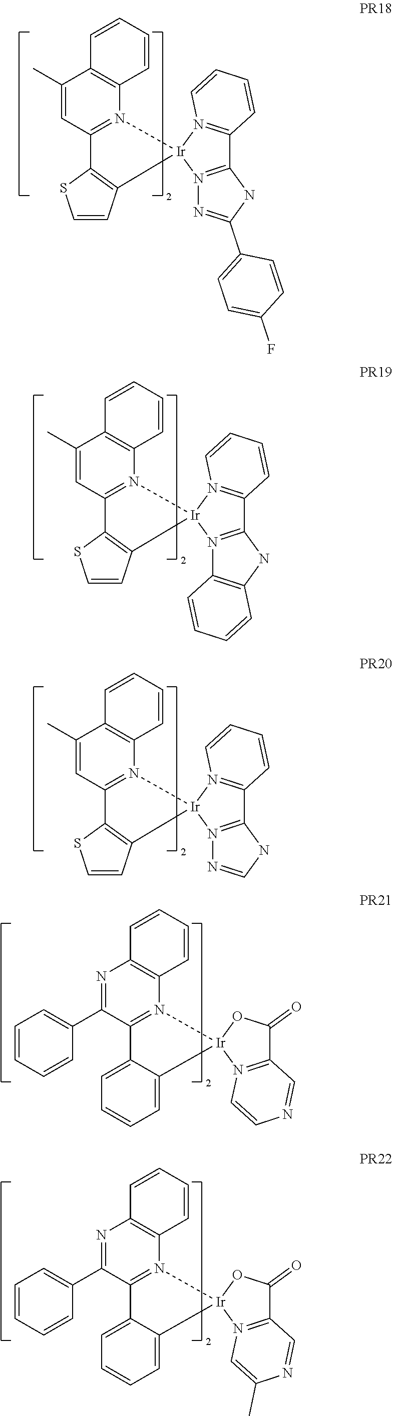

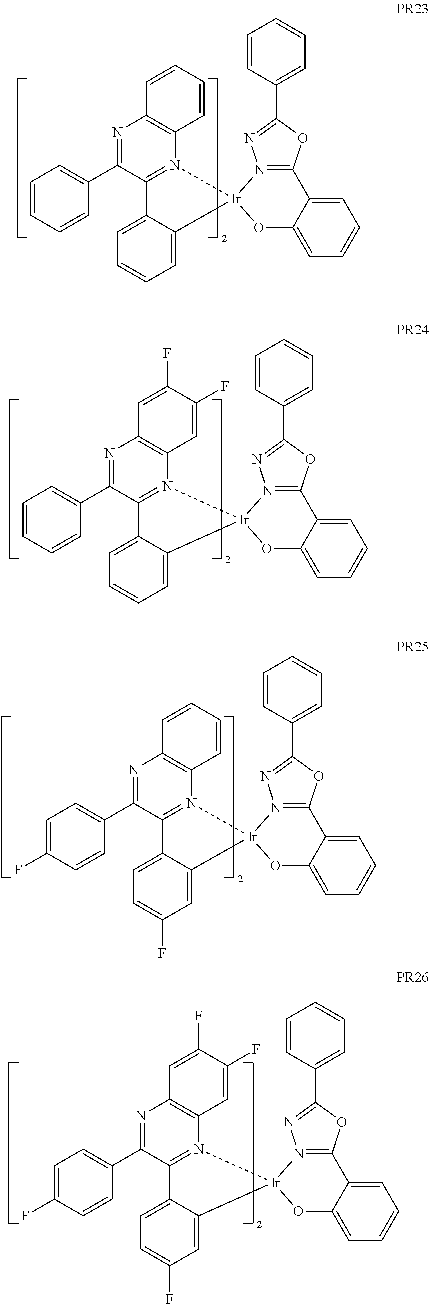

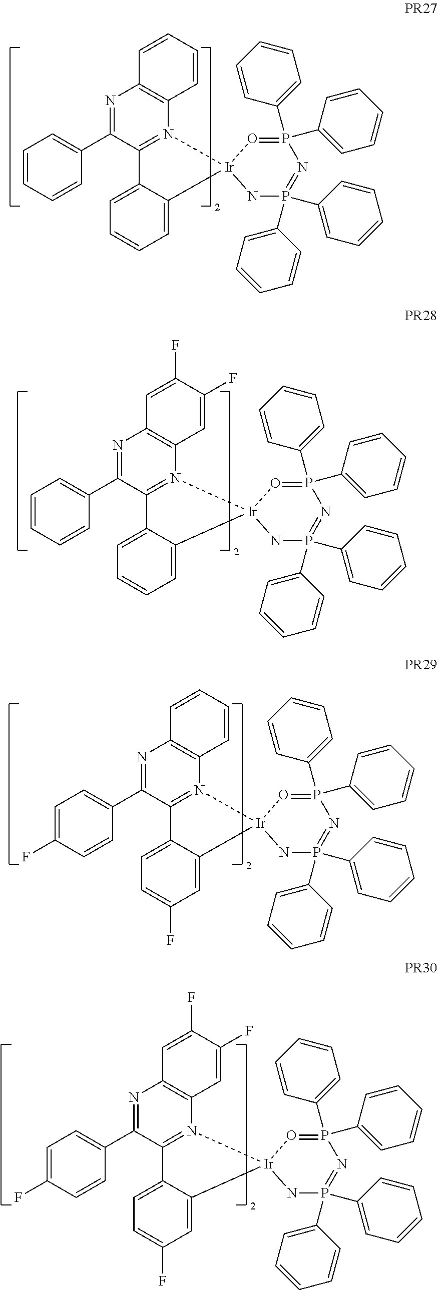

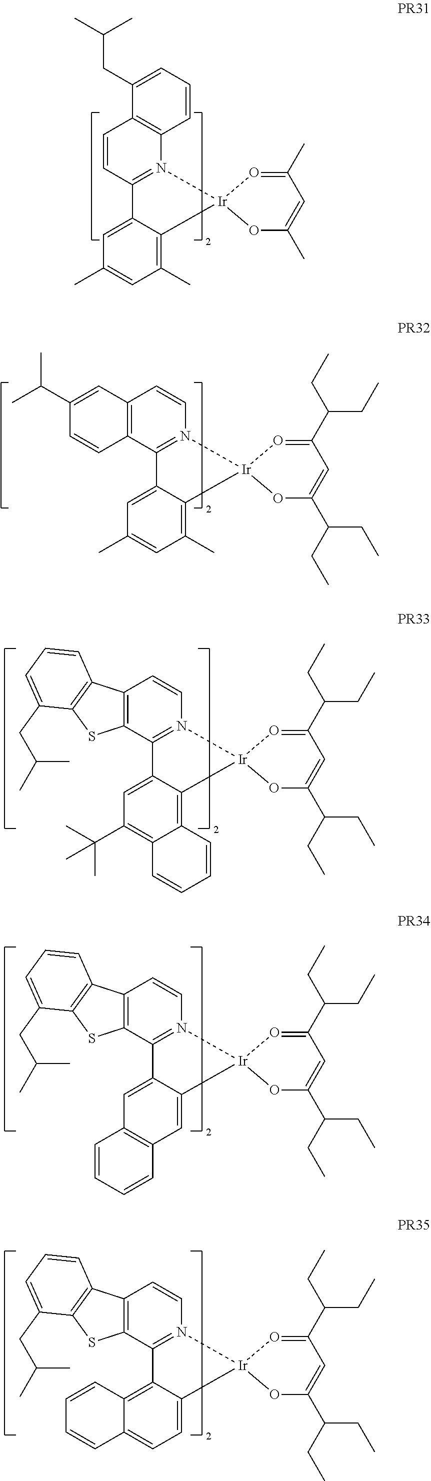

At least one of the emission layers included in each of the light emitting stacks ST1, ST2, ST3, ST4, and ST5 may be an emission layer that emits light with at least third-order resonance. For example, the emission layer included in the fifth light emitting stack ST5 disposed at the uppermost among the light emitting stacks ST1, ST2, ST3, ST4, and ST5 included in the light emitting element ED of an embodiment may be an emission layer that emits light with at least third-order resonance.

In the specification, the “optical distance” may be a distance defined as a distance from the top surface of the first electrode EL1 to the center of the corresponding emission layer. In an embodiment, each of the emission layers included in the light emitting stacks ST1, ST2, ST3, ST4, and ST5 may be disposed at a distance at which light emitted from the emission layer resonates with an x-th order. x may be a natural number greater than or equal to 1.

The blue emission layers BEML1, BEML2, and BEML3 may be included in three of the light emitting stacks ST1, ST2, ST3, ST4, and ST5, and the blue emission layer disposed at the uppermost among the blue emission layers BEML1, BEML2, and BEML3 may be an emission layer that emits light with at least third-order resonance. The blue emission layer disposed at the uppermost may mean a blue emission layer disposed closest to the second electrode EL2. The blue emission layer disposed at the uppermost may be disposed to have an optical distance at which blue light resonates with an n-th order, and n may be an integer greater than or equal to 3. In the light emitting element ED illustrated in FIG. 5B, the third blue emission layer BEML3 included in the fourth light emitting stack ST4 may resonate with third order or fourth order.

The red emission layer REML may be included in one of the light emitting stacks ST1, ST2, ST3, ST4, and ST5, and the red emission layer REML may be an emission layer that emits light with first-order or second-order resonance. The red emission layer REML may be disposed to have an optical distance at which red light resonates with m-th order, and m may be 1 or 2. In the light emitting element ED illustrated in FIG. 5B, the first red emission layer REML included in the third light emitting stack ST3 may resonate with second order.

In the light emitting element ED illustrated in FIG. 5B, the first green emission layer GEML included in the fifth light emitting stack ST5 may resonate with third order. In another embodiment, the first green emission layer GEML may be disposed at a resonance distance of the green light with fourth order or more.

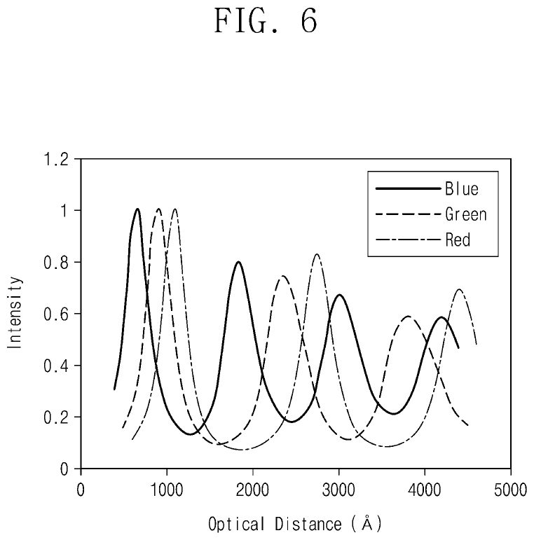

FIG. 6 is a graph showing emission intensity depending on an optical distance of each of red light, blue light, and green light. In FIG. 6, the unit of the optical distance is angstrom (Å), and the emission intensity indicates a relative emission intensity in case that the emission intensity of each light is “1” at the position of the first-order resonance distance.

Referring to FIGS. 5B and 6 together, the blue emission layer disposed at the uppermost may be the third blue emission layer BEML3 included in the fourth light emitting stack ST4, and the third blue emission layer BEML3 may have a first optical distance OD-B. The first optical distance OD-B may be a third-order resonance distance of the blue light. The first optical distance OD-B may be, for example, about 3,000 Å.

The first red emission layer REML included in the third light emitting stack ST3 may have a second optical distance OD-R. The second optical distance OD-R may be a second-order resonance distance of the red light. The second optical distance OD-R may be, for example, about 2,750 Å.

The first green emission layer GEML included in the fifth light emitting stack ST5 may have a third optical distance OD-G. The third optical distance OD-G may be a third-order resonance distance of the green light. The third optical distance OD-G may be, for example, about 3,800 Å.

Referring to FIG. 5C, in the light emitting element ED-1 of an embodiment, the first light emitting stack ST1 may include the first red emission layer REML, the second light emitting stack ST2 may include the first blue emission layer BEML1, the third light emitting stack ST3 may include the first green emission layer GEML, the fourth light emitting stack ST4 may include the second blue emission layer BEML2, and the fifth light emitting stack ST5 may include the third blue emission layer BEML3. The above-described descriptions may be applied to the respective thicknesses, materials, and the like of the blue emission layers BEML1, BEML2, and BEML3, the first green emission layer GEML, and the first red emission layer REML.

The blue emission layers BEML1, BEML2, and BEML3 may be included in three of the light emitting stacks ST1, ST2, ST3, ST4, and ST5, and the blue emission layer disposed at the uppermost among the blue emission layers BEML1, BEML2, and BEML3 may be an emission layer that emits light with at least third-order resonance. The blue emission layer disposed at the uppermost may mean a blue emission layer disposed closest to the second electrode EL2. The blue emission layer disposed at the uppermost may be disposed to have an optical distance at which blue light resonates with n-th order, and n may be an integer greater than or equal to 3. In the light emitting element ED illustrated in FIG. 5C, the third blue emission layer BEML3 included in the fifth light emitting stack ST5 may resonate with fourth order.

The red emission layer REML may be included in one of the light emitting stacks ST1, ST2, ST3, ST4, and ST5, and the red emission layer REML may be an emission layer that emits light with first-order or second-order resonance. The red emission layer REML may be disposed to have an optical distance at which red light resonates with m-th order, and m may be 1 or 2. In the light emitting element ED illustrated in FIG. 5C, the first red emission layer REML included in the first light emitting stack ST1 may resonate with first order.

In the light emitting element ED illustrated in FIG. 5C, the first green emission layer GEML included in the third light emitting stack ST5 may resonate with second order.

Referring to FIGS. 5C and 6 together, the blue emission layer disposed at the uppermost may be the third blue emission layer BEML3 included in the fifth light emitting stack ST5, and the third blue emission layer BEML3 may have a first optical distance OD-B. The first optical distance OD-B may be a fourth-order resonance distance of the blue light. The first optical distance OD-B may be, for example, about 4,200 Å.

The first red emission layer REML included in the first light emitting stack ST1 may have a second optical distance OD-R. The second optical distance OD-R may be a first-order resonance distance of the red light. The second optical distance OD-R may be, for example, about 1,100 Å.

The first green emission layer GEML included in the third light emitting stack ST3 may have a third optical distance OD-G. The third optical distance OD-G may be a second-order resonance distance of the green light. The third optical distance OD-G may be, for example, about 2,350 Å.

Referring to FIGS. 5D and 5E, the light emitting elements ED-2 and ED-3 of embodiments may each include a first complex emission layer HEML1. Compared with the light emitting elements ED and ED-1 illustrated in FIGS. 5B and 5C, the light emitting elements ED-2 and ED-3 illustrated in FIGS. 5D and 5E of embodiments may be formed by replacing the first red emission layer REML with the first complex emission layer HEML1. In an embodiment, the light emitting element ED-2 illustrated in FIG. 5D may include the first complex emission layer HEML1 included in the third light emitting stack ST3. The light emitting element ED-3 illustrated in FIG. 5E may include the first complex emission layer HEML included in the first light emitting stack ST1.

The first complex emission layer HEML1 may include a first red sub-emission layer S-REML1 and a first green sub-emission layer S-GEML1 disposed on the first red sub-emission layer S-REML1. The first red sub-emission layer S-REML1 and the first green sub-emission layer S-GEML1 may be in contact with each other. The first red sub-emission layer S-REML1 may be disposed adjacent to the first electrode EL1 compared to the first green sub-emission layer S-GEML1, and the first green sub-emission layer S-GEML1 may be disposed adjacent to the second electrode EL2 compared to the first red sub-emission layer S-REML1. In the light emitting elements ED-2 and ED-3 of embodiments, since the first red sub-emission layer S-REML1 is disposed adjacent to the first electrode EL1 compared to the first green sub-emission layer S-GEML1, more red light emission may be generated in the first complex emission layer HEML1, and thus white light luminous efficiency of the light emitting elements ED-2 and ED-3 may be improved.

The first red sub-emission layer S-REML1 may emit light having the third wavelength. The light having the third wavelength may be light in a red wavelength region. In an embodiment, the third wavelength may be in a range of about 620 nm to about 700 nm. The first red sub-emission layer S-REML1 may include an organic material that emits light having a wavelength in a range of about 620 nm to about 700 nm.

The first red sub-emission layer S-REML1 may have a single-layered structure. The first red sub-emission layer S-REML1 having a single-layered structure may have a layer in which two different host materials are mixed in one layer. In an embodiment, the first red sub-emission layer S-REML1 may have a structure in which a hole transporting host material and an electron transporting host material are mixed in one layer. The first red sub-emission layer S-REML1 having a single-layered structure may have a thickness in a range of about 50 Å to about 400 Å. In another embodiment, the first red sub-emission layer S-REML1 may have a double-layered structure, unlike the configuration illustrated in FIGS. 5D and 5E. In case that the first red sub-emission layer S-REML1 has a double-layered structure, the double-layered structure may include different host materials, but the disclosure is not limited thereto.

In an embodiment, the first red sub-emission layer S-REML1 may have a second hole transporting host, a second electron transporting host, and a third dopant. The first red sub-emission layer S-REML1 may be a layer in which the second hole transporting host and the second electron transporting host are mixed, the layer being doped with a third dopant that emits light having a third wavelength. In an embodiment, the second hole transporting host and the second electron transporting host included in the first red sub-emission layer S-REML1 may be materials different from the host materials included in the blue emission layers BEML1, BEML2, and BEML3 and the green emission layer GEML. The third dopant may be a phosphorescent dopant. The third dopant may be a red phosphorescent dopant.

The first green sub-emission layer S-GEML1 may emit light having the second wavelength. The light having the second wavelength may be light in a green wavelength region. In an embodiment, the second wavelength may be in a range of about 520 nm to about 600 nm. The first green sub-emission layer S-GEML1 may include an organic material that emits light having a wavelength in a range of about 520 nm to about 600 nm.

The first green sub-emission layer S-GEML1 may have a single-layered structure. The first green sub-emission layer S-GEML1 having a single-layered structure may have a layer in which two different host materials are mixed in one layer. In an embodiment, the first green sub-emission layer S-GEML1 may have a structure in which a hole transporting host material and an electron transporting host material are mixed in one layer. The first green sub-emission layer S-GEML1 having a single-layered structure may have a thickness in a range of about 50 Å to about 400 Å. In another embodiment, the first green sub-emission layer S-GEML1 may have a double-layered structure, unlike the configuration illustrated in FIGS. 5D and 5E. In case that the first green sub-emission layer S-GEML1 has a double-layered structure, the double-layered structure may include different host materials, but the disclosure is not limited thereto.

In an embodiment, the first green sub-emission layer S-GEML1 may have a first hole transporting host, a first electron transporting host, and a second dopant. The first green sub-emission layer S-GEML1 may be a layer in which the first hole transporting host and the first electron transporting host are mixed, the layer being doped with a second dopant that emits light having a second wavelength. The second dopant may be a phosphorescent dopant. The second dopant may be a green phosphorescent dopant.

Referring to FIGS. 5A to 5E, in an embodiment, the light emitting elements ED, ED-1, ED-2, and ED-3 may emit light in a direction from the first electrode EL1 to the second electrode EL2. In the light emitting elements ED, ED-1, ED-2, and ED-3 of an embodiment, each of the stacks ST1, ST2, ST3, ST4, and ST5 may include hole transport regions HTR1, HTR2, HTR3, HTR4, and HTR5 and electron transport regions ETR1, ETR2, ETR3, ETR4, and ETR5. The hole transport regions HTR1, HTR2, HTR3, HTR4, and HTR5 may transfer holes provided from the first electrode EL1 or the charge generation layers CGL1, CGL2, CGL3, and CGL4 to the emission layers. The electron transport regions ETR1, ETR2, ETR3, ETR4, and ETR5 may transfer electrons provided from the second electrode EL2 or the charge generation layers CGL1, CGL2, CGL3, and CGL4 to the emission layers.

In the light emitting elements ED, ED-1, ED-2, and ED-3 of embodiments, a structure in which the hole transport regions HTR1, HTR2, HTR3, HTR4, and HTR5 are disposed under the respective emission layers included in the stacks ST1, ST2, ST3, ST4, and ST5 and the electron transport regions ETR1, ETR2, ETR3, ETR4, and ETR5 are disposed above the respective emission layers included in the stacks ST1, ST2, ST3, ST4, and ST5 is illustrated on the basis of a direction in which light is emitted. For example, the light emitting elements ED, ED-1, ED-2, and ED-3 of embodiments may have a forward element structure, but the disclosure is not limited thereto, and the light emitting elements ED, ED-1, ED-2, and ED-3 may have an inverted element structure in which the electron transport regions ETR1, ETR2, ETR3, ETR4, and ETR5 are disposed under the respective emission layers included in the stacks ST1, ST2, ST3, ST4, and ST5 and the hole transport regions HTR1, HTR2, HTR3, HTR4, and HTR5 are disposed above the respective emission layers included in the stacks ST1, ST2, ST3, ST4, and ST5 on the basis of the direction in which light is emitted.

The hole transport regions HTR1, HTR2, HTR3, HTR4, and HTR5 may respectively include hole injection layers HIL1, HIL2, HIL3, HIL4, and HIL5 and hole transport layers HIL1, HIL2, HIL3, HIL4, and HIL5 respectively disposed on the hole injection layers HIL1, HIL2, HIL3, HIL4, and HIL5. The hole transport layers HTL1, HTL2, HTL3, HTL4, and HTL5 may each be in contact with the bottom surface of the emission layer. However, the disclosure is not limited thereto, and the hole transport regions HTR1, HTR2, HTR3, HTR4, and HTR5 may further include hole side additional layers respectively disposed on the hole transport layers HTL1, HTL2, HTL3, HTL4, and HTL5. The hole side additional layer may include at least one of a hole buffer layer, an emission-auxiliary layer, and an electron blocking layer. The hole buffer layer may compensate for a resonance distance according to the wavelength of light emitted from the emission layer to thus increase luminous efficiency. The electron blocking layer may serve to prevent electron injection from the electron transport region into the hole transport region.

The electron transport regions ETR1, ETR2, ETR3, ETR4, and ETR5 may include electron transport layers ETL1, ETL2, ETL3, ETL4, and ETL5, respectively. The electron transport regions ETR1, ETR2, ETR3, ETR4, and ETR5 may further include electron injection layers respectively disposed on the electron transport layers ETL1, ETL2, ETL3, ETL4, and ETL5. For example, the fifth electron transport region ETR5 included in the fifth light emitting stack ST5 may further include a fifth electron injection layer EIL5 disposed on the fifth electron transport layer ETL5. The electron transport regions ETR1, ETR2, ETR3, ETR4, and ETR5 may each further include an electron side additional layer disposed between the electron transport layer ETL and the emission layer. The electron side additional layer may include at least one of an electron buffer layer and a hole blocking layer.

In the light emitting elements ED, ED-1, ED-2, and ED-3 according to embodiments, the first electrode EL1 may be a reflective electrode. For example, the first electrode EL1 may include Ag, Mg, Cu, Al, Pt, Pd, Au, Ni, Nd, Ir, Cr, Li, Ca, LiF/Ca, LiF/Al, Mo, Ti, W, In, Zn, Sn, and a compound or mixture thereof (e.g., a mixture of Ag and Mg) with high reflectivity. For example, the first electrode EL1 may have a multilayer structure including a reflective film formed of the above-described materials, and a transparent conductive film formed of indium tin oxide (ITO), indium zinc oxide (IZO), zinc oxide (ZnO), indium tin zinc oxide (ITZO), etc. For example, the first electrode EL1 may have a two-layer structure of ITO/Ag or a three-layer structure of ITO/Ag/ITO, but the disclosure is not limited thereto. However, the disclosure is not limited thereto, and the first electrode EL1 may include the above-described metal materials, combinations of at least two metal materials of the above-described metal materials, oxides of the above-described metal materials, or the like. The first electrode EL1 may have a thickness in a range of about 70 nm to about 1,000 nm. For example, the first electrode EL1 may have a thickness in a range of about 100 nm to about 300 nm.

In the light emitting elements ED, ED-1, ED-2, and ED-3 according to embodiments, hole transport regions HTR1, HTR2, HTR3, HTR4 and HTR5 may each have a single layer formed of a single material, a single layer formed of different materials, or a multi-layered structure including multiple layers formed of multiple different materials.

The hole transport regions HTR1, HTR2, HTR3, HTR4, and HTR5 may each be formed using various methods such as a vacuum deposition method, a spin coating method, a cast method, a Langmuir-Blodgett (LB) method, an inkjet printing method, a laser printing method, a laser induced thermal imaging (LITI) method, etc.

The hole transport regions HTR1, HTR2, HTR3, HTR4, and HTR5 may each include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine] (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport regions HTR1, HTR2, HTR3, HTR4, and HTR5 may each include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The hole transport regions HTR1, HTR2, HTR3, HTR4, and HTR5 may each include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport regions HTR1, HTR2, HTR3, HTR4, and HTR5 may each include the above-described compounds of the hole transport region in at least one of a hole injection layer HIL1, HIL2, HIL3, HIL4, or HIL5 (collectively referred as HIL), a hole transport layer HTL1, HTL2, HTL3, HTL4, or HTL5 (collectively referred as HTL), and a hole side additional layer.

The hole transport regions HTR1, HTR2, HTR3, HTR4, and HTR5 may each have a thickness in a range of about 10 nm to about 1,000 nm, for example, in a range of about 10 nm to about 500 nm. The hole injection layer HIL may each have a thickness in a range of, for example, about 5 nm to about 100 nm. The hole transport layer HTL may each have a thickness in a range of about 5 nm to about 100 nm. In case that the hole transport regions HTR1, HTR2, HTR3, HTR4, and HTR5 each include the hole side additional layer, the hole side additional layer may have a thickness in a range of about 1 nm to about 10 nm. In case that the thicknesses of the hole transport regions HTR1, HTR2, HTR3, HTR4, and HTR5 and the layers included therein satisfy the above-described ranges, satisfactory hole transport characteristics may be obtained without a substantial increase in driving voltage.

The hole transport regions HTR1, HTR2, HTR3, HTR4, and HTR5 may each further include, in addition to the above-described materials, a charge generating material to increase conductivity. The charge generating material may be dispersed uniformly or non-uniformly in the hole transport regions HTR1, HTR2, HTR3, HTR4, and HTR5. The charge generating material may be, for example, a p-type dopant. The p-type dopant may include at least one of a halogenated metal compound, a quinone derivative, a metal oxide, and a cyano group-containing compound, but the disclosure is not limited thereto. For example, the p-type dopant may include a halogenated metal compound such as CuI and RbI, a quinone derivative such as tetracyanoquinodimethane (TCNQ) and 2,3,5,6-tetrafluoro-7,7′,8,8′-tetracyanoquinodimethane (F4-TCNQ), a metal oxide such as a tungsten oxide and a molybdenum oxide, etc., but the disclosure is not limited thereto.

Each of the blue emission layers BEML1, BEML2, and BEML3, the first green emission layer GEML, and the first red emission layer REML may include the above-described host material and dopant material. The blue emission layers BEML1, BEML2, and BEML3, the first green emission layer GEML, and the first red emission layer REML may include a material including a carbazole derivative moiety or an amine derivative moiety as a hole transporting host material. Each of the blue emission layers BEML1, BEML2, and BEML3, the first green emission layer GEML, and the first red emission layer REML may include, as an electron transporting host material, a material including a nitrogen-containing aromatic ring structure such as a pyridine derivative moiety, a pyridazine derivative moiety, a pyrimidine derivative moiety, a pyrazine derivative moiety, or a triazine derivative moiety.

Each of the blue emission layers BEML1, BEML2, and BEML3, the first green emission layer GEML, and the first red emission layer REML may include, as a host material, an anthracene derivative, a pyrene derivative, a fluoranthene derivative, a chrysene derivative, a dihydrobenzanthracene derivative, a triphenylene derivative, or the like. Each of the blue emission layers BEML1, BEML2, and BEML3, the first green emission layer GEML, and the first red emission layer REML may further include a general host material as a host material. For example, each of the blue emission layers BEML1, BEML2, and BEML3, the first green emission layer GEML, and the first red emission layer REML may include, as a host material, at least one of bis[2-(diphenylphosphino)phenyl] ether oxide (DPEPO), 4,4′-bis(carbazol-9-yl)biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, the disclosure is not limited thereto, and for example, tris(8-hydroxyquinolino)aluminum (Alq₃), poly(N-vinylcarbazole (PVK), 9,10-di(naphthalene-2-yl)anthracene (ADN), 3-tert-butyl-9,10-di(naphth-2-yl)anthracene (TBADN), distyrylarylene (DSA), 4,4″bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

In an embodiment, the blue emission layers BEML1, BEML2, and BEML3 may include, as a fluorescent dopant material, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), etc.

The first green emission layer GEML and the first red emission layer REML may include a phosphorescent dopant material. For example, a metal complex including iridium (Ir), platinum (Pt), osmium (Os), aurum (Au), titanium (Ti), zirconium (Zr), hafnium (Hf), europium (Eu), terbium (Tb), or thulium (Tm) may be used as a phosphorescence dopant. For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant.

The electron transport regions ETR1, ETR2, ETR3, ETR4, and ETR5 may each have a single layer formed of a single material, a single layer formed of different materials, or a multi-layered structure having multiple layers formed of multiple different materials.

The electron transport regions ETR1, ETR2, ETR3, ETR4, and ETR5 may each be formed using various methods such as a vacuum deposition method, a spin coating method, a cast method, a Langmuir-Blodgett (LB) method, an inkjet printing method, a laser printing method, a laser induced thermal imaging (LITI) method, etc.

The electron transport regions ETR1, ETR2, ETR3, ETR4, and ETR5 may each include an anthracene-based compound. However, the disclosure is not limited thereto, and the electron transport layer ETL may each include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine (T2T), 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebg₂), 9,10-di(naphthalene-2-yl)anthracene (ADN), 1,3-bis[3,5-di(pyridin-3-yl)phenyl]benzene (BmPyPhB), or a mixture thereof.

The electron transport regions ETR1, ETR2, ETR3, ETR4, and ETR5 may each include a metal halide such as LiF, NaCl, CsF, RbCl, RbI, CuI, and KI, a lanthanide metal such as Yb, or a co-deposited material of the metal halide and the lanthanide metal. For example, the electron transport regions ETR1, ETR2, ETR3, ETR4, and ETR5 may include KI:Yb, RbI:Yb, etc. as a co-deposited material. The electron transport regions ETR1, ETR2, ETR3, ETR4, and ETR5 may include at least two of Mg, Ag, Yb, and Al. For example, the electron transport regions ETR1, ETR2, ETR3, ETR4, and ETR5 may include Mg and Yb.

The electron transport regions ETR1, ETR2, ETR3, ETR4, and ETR5 may be formed using a metal oxide such as Li₂O or BaO, or 8-hydroxyl-lithium quinolate (Liq), etc., but the disclosure is not limited thereto. Each of the electron transport regions ETR1, ETR2, ETR3, ETR4, and ETR5 may be formed of a mixture material of an electron transport material and an insulating organometallic salt. The organometallic salt may be a material having an energy band gap greater than or equal to about 4 eV. For example, the organometallic salt may include, for example, a metal acetate, a metal benzoate, a metal acetoacetate, a metal acetylacetonate, or a metal stearate.

The electron transport regions ETR1, ETR2, ETR3, ETR4, and ETR5 may each further include at least one of 2,9-dimethyl-4,7-diphenyl-1,10-phenanthroline (BCP), and 4,7-diphenyl-1,10-phenanthroline (Bphen) in addition to the above-described materials, but the disclosure is not limited thereto.

The electron transport regions ETR1, ETR2, ETR3, ETR4, and ETR5 may include the above-described compounds of the electron transport regions in the electron injection layer EIL5 or the electron transport layers ETL1, ETL2, ETL3, ETL4, and ETL5. In case that the electron transport regions ETR1, ETR2, ETR3, ETR4, and ETR5 each include the electron side additional layer, the above-described materials may be included in the electron side additional layer. In an embodiment, the electron injection layer EIL5 may be formed of at least two of Mg, Ag, Yb, and Al. The electron injection layer EIL5 may be formed of, for example, a mixture of Mg and Yb.

The electron transport regions ETR1, ETR2, ETR3, ETR4 and ETR5 may each have, for example, a thickness in a range of about 10 nm to about 150 nm. The electron transport layer ETL may have a thickness in a range of about 0.1 nm to about 100 nm, for example, in a range about 0.3 nm to about 50 nm. In case that the thickness of the electron transport layer ETL satisfies the aforementioned range, satisfactory electron transport characteristics may be obtained without a substantial increase in driving voltage.

The second electrode EL2 may be provided on the multiple light emitting stacks ST1, ST2, ST3, ST4, and ST5. The second electrode EL2 may be a common electrode. The second electrode EL2 may be a cathode or an anode, but the disclosure is not limited thereto. For example, in case that the first electrode EL1 is an anode, the second electrode EL2 may be a cathode, and in case that the first electrode EL1 is a cathode, the second electrode EL2 may be an anode.

The second electrode EL2 may be a transflective electrode or a transmissive electrode. In case that the second electrode EL2 is a transmissive electrode, the second electrode EL2 may be formed of, for example, ITO, IZO, ZnO, ITZO, etc.

In case that the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, In, Zn, Sn, or a compound or mixture thereof (e.g., AgMg, AgYb, or MgAg). In an embodiment, the second electrode EL2 may have a multi-layered structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown, the second electrode EL2 may be connected with an auxiliary electrode. In case that the second electrode EL2 is connected with the auxiliary electrode, the resistance of the second electrode EL2 may decrease.

A capping layer CPL may be further disposed on the second electrode EL2 of each of the light emitting elements ED, ED-1, ED-2, and ED-3 of an embodiment. The capping layer CPL may include a multilayer or a single layer.

In an embodiment, the capping layer CPL may be an organic layer or an inorganic layer. For example, in case that the capping layer CPL contains an inorganic material, the inorganic material may include an alkaline metal compound (e.g., LiF), an alkaline earth metal compound (e.g., MgF₂), SiON, SiNₓ, SiO_{y}, etc.

For example, in case that the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol sol-9-yl)triphenylamine (TCTA), etc., an epoxy resin, or acrylate such as methacrylate. However, the disclosure is not limited thereto, and the capping layer CPL may include at least one of Compounds P1 to P7 below:

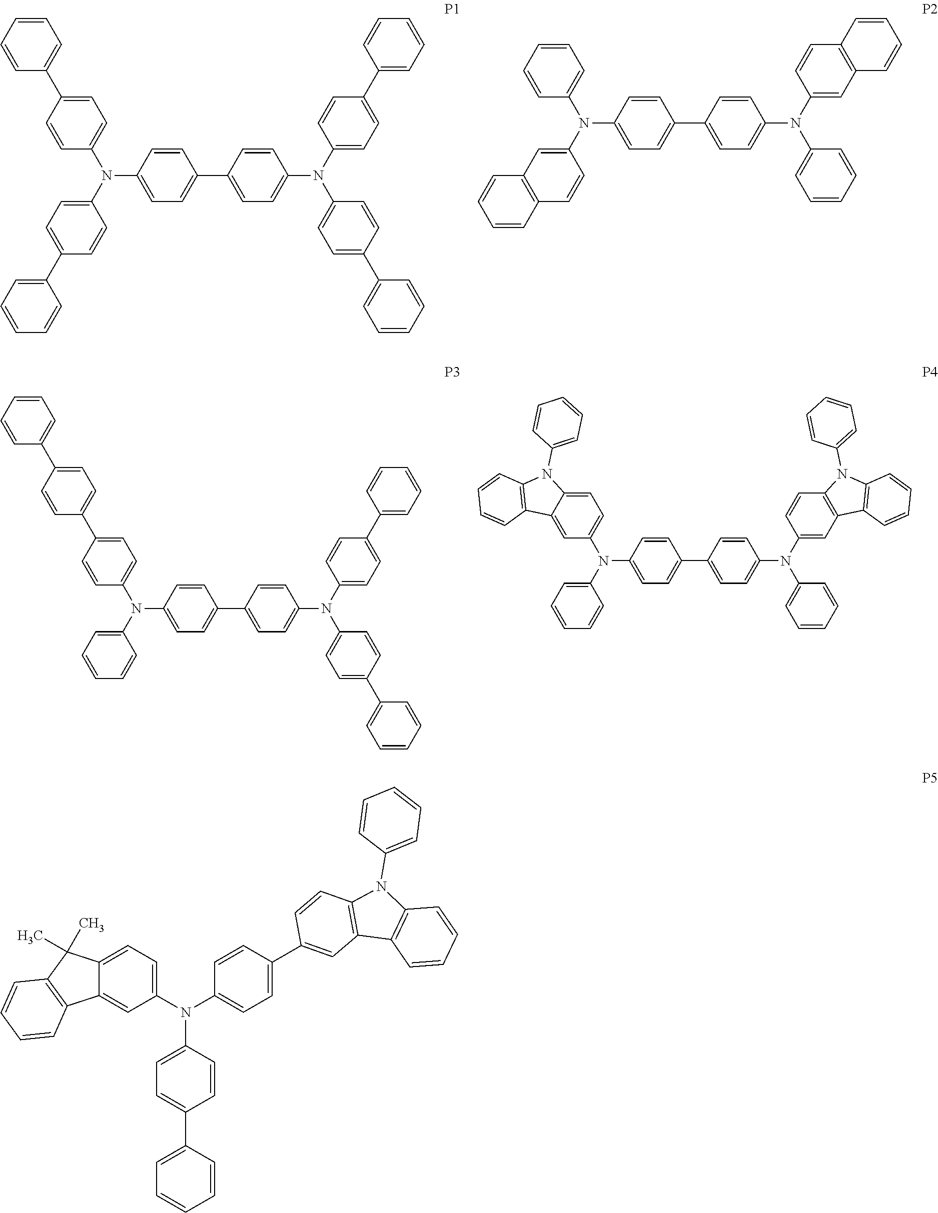

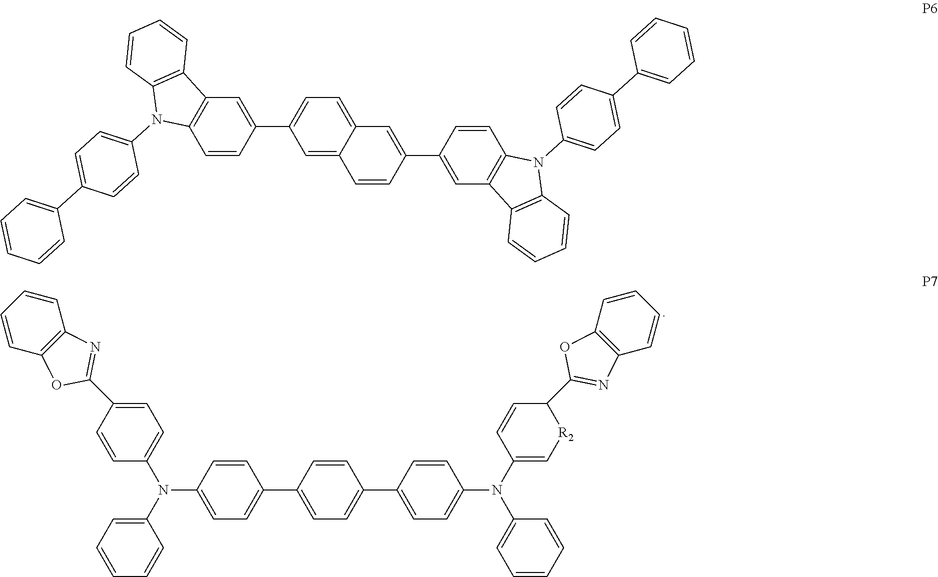

The refractive index of the capping layer CPL may be greater than or equal to about 1.6. For example, the refractive index of the capping layer CPL may be greater than or equal to about 1.6 with respect to light in a wavelength range of about 550 nm to about 660 nm.

The light emitting elements ED, ED-1, ED-2, and ED-3 included in the display panel DP of an embodiment may have a structure including multiple blue emission layers BEML1, BEML2, and BEML3, at least one green emission layer GEML, and at least one red emission layer REML, and thus, light emission at multiple resonance distances may be used, thereby maximizing luminous efficiency. The light emitting elements ED, ED-1, ED-2, and ED-3 according to embodiments may include at least five light emitting stacks, while three of the five light emitting stacks may include a blue emission layer, one light emitting stack may include at least one green emission layer, and one light emitting stack may include at least one red emission layer, thereby maximizing the efficiency of each of x-th order resonance regions of blue light, green light, and red light, thereby maximizing the luminous efficiency of the light emitting element.

Hereinafter, with reference to Examples and Comparative Examples, the results of the characterization of the light emitting elements according to embodiments of the disclosure will be described. Examples described below are only illustrations to assist the understanding of the disclosure, and the scope of the disclosure is not limited thereto.

### (Manufacture of Light Emitting Element)

In Examples and Comparative Examples, after a first electrode was formed on a glass substrate, five light emitting stacks were formed on the first electrode, and a second electrode and a capping layer were formed to manufacture a tandem light emitting element. An n-type charge generation layer in which 2,4,6-tris(3-(pyrimidin-5-yl)phenyl)-1,3,5-triazine (TPM-TAZ) was doped with Liq and a p-type charge generation layer in which 2,9-dimethyl-4,7-diphenyl-1,10-phenanthroline (BCP) was doped with Li were disposed between sequential pairs of the stacks. ITO/Ag/ITO was used as the first electrode, AgMg was used as the second electrode, 1,4,5,8,9,11-hexaazatriphenylenehexacarbonitrile (HATCN) was used as a hole injection layer material, and N,N′-Di(1-naphthyl)-N,N′-diphenyl-(1,1′-biphenyl)-4,4′-diamine (NPB) was used as a hole transport layer material. In the first to fourth light emitting stacks, 2,4,6-tris(biphenyl-3-yl)-1,3,5-triazine (T2T) was used as an electron transport layer material, and in the fifth light emitting stack at the uppermost, a layer in which TPM-TAZ was doped with Liq was used as an electron transport layer material, and Mg and Yb were used as an electron injection layer material. In the light emitting stack including the blue emission layer, an electron blocking layer disposed between the hole transport layer and the emission layer was formed, and 4,4′,4″-tris(N-carbazolyl)triphenylamine (TCTA) was used as an electron blocking layer material. Each layer was formed by a deposition method in a vacuum condition. A capping layer having a thickness of about 500 Å was formed on the second electrode using the above-described P4.

In Examples and Comparative Examples, the above-described H1-1 was used as the host included in the blue emission layer. The above-described FD35 was used as the dopant included in the blue emission layer. The above-described H4-3 and the above-described H3-23 forming an exciplex structure at a ratio of 1:1 were used as the host included in the green emission layer. PD28 was used as the dopant included in the green emission layer. The above-described H5 and H6 forming an exciplex structure at a ratio of 1:1 were used as the host included in the red emission layer. The above-described PR32 was used as the dopant included in the red emission layer.

### Characterization of Examples 1 to 4 and Comparative Examples 1 and 2

In the elements of Examples 1 to 4, as described with reference to FIGS. 5A to 5E, three light emitting stacks among the first to fifth light emitting stacks include the blue emission layer, one light emitting stack includes at least one green emission layer, and one light emitting stack includes at least one red emission layer. Unlike Examples, the light emitting elements of Comparative Examples 1 and 2 did not include a light emitting stack including a red emission layer.

The evaluation results of Examples 1 to 4 and Comparative Examples 1 and 2 are shown in Table 1 below. In the evaluation of the light emitting element of Table 1, the driving voltage and the luminous efficiency indicate voltage and luminous efficiency values corresponding to a brightness of 3,500 nit. The element service life was determined by measuring a time taken for the brightness of the light emitting element to decrease to 97% of an initial brightness. The driving voltage, the luminous efficiency, and the element service life exhibited relative comparison values on the basis of 100% of the driving voltage, the luminous efficiency, and the element service life of Comparative Example 2.

TABLE 1

| | Emission layers | Driving | Luminous | Service |
|---|---|---|---|---|
| | in each stack | voltage (%) | efficiency (%) | life (%) |
| Example 1 | BBRBG | 101 | 102 | 105 |
| Example 2 | BB(R/G)BG | 101 | 110 | 110 |
| Example 3 | RBGBB | 101 | 103 | 106 |
| Example 4 | (R/G)BGBB | 102 | 109 | 110 |
| Comparative | BBGBG | 100 | 100 | 100 |
| Example 1 | | | | |
| Comparative | GBGBB | 100 | 100 | 100 |
| Example 2 | | | | |

Referring to the results of Table 1, it may be seen that the light emitting elements of Examples show similar or low driving voltage and similar or excellent luminous efficiency and element service life characteristics compared to the light emitting elements of the Comparative Examples.

The light emitting elements of embodiments may include multiple blue emission layers, at least one green emission layer, and at least one red emission layer, and for example, the light emitting stack including the red emission layer may be disposed adjacent to the first electrode compared to the light emitting stack including the green emission layer, so that the efficiency of forming white light is optimized, thereby improving the luminous efficiency and element service life. The light emitting elements of embodiments may include the red emission layer so that red, green, and blue light are uniformly emitted compared to the light emitting elements of Comparative Examples including only the blue emission layers and the green emission layers in five stacks. Thus, the luminous efficiency and element service life of the light emitting elements of Examples may be improved as compared to the light emitting elements of Comparative Examples.

According to an embodiment of the disclosure, in the tandem light emitting element including multiple light emitting stacks, the luminous efficiency may be maximized through the blue emission layers, at least one green emission layer, and at least one red emission layer, and thus the luminous efficiency and service life of the light emitting element may be improved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A light emitting element comprising:
a first electrode;
a first light emitting stack disposed on the first electrode;
a second light emitting stack disposed on the first light emitting stack;
a third light emitting stack disposed on the second light emitting stack;
a fourth light emitting stack disposed on the third light emitting stack;
a fifth light emitting stack disposed on the fourth light emitting stack;
a second electrode disposed on the fifth light emitting stack; and
charge generation layers disposed between adjacent ones of the first light emitting stack to the fifth light emitting stack, wherein
each of the first to fifth light emitting stacks comprises at least one emission layer, and
the first to fifth light emitting stacks comprise at least two blue emission layers, at least one green emission layer, and at least one red emission layer.

2. The light emitting element of claim 1, wherein the first light emitting stack to the fifth light emitting stack comprise three blue emission layers, one or two green emission layers, and one or two red emission layers.

3. The light emitting element of claim 1, wherein
the first light emitting stack comprises a first blue emission layer,
the second light emitting stack comprises a second blue emission layer,
the third light emitting stack comprises a red emission layer,
the fourth light emitting stack comprises a third blue emission layer, and
the fifth light emitting stack comprises a green emission layer.

4. The light emitting element of claim 1, wherein
the first light emitting stack comprises a first blue emission layer,
the second light emitting stack comprises a second blue emission layer,
the third light emitting stack comprises a first complex emission layer,
the fourth light emitting stack comprises a third blue emission layer,
the fifth light emitting stack comprises a green emission layer, and
the first complex emission layer comprises a red sub-emission layer, and a green sub-emission layer disposed on the red sub-emission layer.

5. The light emitting element of claim 1, wherein
the first light emitting stack comprises a red emission layer,
the second light emitting stack comprises a first blue emission layer,
the third light emitting stack comprises a green emission layer,
the fourth light emitting stack comprises a second blue emission layer, and
the fifth light emitting stack comprises a third blue emission layer.

6. The light emitting element of claim 1, wherein
the first light emitting stack comprises a first complex emission layer,
the second light emitting stack comprises a first blue emission layer,
the third light emitting stack comprises a green emission layer,
the fourth light emitting stack comprises a second blue emission layer,
the fifth light emitting stack comprises a third blue emission layer, and
the first complex emission layer comprises a red sub-emission layer and a green sub-emission layer disposed on the red sub-emission layer.

7. The light emitting element of claim 1, wherein
the first light emitting stack to the fifth light emitting stack comprise a first blue emission layer, a second blue emission layer, and a third blue emission layer,
the third blue emission layer is disposed adjacent to the second electrode compared to the first blue emission layer and the second blue emission layer,
a distance from a top surface of the first electrode to a center of the third blue emission layer is an “n”th-order resonance distance of the third blue emission layer, and
“n” is an integer greater than or equal to 3.

8. The light emitting element of claim 1, wherein
the first light emitting stack to the fifth light emitting stack comprise a red emission layer,
a distance from a top surface of the first electrode to a center of the red emission layer is an “m”th-order resonance distance of the red emission layer, and
“m” is 1 or 2.

9. The light emitting element of claim 1, wherein the at least one emission layer included in each of the first light emitting stack to the fifth light emitting stack has a thickness in a range of about 50 Å to about 400 Å.

10. The light emitting element of claim 1, wherein the charge generation layers comprise:
a first charge generation layer disposed between the first light emitting stack and the second light emitting stack;
a second charge generation layer disposed between the second light emitting stack and the third light emitting stack;
a third charge generation layer disposed between the third light emitting stack and the fourth light emitting stack; and
a fourth charge generation layer disposed between the fourth light emitting stack and the fifth light emitting stack.

11. The light emitting element of claim 1, wherein each of the charge generation layers comprises:
a p-type charge generation layer doped with a p-dopant; and
an n-type charge generation layer doped with an n-dopant.

12. The light emitting element of claim 1, wherein each of the first to fifth light emitting stacks further comprises:
a hole transport region adjacent to the first electrode; and
an electron transport region which is spaced apart from the hole transport region with the emission layer interposed between the electron transport region and the hole transport region, and is adjacent to the second electrode.

13. The light emitting element of claim 12, wherein
at least one of the electron transport regions of the first to fifth light emitting stacks comprises an electron injection layer, and
the electron injection layer includes at least two of Mg, Ag, Yb, and Al.

14. The light emitting element of claim 1, wherein
at least one of the first light emitting stack to the fifth light emitting stack comprises a phosphorescent emission layer, and
at least another one of the first light emitting stack to the fifth light emitting stack comprises a fluorescent emission layer.

15. The light emitting element of claim 1, wherein
at least one of the first light emitting stack to the fifth light emitting stack comprises a first host, a second host, and a dopant, and
the first host and the second host form an exciplex.

16. The light emitting element of claim 1, further comprising:
a capping layer disposed on the second electrode,
wherein the capping layer has a refractive index greater than or equal to about 1.6.

17. A light emitting element comprising:
a first electrode;
a first light emitting stack disposed on the first electrode;
a second light emitting stack disposed on the first light emitting stack;
a third light emitting stack disposed on the second light emitting stack;
a fourth light emitting stack disposed on the third light emitting stack;
a fifth light emitting stack disposed on the fourth light emitting stack; and
a second electrode disposed on the fifth light emitting stack, wherein
three of the first light emitting stack to the fifth light emitting stack comprise blue emission layers,
one of the first light emitting stack to the fifth light emitting stack comprises at least one green emission layer,
a rest of the first light emitting stack to the fifth light emitting stack comprises at least one red emission layer, and
the rest of the first light emitting stack to the fifth light emitting stack comprising the at least one red emission layer is disposed adjacent to the first electrode compared to the one of the first light emitting stack to the fifth light emitting stack comprising the at least one green emission layer.

18. A display panel comprising:
a light emitting element that emits source light; and
an optical structure layer which is disposed on the light emitting element and transmits the source light or converts the source light into light having a different wavelength, wherein
the light emitting element comprises:
a first electrode;
a first light emitting stack disposed on the first electrode;
a second light emitting stack disposed on the first light emitting stack;
a third light emitting stack disposed on the second light emitting stack;
a fourth light emitting stack disposed on the third light emitting stack;
a fifth light emitting stack disposed on the fourth light emitting stack;
a second electrode disposed on the fifth light emitting stack; and
charge generation layers disposed between adjacent ones of the first light emitting stack to the fifth light emitting stack,
each of the first to fifth light emitting stacks comprises at least one emission layer, and
the first to fifth light emitting stacks comprise at least two blue emission layers, at least one green emission layer, and at least one red emission layer.

19. The display panel of claim 18, wherein
the optical structure layer comprises a light control layer disposed on the light emitting element, and
the light control layer comprises:
a first light control pattern that emits light having a red wavelength;
a second light control pattern that emits light having a blue wavelength; and
a third light control pattern that emits light having a green wavelength.

20. The display panel of claim 18, wherein the first light emitting stack to the fifth light emitting stack comprise three blue emission layers, one or two green emission layers, and one or two red emission layers.
